(19) United States
(12) Patent Application Publication
(10) Pub. No.: US 2025/0110404 A1
(43) Pub. Date: Apr. 3, 2025

(54) RESIST COMPOSITION AND METHOD FOR FORMING RESIST PATTERN

(71) Applicant: TOKYO OHKA KOGYO CO., LTD., Kawasaki-shi (JP)

(72) Inventors: Masato MIYAZAKI, Kawasaki-shi (JP); Fumitake HIRAYAMA, Kawasaki-shi (JP); Shinichi KOHNO, Kawasaki-shi (JP); Yusuke NAKAGAWA, Kawasaki-shi (JP)

(21) Appl. No.: 18/729,822

(22) PCT Filed: Jan. 24, 2023
(86) PCT No.: PCT/JP2023/002003

§ 371 Date: Jul. 17, 2024

(30) Foreign Application Priority Data
Jan. 24, 2022 (JP) 2022-008707

(51) Int. Cl. G03F 7/039; G03F 7/038

(52) U.S. Cl. CPC G03F 7/0397; G03F 7/0382; G03F 7/0388

(57) ABSTRACT

A resist composition including a resin component that has a constitutional unit containing an acid decomposable group whose polarity is increased due to an action of an acid, a constitutional unit represented by General Formula (a10-1), and a constitutional unit represented by General Formula (a5-1), and a resin component that has a constitutional unit represented by General Formula (z1-1) and no acid dissociable group. In the formulae, Wa^{x1} represents an aromatic hydrocarbon group, Ra⁵ represents an acid non-dissociable aliphatic cyclic group in which some carbon atoms forming a ring skeleton may be substituted with oxygen atoms, and Rz⁰ represents a hydrogen atom or a hydrocarbon group containing no acid dissociable group

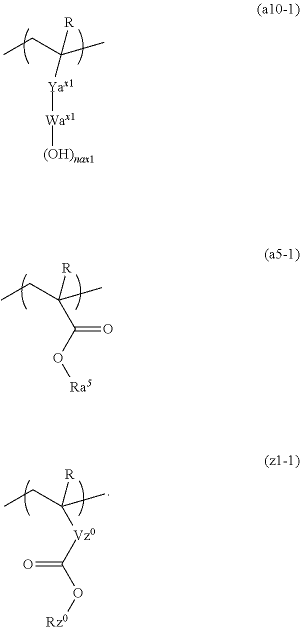

### TECHNICAL FIELD

The present invention relates to a resist composition and a method for forming a resist pattern.

Priority is claimed on Japanese Patent Application No. 2022-008707, filed Jan. 24, 2022, the content of which is incorporated herein by reference.

### BACKGROUND ART

In recent years, in the manufacture of semiconductor elements and liquid crystal display elements, advances in lithography technologies have led to rapid progress in the field of pattern miniaturization. These pattern miniaturization techniques typically involve shortening the wavelength (increasing the energy) of the exposure light source.

Resist materials require lithography characteristics such as a high resolution that enables reproduction of patterns with minute dimensions, and a high level of sensitivity to these kinds of exposure light sources.

As a resist material that satisfies these requirements, a chemically amplified resist composition containing a base material component whose solubility in a developing solution is changed due to an action of an acid and an acid generation agent component that generates an acid upon light exposure has been used.

In the manufacture of a semiconductor package, a MEMS, and the like, a step of forming a thick resist film on a surface of a processing object, forming a resist pattern, and performing etching or the like is carried out. In a case where a chemically amplified resist composition is used here, the sensitivity is more difficult to maintain during light exposure as the film thickness of the resist film increases, and as a result, problems of a decrease in resolution for development and difficulties in obtaining a desired resist pattern shape occur. Further, there is also a problem in that cracking is likely to occur in the resist pattern as the film thickness of the resist film increases.

Patent Document 1 suggests a resist composition containing a resin component which has a constitutional unit containing an acid decomposable group and a constitutional unit derived from hydroxystyrene, and a plasticizer component which has a constitutional unit having a specific structure containing no acid dissociable group, in which the content of the plasticizer component is 50 parts by mass or less with respect to 100 parts by mass of the resin component, and the solid content concentration was 25% by mass or greater. With the resist composition, a thick resist film can be formed, and a resist pattern in which cracks are unlikely to occur and surface roughness during etching is unlikely to occur can be formed.

### CITATION LIST

### Patent Document

[Patent Document 1] Japanese Unexamined Patent Application, First Publication No. 2021-92659

### SUMMARY OF INVENTION

### Technical Problem

Meanwhile, at present, with the increases in the integration of LSIs and the speed of communication, an increase in memory capacity is required, and further pattern miniaturization is rapidly progressing. The lithography using an electron beam or EUV aims to form a fine pattern with a size of several tens of nanometers. However, there are still many problems such as low productivity, and there is a limit in a technique using fine processing.

On the other hand, in addition to the pattern fining, a three-dimensional structure device for increasing the capacity of a memory by stacking cells in lamination has been developed.

In production of the three-dimensional structure device, a step in which a thick resist film having a film thickness greater than that of the related art, for example, a film thickness of 5 μm or greater is formed on a surface of a material to be processed, a resist pattern is formed, and etching or the like is performed is carried out. In a case where a chemically amplified resist composition is used, since an exposure light source is unlikely to reach a bottom portion of a resist film in a case where the resist is formed into a thick film, a resist having higher transparency is required. It is a mainstream to reduce the amount of a constitutional unit derived from hydroxystyrene in a base material component in order to improve the transparency, but there is a concern that a difference (ACD) in CD between an upper portion of the pattern and a bottom portion of the pattern increases, and the shape of the resist after the patterning is tapered.

In addition, the pattern CD may be affected, for example, by a process of performing post-exposure delay on the resist film.

Further, in a case where the resist is formed into a thick film, the risk of occurrence of cracks due to thermal contraction during the process increases, and thus there is room for improvement.

Further, in a case where the resist is formed into a thick film, there is a concern of deterioration of handleability such as occurrence of pipe clogging during production of a resist or transportation due to an increase in viscosity.

The present invention has been made in consideration of the above-described circumstances, and an object of the present invention is to provide a resist pattern composition which has appropriate viscosity and satisfactory handleability, is unlikely to be affected by the process during pattern formation, reduces occurrence of cracks, and is capable of forming a thick resist pattern having a satisfactory shape, and a method for forming a resist pattern using the resist composition.

### Solution to Problem

In order to achieve the above-described object, the present invention employs the following configurations.

That is, according to a first aspect of the present invention, there is provided a resist composition which generates an acid upon light exposure and whose solubility in a developing solution is changed due to an action of the acid, the resist composition including: a resin component (A1) that has a constitutional unit (a1) containing an acid decomposable group whose polarity is increased due to an action of an acid, a constitutional unit (a10) represented by General Formula (a10-1), and a constitutional unit (a5) represented by General Formula (a5-1); and a resin component (Z) that has a constitutional unit (z1) represented by General Formula (z1-1) and no acid dissociable group.

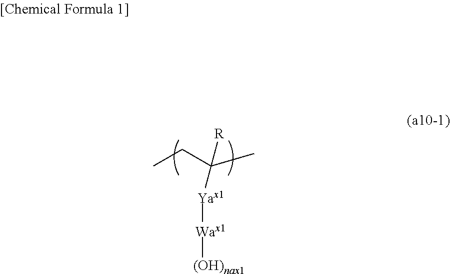

[In the formula, R represents a hydrogen atom, an alkyl group having 1 to 5 carbon atoms, or a halogenated alkyl group having 1 to 5 carbon atoms. Ya^{x1} represents a single bond or a divalent linking group. Wa^{x1} represents an aromatic hydrocarbon group which may have a substituent. nₐₓ₁ represents an integer of 1 or greater.]

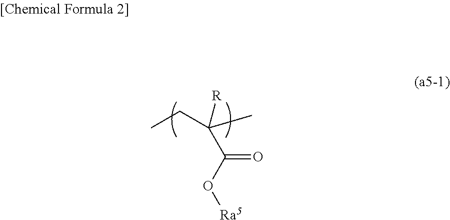

[In the formula, R represents a hydrogen atom, an alkyl group having 1 to 5 carbon atoms, or a halogenated alkyl group having 1 to 5 carbon atoms. Ra⁵ represents an acid non-dissociable aliphatic cyclic group in which some carbon atoms forming a ring skeleton may be substituted with oxygen atoms.]

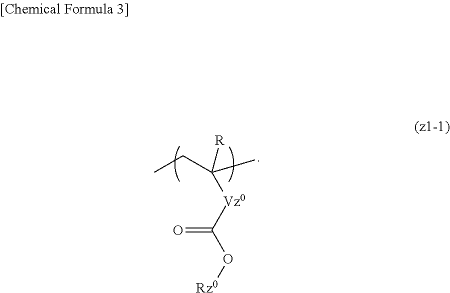

[In the formula, R represents a hydrogen atom, an alkyl group having 1 to 5 carbon atoms, or a halogenated alkyl group having 1 to 5 carbon atoms. Vz⁰ represents a single bond or a divalent hydrocarbon group which may contain a heteroatom. Here, in a case where Vz⁰ represents the divalent hydrocarbon group which may have a heteroatom, Vz⁰ does not include an acid dissociable group. Rz⁰ represents a hydrogen atom or a group represented by General Formula (z1-r-1).]

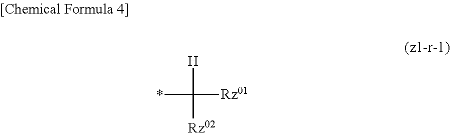

[In the formula, Rz⁰¹ represents a hydrocarbon group which may have a substituent. Rz⁰² represents a hydrogen atom or a hydrocarbon group which may have a substituent. Rz⁰¹ and Rz⁰² may be bonded to each other to form a ring structure. Here, Rz⁰¹ and Rz⁰² do not include an acid dissociable group. * represents a bonding site.]

According to a second aspect of the present invention, there is provided a method for forming a resist pattern, including: a step of forming a resist film on a support using the resist composition according to the first aspect; a step of exposing the resist film to light; and a step of developing the resist film exposed to light to form a resist pattern.

### Advantageous Effects of Invention

According to the present invention, it is possible to provide a resist pattern composition which has appropriate viscosity and satisfactory handleability, is unlikely to be affected by the process during pattern formation, reduces occurrence of cracks, and is capable of forming a thick resist pattern having a satisfactory shape, and a method for forming a resist pattern using the resist composition.

### DESCRIPTION OF EMBODIMENTS

In the present specification and the present claims, the term “aliphatic” is a relative concept used in relation to the term “aromatic”, and defines a group or compound that has no aromaticity.

The term “alkyl group” includes a linear, branched, or cyclic monovalent saturated hydrocarbon group unless otherwise specified. The same applies to the alkyl group in an alkoxy group.

The term “alkylene group” includes a linear, branched, or cyclic divalent saturated hydrocarbon group unless otherwise specified.

Examples of “halogen atom” include a fluorine atom, a chlorine atom, a bromine atom, and an iodine atom.

The term “constitutional unit” indicates a monomer unit constituting a polymer compound (a resin, a polymer, or a copolymer).

The expression “may have a substituent” includes both a case where a hydrogen atom (—H) is substituted with a monovalent group and a case where a methylene (—CH₂—) group is substituted with a divalent group.

The term “light exposure” is a general concept for irradiation with radiation.

The term “acid decomposable group” indicates a group having acid decomposability in which at least a part of a bond in the structure of the acid decomposable group can be cleaved due to the action of an acid.

Examples of the acid decomposable group whose polarity is increased due to the action of an acid include groups which are decomposed due to the action of an acid to generate a polar group.

Examples of the polar group include a carboxy group, a hydroxyl group, an amino group, and a sulfo group (—SO₃H).

More specific examples of the acid decomposable group include a group in which the above-described polar group has been protected by an acid dissociable group (such as a group in which a hydrogen atom of the OH-containing polar group has been protected by an acid dissociable group).

Here, the term “acid dissociable group” indicates both a group (i) having an acid dissociation property in which a bond between the acid dissociable group and an atom adjacent to the acid dissociable group can be cleaved due to the action of an acid and a group (ii) in which some bonds are cleaved due to the action of an acid, a decarboxylation reaction occurs, and thus the bond between the acid dissociable group and the atom adjacent to the acid dissociable group can be cleaved.

It is necessary that the acid dissociable group that constitutes the acid decomposable group is a group which exhibits a lower polarity than that of the polar group generated by the dissociation of the acid dissociable group. Thus, in a case where the acid dissociable group is dissociated by the action of an acid, a polar group exhibiting a higher polarity than that of the acid dissociable group is generated so that the polarity is increased. As a result, the polarity of an entire component (A1) is increased. Due to the increase in the polarity, relatively, the solubility in a developing solution is changed such that the solubility is increased in a case where the developing solution is an alkali developing solution and the solubility is decreased in a case where the developing solution is an organic developing solution.

The term “base material component” denotes an organic compound having a film-forming ability. Organic compounds used as the base material component are classified into non-polymers and polymers. As the non-polymers, those having a molecular weight of 500 or greater and less than 4,000 are typically used. Hereinafter, the term “low-molecular-weight compound” denotes a non-polymer having a molecular weight of 500 or greater and less than 4,000. As the polymer, those having a molecular weight of 1,000 or greater are typically used. Hereinafter, “resin”. “polymer compound”, or “polymer” indicates a polymer having a molecular weight of 1,000 or greater. As the molecular weight of the polymer, the weight-average molecular weight in terms of polystyrene according to gel permeation chromatography (GPC) is used.

The expression “constitutional unit to be derived” denotes a constitutional unit formed by cleavage of a multiple bond between carbon atoms, for example, an ethylenic double bond.

In “acrylic acid ester”, the hydrogen atom bonded to the carbon atom at the α-position may be substituted with a substituent. The substituent (R^{αx}) that substitutes the hydrogen atom bonded to the carbon atom at the α-position is an atom other than the hydrogen atom or a group. Further, the acrylic acid ester includes itaconic acid diester in which the substituent (R^{αx}) has been substituted with a substituent having an ester bond and α-hydroxyacryl ester in which the substituent (R^{αx}) has been substituted with a hydroxyalkyl group or a group obtained by modifying a hydroxyl group thereof. Further, the carbon atom at the α-position of acrylic acid ester indicates the carbon atom to which the carbonyl group of acrylic acid is bonded, unless otherwise specified.

Hereinafter, acrylic acid ester in which the hydrogen atom bonded to the carbon atom at the α-position has been substituted with a substituent is also referred to as α-substituted acrylic acid ester.

The concept “derivative” includes those obtained by substituting a hydrogen atom at the α-position of a target compound with another substituent such as an alkyl group or a halogenated alkyl group, and derivatives thereof. Examples of the derivatives thereof include those obtained by substituting a hydrogen atom of a hydroxyl group of a target compound, in which the hydrogen atom at the α-position may be substituted with a substituent, with an organic group, and those obtained by bonding a substituent other than a hydroxyl group to a target compound in which the hydrogen atom at the α-position may be substituted with a substituent. Further, the α-position denotes the first carbon atom adjacent to a functional group unless otherwise specified.

Examples of the substituent that substitutes the hydrogen atom at the α-position of hydroxystyrene include those for R^{αx}.

In the present specification and the present claims, asymmetric carbons may be present and enantiomers or diastereomers may be present depending on the structures of the chemical formulae. In this case, these isomers are represented by one chemical formula. These isomers may be used alone or in the form of a mixture.

### (Resist Composition)

A resist composition according to a first aspect of the present invention is a resist composition which generates an acid upon light exposure and whose solubility in a developing solution is changed due to an action of the acid, the resist composition including a base material component (A) whose solubility in a developing solution is changed due to the action of an acid (hereinafter, also referred to as “component (A)”) and a resin component (Z) containing no acid dissociable group (hereinafter, also referred to as “component (Z)”).

In a case where a resist film is formed using such a resist composition, a thick resist film (for example, a film having a film thickness of 5 μm to 20 μm) can be formed.

In a case where a resist film is formed of such a resist composition and the resist film is selectively exposed, since an acid is generated in an exposed portion of the resist film and the solubility of the component (A) in a developing solution is changed due to the action of the acid while the solubility of the component (A) in a developing solution is not changed in an unexposed portion of the resist film, a difference in solubility in the developing solution occurs between the exposed portion of the resist film and the unexposed portion of the resist film. Therefore, in a case where the resist film is developed, the exposed portion of the resist film is dissolved and removed to form a positive-tone resist pattern in a case where the resist composition is of a positive-tone, whereas the unexposed portion of the resist film is dissolved and removed to form a negative-tone resist pattern in a case where the resist composition is of a negative tone.

In the present specification, a resist composition which forms a positive-tone resist pattern by dissolving and removing the exposed portion of the resist film is referred to as a positive-tone resist composition, and a resist composition which forms a negative-tone resist pattern by dissolving and removing the unexposed portion of the resist film is referred to as a negative-tone resist composition. The resist composition of the present embodiment may be a positive-tone resist composition or a negative-tone resist composition. Further, the resist composition of the present embodiment may be used in an alkali developing process using an alkali developing solution in the developing treatment in a case of forming a resist pattern or may be used in a solvent developing process using a developing solution containing an organic solvent (organic developing solution) in the developing treatment.

The resist composition of the present embodiment has a function of generating an acid upon exposure, and the component (A) may generate an acid upon exposure or an additive component blended separately from the component (A) may generate an acid upon exposure.

Specifically, the resist composition according to the present embodiment may (1) further contain an acid generation agent component (B) (hereinafter, referred to as “component (B)”) that generates an acid upon light exposure; (2) have a component (A) that generates an acid upon light exposure; and (3) have a component (A) that generates an acid upon light exposure and further contains component (B).

That is, in the cases of (2) and (3) described above, the component (A) is “base material component which generates an acid upon light exposure and whose solubility in a developing solution is changed due to the action of the acid”. In a case where the component (A) is a base material component which generates an acid upon light exposure and whose solubility in a developing solution is changed due to the action of the acid, it is preferable that a component (A1) described below is a polymer compound which generates an acid upon light exposure and whose solubility in a developing solution is changed due to the action of the acid. As such a polymer compound, a resin having a constitutional unit that generates an acid upon light exposure can be used. As the constitutional unit that generates an acid upon light exposure, those which have been known can be used. Among these, the resist composition of the present embodiment in the case of (1) described above is preferable.

### <Component (A)>

In the resist composition of the present embodiment, it is preferable that the component (A) has a resin component (A1) whose solubility in a developing solution is changed due to the action of an acid (hereinafter, also referred to as “component (A1)”). Since the polarity of the base material component before and after the light exposure is changed by using the component (A1), an excellent development contrast can be obtained not only in an alkali developing process but also in a solvent developing process.

As the component (A), at least the component (A1) is used, and other polymer compounds and/or low-molecular-weight compounds may be used in combination with the component (A1).

In a case of applying an alkali developing process, the base material component having the component (A1) is insoluble in an alkali developing solution before light exposure, but in a case where an acid is generated from the component (B) upon light exposure, the action of this acid causes an increase in the polarity of the base material component, thereby increasing the solubility of the component (A1) in an alkali developing solution. Therefore, in a case where selective light exposure is performed on a resist film formed by coating a support with the resist composition in the resist pattern formation, the exposed portion of the resist film is changed from being insoluble to being soluble in an alkali developing solution, whereas the unexposed portion of the resist film remains insoluble in an alkali developing solution, and thus a positive-tone resist pattern is formed by performing alkali development.

Meanwhile, in a case of a solvent developing process, the base material component having the component (A1) exhibits high solubility in an organic developing solution before light exposure. For example, in a case where an acid is generated from the component (B) upon light exposure, the polarity of the component (A1) is increased due to the action of the acid, thereby decreasing the solubility of the component (A1) in an organic developing solution. Therefore, in a case where selective light exposure is performed on a resist film formed by coating a support with the resist composition in the resist pattern formation, the exposed portion of the resist film is changed from being soluble to being insoluble in an organic developing solution, whereas the unexposed portion of the resist film remains soluble in an organic developing solution. Therefore, a negative-tone resist pattern is formed by performing development using an organic developing solution so that a contrast is imparted between the exposed portion and the unexposed portion.

In the resist composition according to the present embodiment, the component (A) may be used alone or in combination of two or more kinds thereof.

### In Regard to Component (A1)

The component (A1) is a polymer compound that has a constitutional unit (a1) containing an acid decomposable group whose polarity is increased due to the action of an acid, a constitutional unit (a10) represented by General Formula (a10-1), and a constitutional unit (a5) represented by General Formula (a5-1).

The component (A1) may have other constitutional units in addition to the constitutional unit (a1), the constitutional unit (a10), and the constitutional unit (a5).

<<Constitutional Unit (a1)>>

The constitutional unit (a1) is a constitutional unit that contains an acid decomposable group whose polarity is increased due to the action of an acid.

Examples of the acid dissociable group are the same as those which have been suggested as the acid dissociable groups of the base resin for a chemically amplified resist composition.

Specific examples of the acid dissociable group of the base resin for a chemically amplified resist composition include “acetal type acid dissociable group”, “tertiary alkyl ester type acid dissociable group”, and “tertiary alkyloxycarbonyl acid dissociable group” described below.

### Acetal Type Acid Dissociable Group:

Examples of the acid dissociable group that protects a carboxy group or a hydroxyl group in the polar groups include an acid dissociable group represented by General Formula (a1-r-1) (hereinafter, also referred to as “acetal type acid dissociable group”).

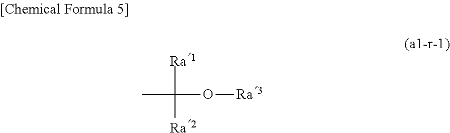

[In the formula, Ra′¹ and Ra′² represent a hydrogen atom or an alkyl group. Ra′³ represents a hydrocarbon group, and Ra′³ may be bonded to any of Ra′¹ and Ra′² to form a ring.]

In Formula (a1-r-1), it is preferable that at least one of Ra′¹ or Ra′² represents a hydrogen atom and more preferable that both Ra′¹ and Ra′² represent a hydrogen atom.

In a case where Ra′¹ or Ra′² represents an alkyl group, examples of the alkyl group include the same alkyl groups exemplified as the substituent which may be bonded to the carbon atom at the α-position in the description of the α-substituted acrylic acid ester. Among these, an alkyl group having 1 to 5 carbon atoms is preferable. Specific preferred examples thereof include linear or branched alkyl groups. More specific examples thereof include a methyl group, an ethyl group, a propyl group, an isopropyl group, an n-butyl group, an isobutyl group, a tert-butyl group, a pentyl group, an isopentyl group, and a neopentyl group. Among these, a methyl group or an ethyl group is more preferable, and a methyl group is particularly preferable.

In Formula (a1-r-1), examples of the hydrocarbon group as Ra′³ include a linear or branched alkyl group and a cyclic hydrocarbon group.

The linear alkyl group has preferably 1 to 5 carbon atoms, more preferably 1 to 4 carbon atoms, and still more preferably 1 or 2 carbon atoms. Specific examples thereof include a methyl group, an ethyl group, an n-propyl group, an n-butyl group, and an n-pentyl group. Among these, a methyl group, an ethyl group, or an n-butyl group is preferable, and a methyl group or an ethyl group is more preferable.

The branched alkyl group has preferably 3 to 10 carbon atoms and more preferably 3 to 5 carbon atoms. Specific examples thereof include an isopropyl group, an isobutyl group, a tert-butyl group, an isopentyl group, a neopentyl group a 1,1-diethylpropyl group, and a 2,2-dimethylbutyl group. Among these, an isopropyl group is preferable.

In a case where Ra′³ represents a cyclic hydrocarbon group, the hydrocarbon group may be an aliphatic hydrocarbon group or an aromatic hydrocarbon group and may be a polycyclic group or a monocyclic group.

As the aliphatic hydrocarbon group which is a monocyclic group, a group in which one hydrogen atom has been removed from a monocycloalkane is preferable. The monocycloalkane has preferably 3 to 6 carbon atoms, and specific examples thereof include cyclopentane and cyclohexane.

As the aliphatic hydrocarbon group which is a polycyclic group, a group in which one hydrogen atom has been removed from a polycycloalkane is preferable. As the polycycloalkane, a group having 7 to 12 carbon atoms is preferable, and specific examples thereof include adamantane, norbornane, isobornane, tricyclodecane, and tetracyclododecane.

In a case where the cyclic hydrocarbon group as Ra′³ is an aromatic hydrocarbon group, the aromatic hydrocarbon group is a hydrocarbon group having at least one aromatic ring.

The aromatic ring is not particularly limited as long as the aromatic ring is a cyclic conjugated system having (4n+2) a electrons and may be monocyclic or polycyclic. The aromatic ring has preferably 5 to 30 carbon atoms, more preferably 5 to 20 carbon atoms, still more preferably 6 to 15 carbon atoms, and particularly preferably 6 to 12 carbon atoms.

Specific examples of the aromatic ring include aromatic hydrocarbon rings such as benzene, naphthalene, anthracene, and phenanthrene; and aromatic heterocyclic rings in which some of the carbon atoms constituting the above-described aromatic hydrocarbon rings are substituted with heteroatoms. Examples of the heteroatom in the aromatic heterocyclic rings include an oxygen atom, a sulfur atom, and a nitrogen atom. Specific examples of the aromatic heterocyclic ring include a pyridine ring and a thiophene ring.

Specific examples of the aromatic hydrocarbon group as Ra′³ include a group in which one hydrogen atom has been removed from the above-described aromatic hydrocarbon ring or aromatic heterocyclic ring (such as an aryl group or a heteroaryl group); a group in which one hydrogen atom has been removed from an aromatic compound having two or more aromatic rings (such as biphenyl or fluorene); and a group in which one hydrogen atom of the above-described aromatic hydrocarbon ring or aromatic heterocyclic ring has been substituted with an alkylene group (for example, an arylalkyl group such as a benzyl group, a phenethyl group, a 1-naphthylmethyl group, a 2-naphthylmethyl group, a 1-naphthylethyl group, or a 2-naphthylethyl group). The number of carbon atoms in the alkylene group bonded to the aromatic hydrocarbon ring or aromatic heterocyclic ring is preferably in a range of 1 to 4, more preferably 1 or 2, and particularly preferably 1.

The cyclic hydrocarbon group as Ra′³ may include a substituent. Examples of the substituent include —R^{P1}, —R^{P2}—O—R^{P1}, —R^{P2}—CO—R^{P1}, —R^{P}—CO—OR^{P1}, —R^{P2}—O—CO—R^{P1}, —R^{P2}—OH, —R^{P2}—CN, and —R^{P1}—COOH (hereinafter, these substituents will also be collectively referred to as “Ra^{x5}”).

Here, R^{P1} represents a chain-like monovalent saturated hydrocarbon group having 1 to 10 carbon atoms, a monovalent aliphatic cyclic saturated hydrocarbon group having 3 to 20 carbon atoms, or a monovalent aromatic hydrocarbon group having 6 to 30 carbon atoms. Further, R^{P2} represents a single bond, a chain-like divalent saturated hydrocarbon group having 1 to 10 carbon atoms, a divalent aliphatic cyclic saturated hydrocarbon group having 3 to 20 carbon atoms, or a divalent aromatic hydrocarbon group having 6 to 30 carbon atoms. Here, some or all hydrogen atoms in the chain-like saturated hydrocarbon group, the aliphatic cyclic saturated hydrocarbon group, and the aromatic hydrocarbon group as R^{P1} and R^{P2} may be substituted with fluorine atoms. The aliphatic cyclic hydrocarbon group may have one or more of a single kind of substituents or one or more of each of plural kinds of the substituents.

Examples of the chain-like monovalent saturated hydrocarbon group having 1 to 10 carbon atoms include a methyl group, an ethyl group, a propyl group, a butyl group, a pentyl group, a hexyl group, a heptyl group, an octyl group, and a decyl group.

Examples of the monovalent aliphatic cyclic saturated hydrocarbon group having 3 to 20 carbon atoms include a monocyclic aliphatic saturated hydrocarbon group such as a cyclopropyl group, a cyclobutyl group, a cyclopentyl group, a cyclohexyl group, a cycloheptyl group, a cyclooctyl group, a cyclodecyl group, or a cyclododecyl group; and a polycyclic aliphatic saturated hydrocarbon group such as a bicyclo[2.2.2]octanyl group, a tricyclo[5.2.1.02,6]decanyl group, a tricyclo[3.3.1.13,7] decanyl group, a tetracyclo[6.2.1.13,6.02,7]dodecanyl group, or an adamantyl group.

Examples of the monovalent aromatic hydrocarbon group having 6 to 30 carbon atoms include a group formed by removing one hydrogen atom from an aromatic hydrocarbon ring such as benzene, biphenyl, fluorene, naphthalene, anthracene, or phenanthrene.

In a case where Ra′³ is bonded to any of Ra′¹ and Ra′² to form a ring, the cyclic group is preferably a 4- to 7-membered ring and more preferably a 4- to 6-membered ring. Specific examples of the cyclic group include a tetrahydropyranyl group and a tetrahydrofuranyl group.

### Tertiary Alkyl Ester Type Acid Dissociable Group:

Examples of the acid dissociable group that protects a carboxy group among the polar groups include an acid dissociable group represented by General Formula (a1-r-2).

Among examples of the acid dissociable group represented by Formula (a1-r-2), a group formed of an alkyl group is referred to as “tertiary alkyl ester type acid dissociable group” for convenience.

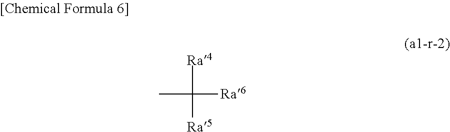

[In the formula, Ra′⁴ to Ra′⁶ each represent a hydrocarbon group, and Ra′⁵ and Ra′⁶ may be bonded to each other to form a ring.]

Examples of the hydrocarbon group as Ra′⁶ include a linear or branched alkyl group, a chain-like or cyclic alkenyl group, and a cyclic hydrocarbon group.

Examples of the linear or branched alkyl group and the cyclic hydrocarbon group (an aliphatic hydrocarbon group which is a monocyclic group, an aliphatic hydrocarbon group which is a polycyclic group, or an aromatic hydrocarbon group) as Ra′⁴ include the same groups as those for Ra′³.

As the chain-like or cyclic alkenyl group as Ra′⁴, an alkenyl group having 2 to 10 carbon atoms is preferable.

Examples of the hydrocarbon group as Ra′⁵ or Ra′⁶ include the same groups as those for Ra′³.

In a case where Ra′⁵ and Ra′⁶ are bonded to each other to form a ring, suitable examples thereof include a group represented by General Formula (a1-r2-1), a group represented by General Formula (a1-r2-2), and a group represented by General Formula (a1-r2-3).

Meanwhile, in a case where Ra′⁴ to Ra′⁶ independently represent a hydrocarbon group without being bonded to one another, suitable examples thereof include a group represented by General Formula (a1-r2-4).

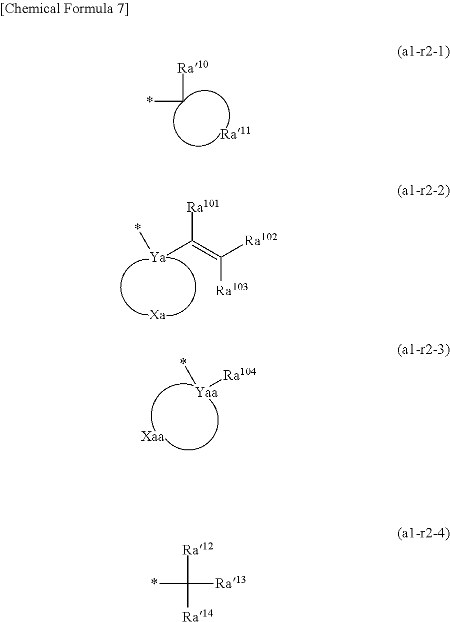

[In Formula (a1-r2-1). Ra′¹⁰ represents a linear or branched alkyl group having 1 to 12 carbon atoms, in which a part thereof may be substituted with a halogen atom or a heteroatom-containing group. Ra′¹¹ represents a group that forms an aliphatic cyclic group with the carbon atom to which Ra′¹⁰ has been bonded. In Formula (a1-r2-2), Ya represents a carbon atom. Xa represents a group that forms a cyclic hydrocarbon group with Ya. Some or all hydrogen atoms in this cyclic hydrocarbon group may be substituted. Ra¹⁰¹ to Ra¹⁰³ each independently represent a hydrogen atom, a chain-like monovalent saturated hydrocarbon group having 1 to 10 carbon atoms, or a monovalent aliphatic cyclic saturated hydrocarbon group having 3 to 20 carbon atoms. Some or all hydrogen atoms in the chain-like saturated hydrocarbon group and the aliphatic cyclic saturated hydrocarbon group may be substituted. Two or more of Ra¹⁰¹ to Ra¹⁰³ may be bonded to each other to form a cyclic structure. In Formula (a1-r2-3), Yaa represents a carbon atom. Xaa represents a group that forms an aliphatic cyclic group with Yaa. Ra¹⁰⁴ represents an aromatic hydrocarbon group which may have a substituent. In Formula (a1-r2-4), Ra′¹² and Ra′¹³ each independently represent a chain-like monovalent saturated hydrocarbon group having 1 to 10 carbon atoms. Some or all hydrogen atoms in this chain-like saturated hydrocarbon group may be substituted. Ra′¹⁴ represents a hydrocarbon group which may have a substituent. * represents a bonding site.]

In Formula (a1-r2-1), Ra′¹⁰ represents a linear or branched alkyl group having 1 to 12 carbon atoms, in which a part thereof may be substituted with a halogen atom or a heteroatom-containing group.

The linear alkyl group as Ra′¹⁰ has 1 to 12 carbon atoms, preferably 1 to 10 carbon atoms, and particularly preferably 1 to 5 carbon atoms.

Examples of the branched alkyl group as Ra′¹⁰ include those for Ra′³ described above.

The alkyl group in Ra′¹⁰ may be partially substituted with a halogen atom or a heteroatom-containing group. For example, some hydrogen atoms constituting the alkyl group may be substituted with a halogen atom or a heteroatom-containing group. Further, some carbon atoms (methylene group or the like) constituting the alkyl group may be substituted with a heteroatom-containing group.

Examples of the heteroatoms here include an oxygen atom, a nitrogen atom, and a sulfur atom. Examples of the heteroatom-containing group include (—O—), —C(═O)—O—, —O—C(═O)—, —C(═O)—, —O—C(═O)—O—, —C(═O)—NH—. —NH—, —S—, —S(═O)—, and —S(═O)₂—O—.

In Formula (a1-r2-1), preferred examples of Ra′¹¹ (an aliphatic cyclic group that is formed together with a carbon atom to which Ra′¹⁰ is bonded) include the groups exemplified as the aliphatic hydrocarbon group (alicyclic hydrocarbon group) which is a monocyclic group or a polycyclic group as Ra′³ in Formula (a1-r-1). Among these, a monocyclic alicyclic hydrocarbon group is preferable, specifically, a cyclopentyl group or a cyclohexyl group is more preferable, and a cyclopentyl group is still more preferable.

In Formula (a1-r2-2), examples of the cyclic hydrocarbon group that is formed by Xa together with Ya include a group in which one or more hydrogen atoms have been further removed from the cyclic monovalent hydrocarbon group (aliphatic hydrocarbon group) as Ra′³ in Formula (a1-r-1).

The cyclic hydrocarbon group that is formed by Xa together with Ya may have a substituent. Examples of the substituent include those exemplified as the substituents that the cyclic hydrocarbon group as Ra′³ may have.

In Formula (a1-r2-2), examples of the chain-like monovalent saturated hydrocarbon group having 1 to 10 carbon atoms as Ra¹⁰¹ to Ra¹⁰³ include a methyl group, an ethyl group, a propyl group, a butyl group, a pentyl group, a hexyl group, a heptyl group, an octyl group, and a decyl group.

Examples of the monovalent aliphatic cyclic saturated hydrocarbon group having 3 to 20 carbon atoms as Ra¹⁰¹ to Ra¹⁰¹ include a monocyclic aliphatic saturated hydrocarbon group such as a cyclopropyl group, a cyclobutyl group, a cyclopentyl group, a cyclohexyl group, a cycloheptyl group, a cyclooctyl group, a cyclodecyl group, or a cyclododecyl group; and a polycyclic aliphatic saturated hydrocarbon group such as a bicyclo[2.2.2]octanyl group, a tricyclo[5.2.1.02,6]decanyl group, a tricyclo[3.3.1.13,7] decanyl group, a tetracyclo[6.2.1.13,6.02,7]dodecanyl group, or an adamantyl group. From the viewpoint of ease of synthesis, Ra¹⁰¹ to Ra¹⁰³ represent preferably a hydrogen atom or a chain-like monovalent saturated hydrocarbon group having 1 to 10 carbon atoms, more preferably a hydrogen atom, a methyl group, or an ethyl group, and particularly preferably a hydrogen atom.

Examples of the substituent included in the chain-like saturated hydrocarbon group or the aliphatic cyclic saturated hydrocarbon group represented by Ra¹⁰¹ to Ra¹⁰³ include the same substituents as those for Ra^{x5}.

Examples of the group having a carbon-carbon double bond generated by two or more of Ra¹⁰¹ to Ra¹⁰³ being bonded to each other to form a cyclic structure include a cyclopentenyl group, a cyclohexenyl group, a methylcyclopentenyl group, a methylcyclohexenyl group, a cyclopentylidenethenyl group, and a cyclohexylidenethenyl group. Among these, from the viewpoint of ease of synthesis, a cyclopentenyl group, a cyclohexenyl group, or a cyclopentylidenethenyl group is preferable.

In Formula (a1-r2-3), as the aliphatic cyclic group that is formed by Xaa together with Yaa, the group exemplified as the aliphatic hydrocarbon group which is a monocyclic group or a polycyclic group as Ra′³ in Formula (a1-r-1) is preferable.

In Formula (a1-r2-3), examples of the aromatic hydrocarbon group as Ra¹⁰⁴ include a group in which one or more hydrogen atoms have been removed from an aromatic hydrocarbon ring having 5 to 30 carbon atoms. Among the examples, Ra¹⁰⁴ represents preferably a group in which one or more hydrogen atoms have been removed from an aromatic hydrocarbon ring having 6 to 15 carbon atoms, more preferably a group in which one or more hydrogen atoms have been removed from benzene, naphthalene, anthracene, or phenanthrene, still more preferably a group in which one or more hydrogen atoms have been removed from benzene, naphthalene, or anthracene, particularly preferably a group in which one or more hydrogen atoms have been removed from benzene or naphthalene, and most preferably a group in which one or more hydrogen atoms have been removed from benzene.

Examples of the substituent that Ra¹⁰⁴ in Formula (a1-r2-3) may have include a methyl group, an ethyl group, a propyl group, a hydroxy group, a carboxy group, a halogen atom, an alkoxy group (such as a methoxy group, an ethoxy group, a propoxy group, or a butoxy group), and an alkyloxycarbonyl group.

In Formula (a1-r2-4), Ra′¹² and Ra′¹³ each independently represent a chain-like monovalent saturated hydrocarbon group having 1 to 10 carbon atoms. Examples of the chain-like monovalent saturated hydrocarbon group having 1 to 10 carbon atoms as Ra′¹² and Ra′¹³ include those exemplified as the chain-like monovalent saturated hydrocarbon group having 1 to 10 carbon atoms as Ra¹⁰¹ to Ra¹⁰³. Some or all hydrogen atoms in this chain-like saturated hydrocarbon group may be substituted.

Ra′¹² and Ra′¹³ represent preferably a hydrogen atom or an alkyl group having 1 to 5 carbon atoms, more preferably an alkyl group having 1 to 5 carbon atoms, still more preferably a methyl group or an ethyl group, and particularly preferably a methyl group.

In a case where the chain-like saturated hydrocarbon group represented by Ra′¹² and Ra′¹³ is substituted, examples of the substituent thereof include the same substituents as those for R^{x5}.

In Formula (a1-r2-4), Ra′¹⁴ represents a hydrocarbon group which may have a substituent. Examples of the hydrocarbon group as Ra′¹⁴ include a linear or branched alkyl group and a cyclic hydrocarbon group.

The linear alkyl group as Ra′¹⁴ has preferably 1 to 5 carbon atoms, more preferably 1 to 4 carbon atoms, and still more preferably 1 or 2 carbon atoms. Specific examples thereof include a methyl group, an ethyl group, an n-propyl group, an n-butyl group, and an n-pentyl group. Among these, a methyl group, an ethyl group, or an n-butyl group is preferable, and a methyl group or an ethyl group is more preferable.

The branched alkyl group as Ra′¹⁴ has preferably 3 to 10 carbon atoms and more preferably 3 to 5 carbon atoms. Specific examples thereof include an isopropyl group, an isobutyl group, a tert-butyl group, an isopentyl group, a neopentyl group a 1,1-diethylpropyl group, and a 2,2-dimethylbutyl group. Among these, an isopropyl group is preferable.

In a case where Ra′¹⁴ represents a cyclic hydrocarbon group, the hydrocarbon group may be an aliphatic hydrocarbon group or an aromatic hydrocarbon group and may be a polycyclic group or a monocyclic group.

As the aliphatic hydrocarbon group which is a monocyclic group, a group in which one hydrogen atom has been removed from a monocycloalkane is preferable. The monocycloalkane has preferably 3 to 6 carbon atoms, and specific examples thereof include cyclopentane and cyclohexane.

As the aliphatic hydrocarbon group which is a polycyclic group, a group in which one hydrogen atom has been removed from a polycycloalkane is preferable. As the polycycloalkane, a group having 7 to 12 carbon atoms is preferable, and specific examples thereof include adamantane, norbornane, isobornane, tricyclodecane, and tetracyclododecane.

Examples of the aromatic hydrocarbon group as Ra′¹⁴ include the same groups as those for the aromatic hydrocarbon group as Ra¹⁰⁴. Among these, Ra′¹⁴ represents preferably a group in which one or more hydrogen atoms have been removed from an aromatic hydrocarbon ring having 6 to 15 carbon atoms, more preferably a group in which one or more hydrogen atoms have been removed from benzene, naphthalene, anthracene, or phenanthrene, still more preferably a group in which one or more hydrogen atoms have been removed from benzene, naphthalene, or anthracene, particularly preferably a group in which one or more hydrogen atoms have been removed from naphthalene or anthracene, and most preferably a group in which one or more hydrogen atoms have been removed from naphthalene.

Examples of the substituent that Ra′¹⁴ may have include the same groups as those for the substituent that Ra¹⁰⁴ may have.

In a case where Ra′¹⁴ in Formula (a1-r2-4) represents a naphthyl group, the position bonded to the tertiary carbon atom in Formula (a1-r2-4) may be the 1-position or the 2-position of the naphthyl group.

In a case where Ra′¹⁴ in Formula (a1-r2-4) represents an anthryl group, the position bonded to the tertiary carbon atom in Formula (a1-r2-4) may be the 1-position, the 2-position, or the 9-position of the anthryl group.

Specific examples of the group represented by Formula (a1-r2-1) are shown below.

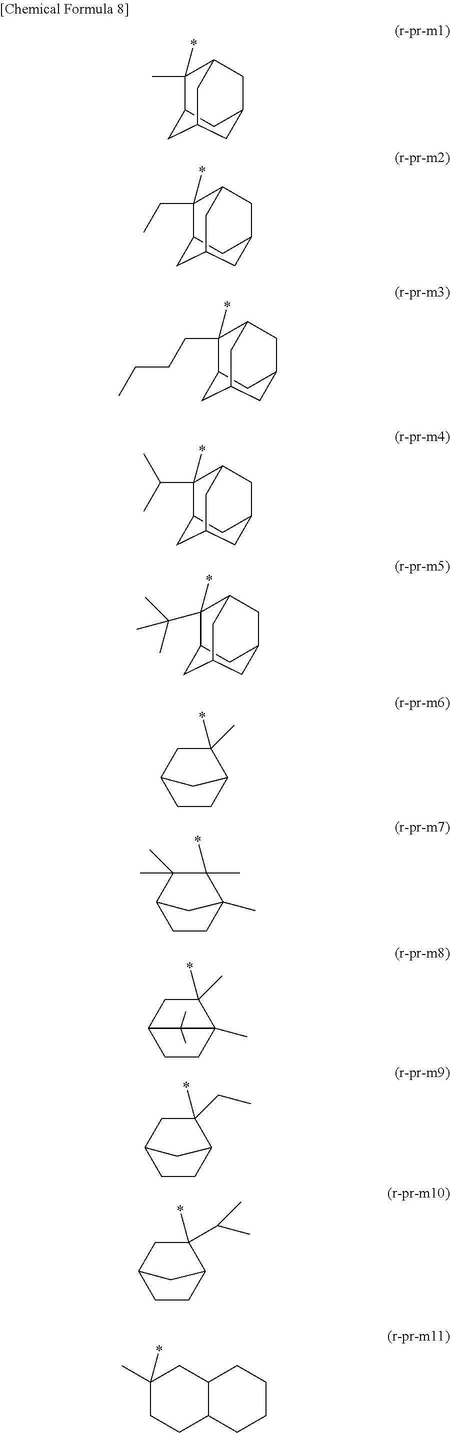

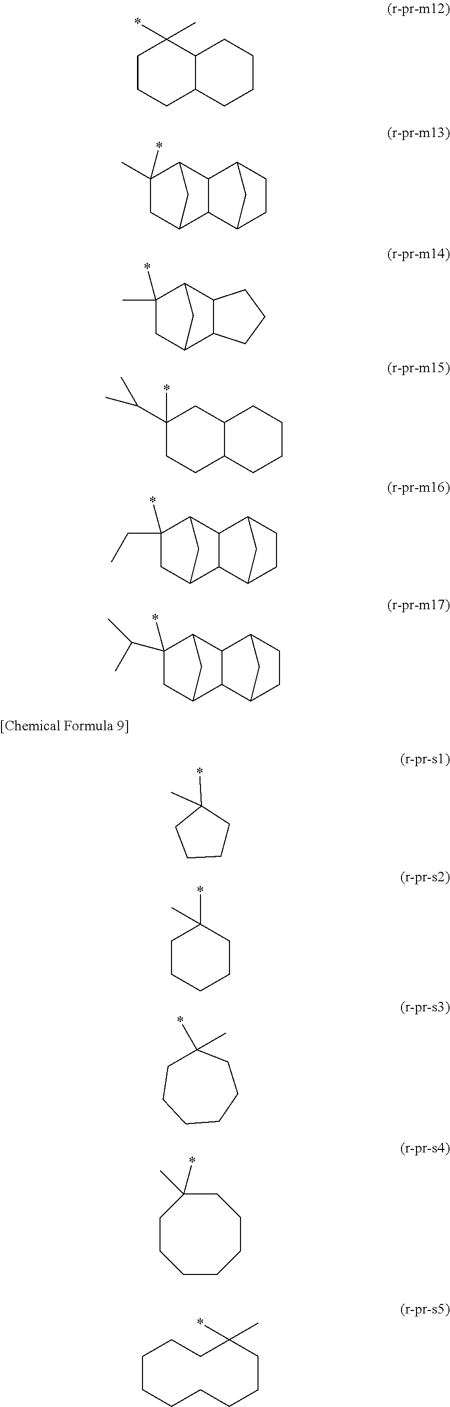

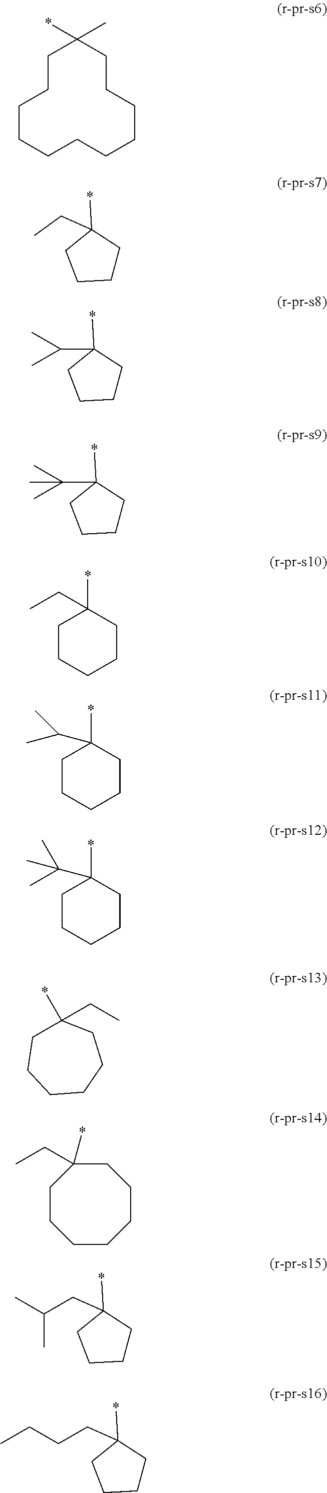

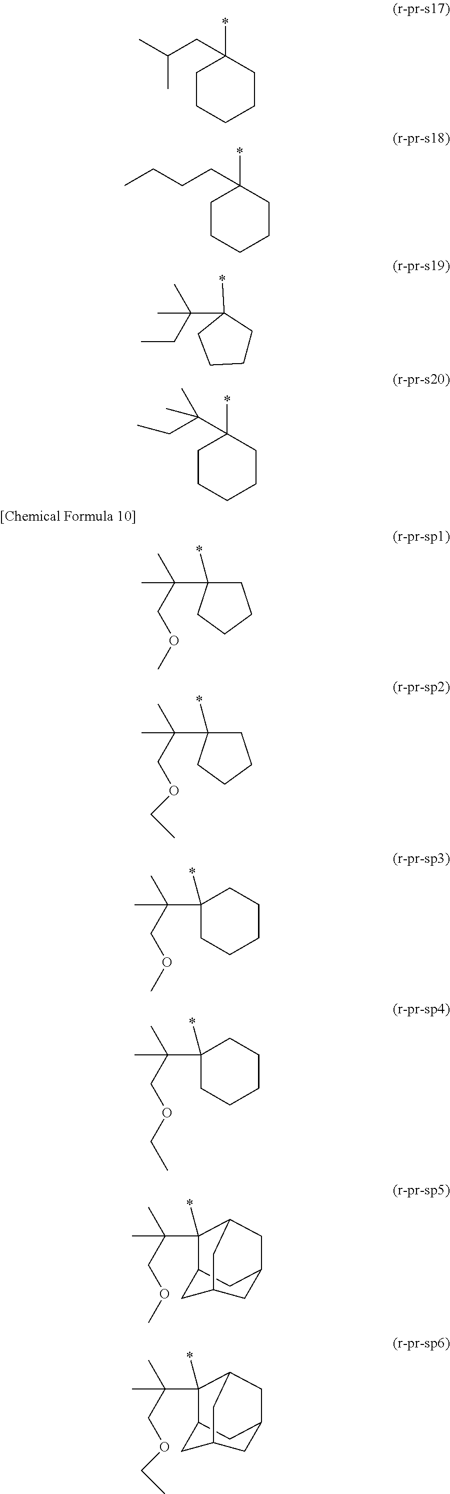

Specific examples of the group represented by Formula (a1-r2-2) are shown below.

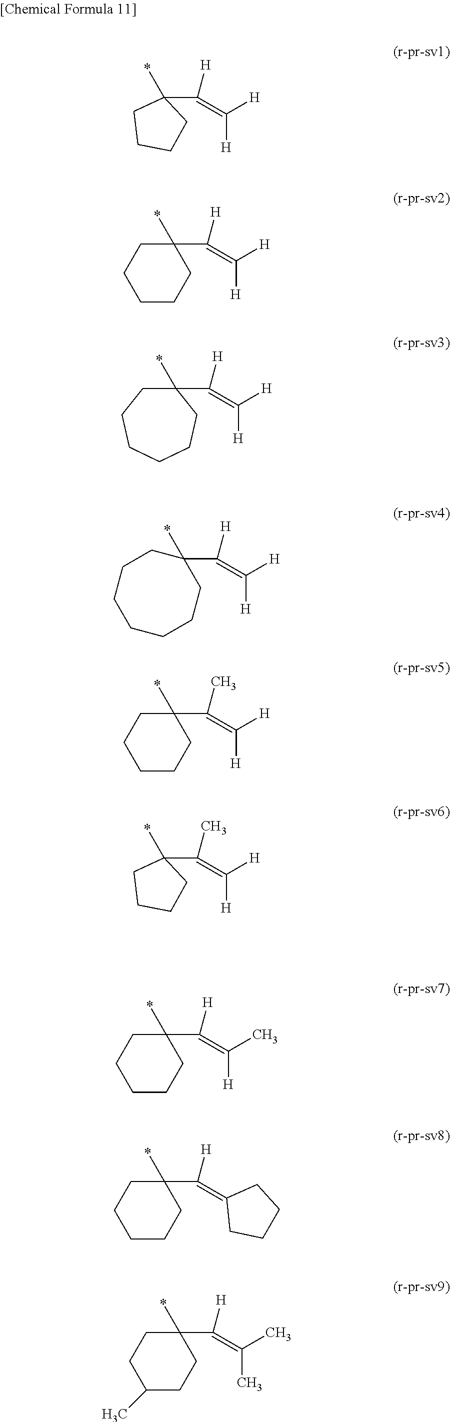

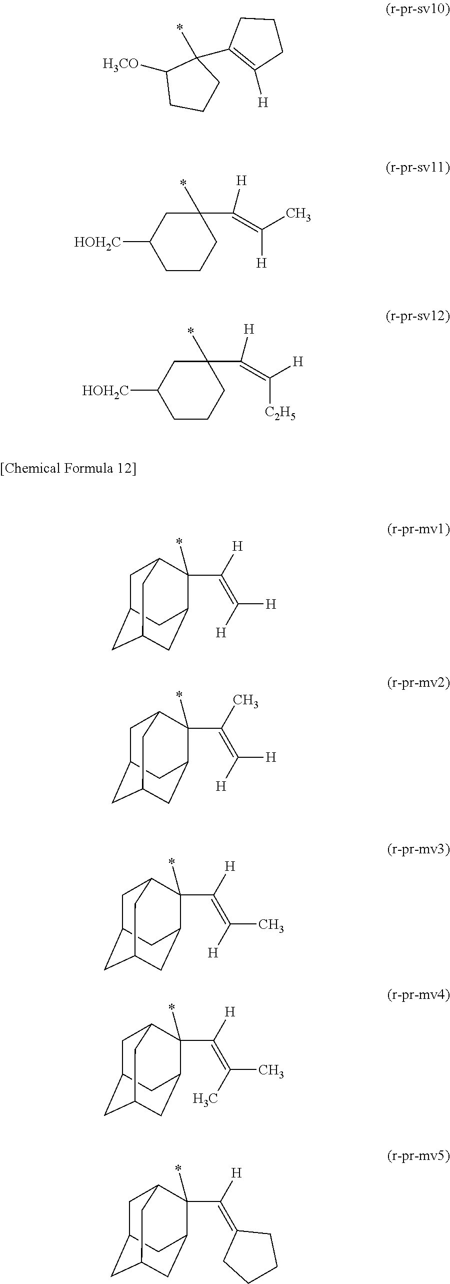

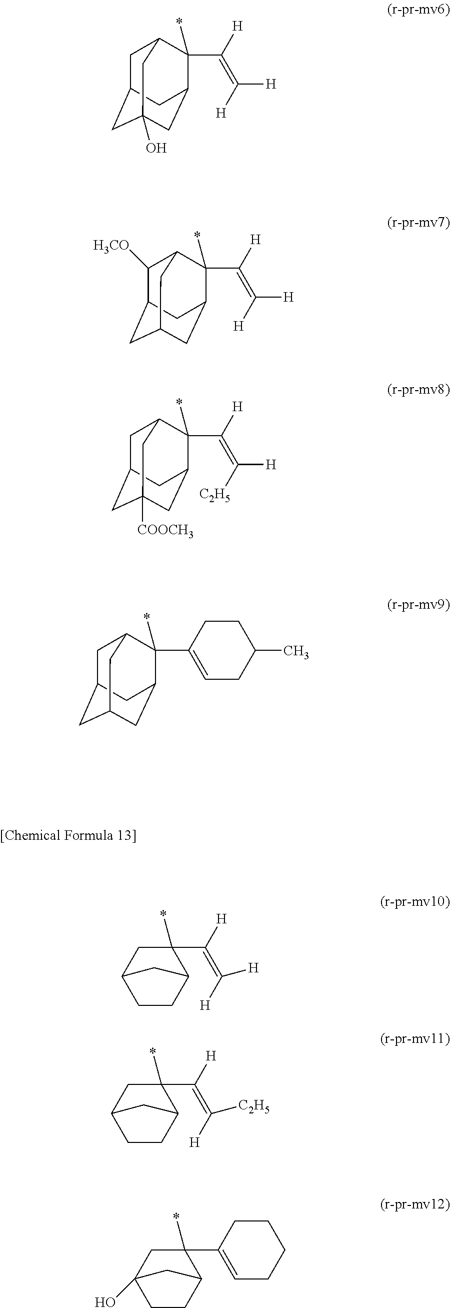

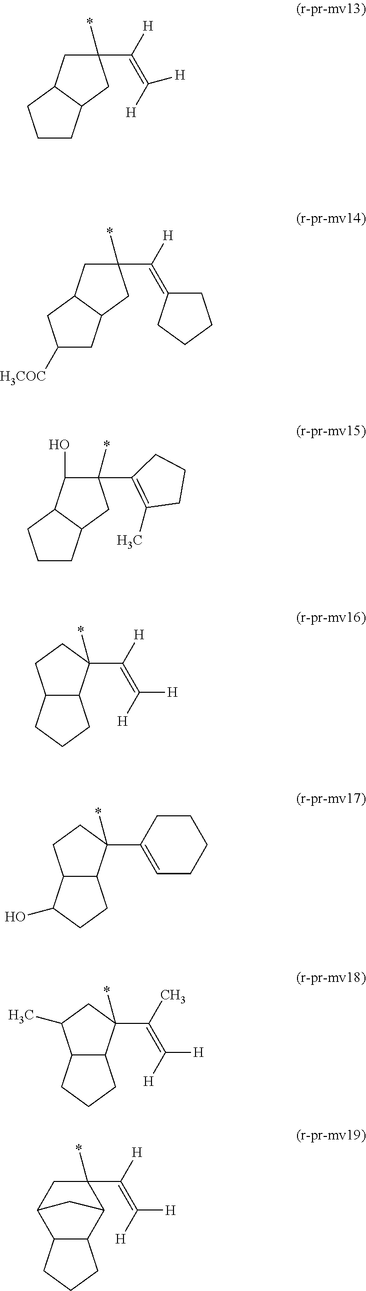

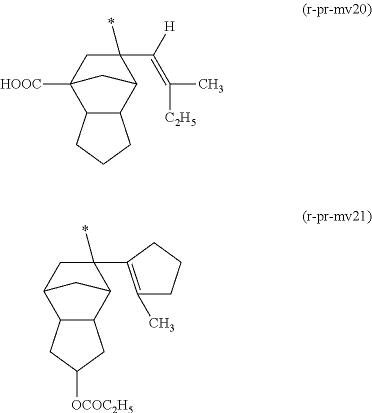

Specific examples of the group represented by Formula (a1-r2-3) are shown below.

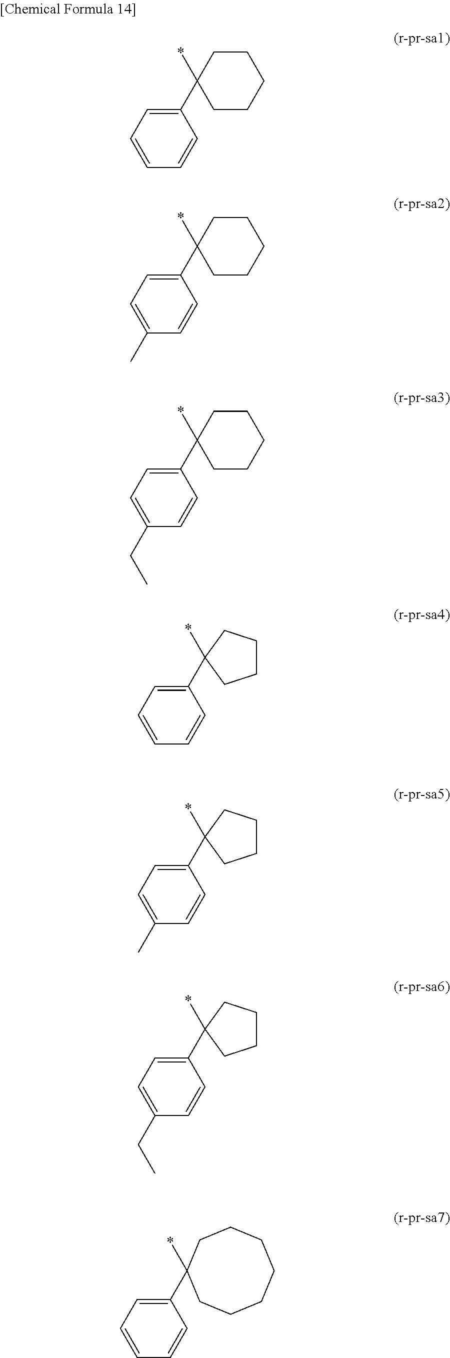

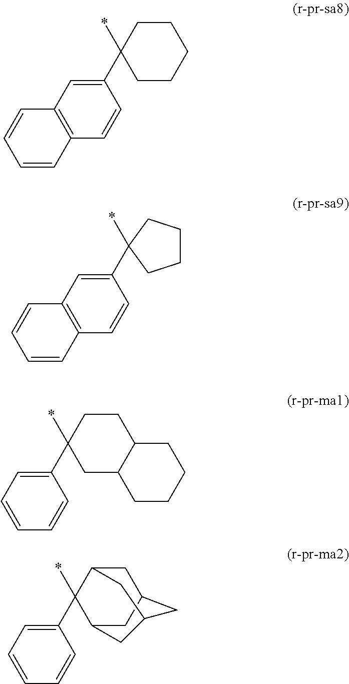

Specific examples of the group represented by Formula (a1-r2-4) are shown below.

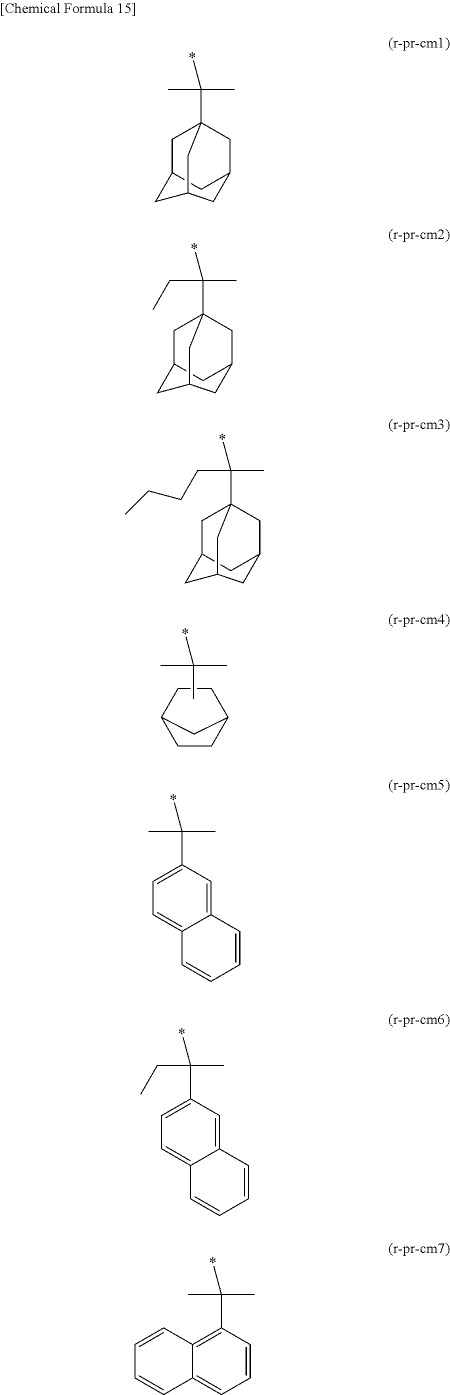

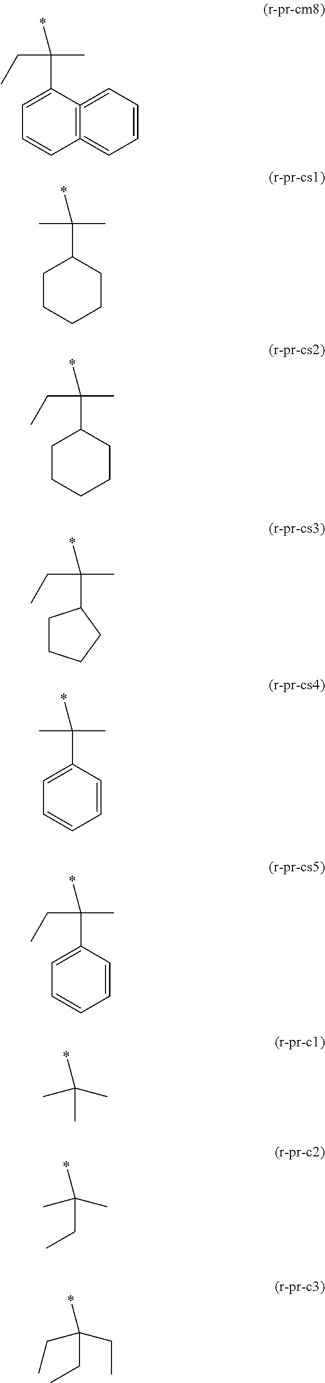

### Tertiary Alkyloxycarbonyl Acid Dissociable Group:

Examples of the acid dissociable group that protects a hydroxyl group among the polar groups include an acid dissociable group (hereinafter, also referred to as “tertiary alkyloxycarbonyl acid dissociable group” for convenience) represented by General Formula (a1-r-3).

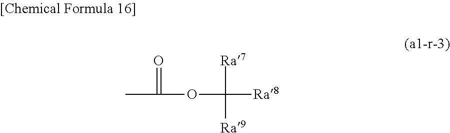

[In the formula, Ra′⁷ to Ra′⁹ each represent an alkyl group.]

In Formula (a1-r-3), Ra′⁷ to Ra′⁹ each represent preferably an alkyl group having 1 to 5 carbon atoms and more preferably an alkyl group having 1 to 3 carbon atoms.

Further, the total number of carbon atoms in each alkyl group is preferably in a range of 3 to 7, more preferably in a range of 3 to 5, and most preferably 3 or 4.

Examples of the constitutional unit (a1) include a constitutional unit derived from acrylic acid ester in which the hydrogen atom bonded to the carbon atom at the α-position may be substituted with a substituent; a constitutional unit derived from acrylamide; a constitutional unit in which at least some hydrogen atoms in a hydroxyl group of a constitutional unit derived from hydroxystyrene or a hydroxystyrene derivative are protected by a substituent containing the acid decomposable group; and a constitutional unit in which at least some hydrogen atoms in —C(═O)—OH of a constitutional unit derived from vinylbenzoic acid or a vinylbenzoic acid derivative are protected by a substituent containing the acid decomposable group.

Among the examples, as the constitutional unit (a1), a constitutional unit derived from acrylic acid ester in which the hydrogen atom bonded to the carbon atom at the α-position may be substituted with a substituent is preferable.

Specific preferred examples of such a constitutional unit (a1) include constitutional units represented by General Formula (a1-1) or (a1-2) shown below.

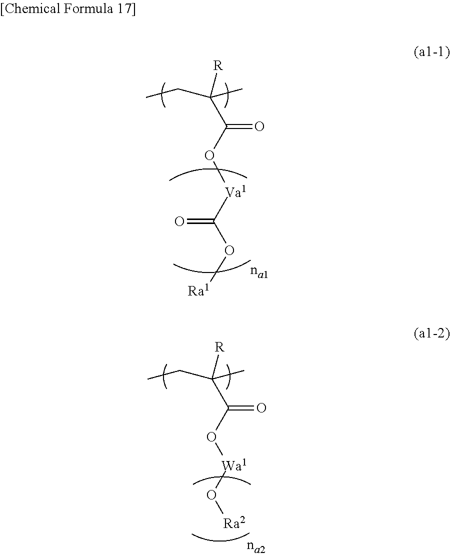

[In the formulae, R represents a hydrogen atom, an alkyl group having 1 to 5 carbon atoms, or a halogenated alkyl group having 1 to 5 carbon atoms. Va¹ represents a divalent hydrocarbon group which may have an ether bond. nₐ₁ represents an integer of 0 to 2. Ra¹ represents an acid dissociable group represented by General Formula (a1-r-1) or (a1-r-2). Wa¹ represents a (nₐ₂+1)-valent hydrocarbon group, nₐ₂ represents an integer of 1 to 3, and Ra² represents an acid dissociable group represented by General Formula (a1-r-1) or (a1-r-3).]

In Formula (a1-1), as the alkyl group having 1 to 5 carbon atoms as R, a linear or branched alkyl group having 1 to 5 carbon atoms is preferable, and specific examples thereof include a methyl group, an ethyl group, a propyl group, an isopropyl group, an n-butyl group, an isobutyl group, a tert-butyl group, a pentyl group, an isopentyl group, and a neopentyl group. The halogenated alkyl group having 1 to 5 carbon atoms is a group in which some or all hydrogen atoms in the alkyl group having 1 to 5 carbon atoms have been substituted with halogen atoms. As the halogen atom, a fluorine atom is particularly preferable.

R represents preferably a hydrogen atom, an alkyl group having 1 to 5 carbon atoms, or a fluorinated alkyl group having 1 to 5 carbon atoms and most preferably a hydrogen atom or a methyl group from the viewpoint of the industrial availability.

In Formula (a1-1), the divalent hydrocarbon group as Va¹ may be an aliphatic hydrocarbon group or an aromatic hydrocarbon group.

The aliphatic hydrocarbon group as the divalent hydrocarbon group represented by Va¹ may be saturated or unsaturated. In general, it is preferable that the aliphatic hydrocarbon group is saturated.

More specific examples of the aliphatic hydrocarbon group include a linear or branched aliphatic hydrocarbon group and an aliphatic hydrocarbon group having a ring in the structure thereof.

The linear aliphatic hydrocarbon group has preferably 1 to 10 carbon atoms, more preferably 1 to 6 carbon atoms, still more preferably 1 to 4 carbon atoms, and most preferably 1 to 3 carbon atoms.

As the linear aliphatic hydrocarbon group, a linear alkylene group is preferable, and specific examples thereof include a methylene group [—CH₂—], an ethylene group [—(CH₂)₂—], a trimethylene group [—(CH₂)₃—], a tetramethylene group [—(CH₂)₄—], and a pentamethylene group [—(CH₂)—].

The branched aliphatic hydrocarbon group has preferably 2 to 10 carbon atoms, more preferably 3 to 6 carbon atoms, still more preferably 3 or 4 carbon atoms, and most preferably 3 carbon atoms.

As the branched aliphatic hydrocarbon group, a branched alkylene group is preferable, and specific examples thereof include alkylalkylene groups, for example, alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂— and —CH₂CH(CH₃)CH₂—; and alkyltetramethylene groups such as —CH(CH₃)CH₂CH₂CH₂— and —CH₂CH(CH₃)CH₂CH₂—. As the alkyl group in the alkylalkylene group, a linear alkyl group having 1 to 5 carbon atoms is preferable.

Examples of the aliphatic hydrocarbon group having a ring in the structure thereof include an alicyclic hydrocarbon group (a group in which two hydrogen atoms have been removed from an aliphatic hydrocarbon ring), a group in which the alicyclic hydrocarbon group is bonded to the terminal of the linear or branched aliphatic hydrocarbon group, and a group in which the alicyclic hydrocarbon group is interposed in the middle of the linear or branched aliphatic hydrocarbon group. Examples of the linear or branched aliphatic hydrocarbon group include the same groups as those for the linear aliphatic hydrocarbon group or the branched aliphatic hydrocarbon group.

The alicyclic hydrocarbon group has preferably 3 to 20 carbon atoms and more preferably 3 to 12 carbon atoms.

The alicyclic hydrocarbon group may be monocyclic or polycyclic. As the monocyclic alicyclic hydrocarbon group, a group in which two hydrogen atoms have been removed from a monocycloalkane is preferable. The monocycloalkane has preferably 3 to 6 carbon atoms, and specific examples thereof include cyclopentane and cyclohexane. As the polycyclic alicyclic hydrocarbon group, a group in which two hydrogen atoms have been removed from a polycycloalkane is preferable. As the polycycloalkane, a group having 7 to 12 carbon atoms is preferable. Specific examples thereof include adamantane, norbornane, isobornane, tricyclodecane, and tetracyclododecane.

The aromatic hydrocarbon group as the divalent hydrocarbon group represented by Va¹ is a hydrocarbon group having an aromatic ring.

The aromatic hydrocarbon group has preferably 3 to 30 carbon atoms, more preferably 5 to 30 carbon atoms, still more preferably 5 to 20 carbon atoms, particularly preferably 6 to 15 carbon atoms, and most preferably 6 to 12 carbon atoms. Here, the number of carbon atoms in a substituent is not included in the number of carbon atoms.

Specific examples of the aromatic ring contained in the aromatic hydrocarbon group include aromatic hydrocarbon rings such as benzene, biphenyl, fluorene, naphthalene, anthracene, and phenanthrene; and aromatic heterocyclic rings in which some carbon atoms constituting the above-described aromatic hydrocarbon rings have been substituted with heteroatoms. Examples of the heteroatom in the aromatic heterocyclic rings include an oxygen atom, a sulfur atom, and a nitrogen atom.

Specific examples of the aromatic hydrocarbon group include a group in which two hydrogen atoms have been removed from the above-described aromatic hydrocarbon ring (an arylene group); and a group in which one hydrogen atom of a group (an aryl group) formed by removing one hydrogen atom from the aromatic hydrocarbon ring has been substituted with an alkylene group (for example, a group formed by further removing one more hydrogen atom from an aryl group in an arylalkyl group such as a benzyl group, a phenethyl group, a 1-naphthylmethyl group, a 2-naphthylmethyl group, a 1-naphthylethyl group, or a 2-naphthylethyl group). The alkylene group (alkyl chain in the arylalkyl group) has preferably 1 to 4 carbon atoms, more preferably 1 or 2 carbon atoms, and particularly preferably 1 carbon atom.

In Formula (a1-1), Ra¹ represents an acid dissociable group represented by Formula (a1-r-1) or (a1-r-2).

In Formula (a1-2), the (nₐ₂+1)-valent hydrocarbon group as Wa¹ may be an aliphatic hydrocarbon group or an aromatic hydrocarbon group. The aliphatic hydrocarbon group indicates a hydrocarbon group that has no aromaticity and may be saturated or unsaturated. In general, it is preferable that the aliphatic hydrocarbon group is saturated. Examples of the aliphatic hydrocarbon group include a linear or branched aliphatic hydrocarbon group, an aliphatic hydrocarbon group having a ring in the structure thereof, and a group obtained by combining the linear or branched aliphatic hydrocarbon group and the aliphatic hydrocarbon group having a ring in the structure thereof.

The valency of nₐ₂+1 is preferably divalent to tetravalent and more preferably divalent or trivalent.

In the Formula (a1-2), Ra² represents an acid dissociable group represented by General Formula (a1-r-1) or (a1-r-3).

Specific examples of the constitutional unit represented by Formula (a1-1) are shown below. In the formulae shown below, R^{a} represents a hydrogen atom, a methyl group, or a trifluoromethyl group.

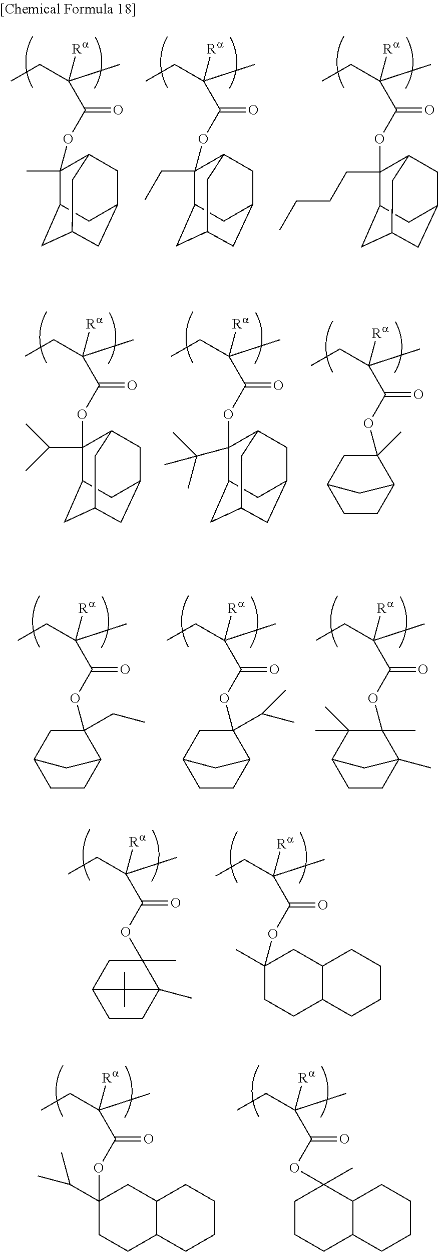

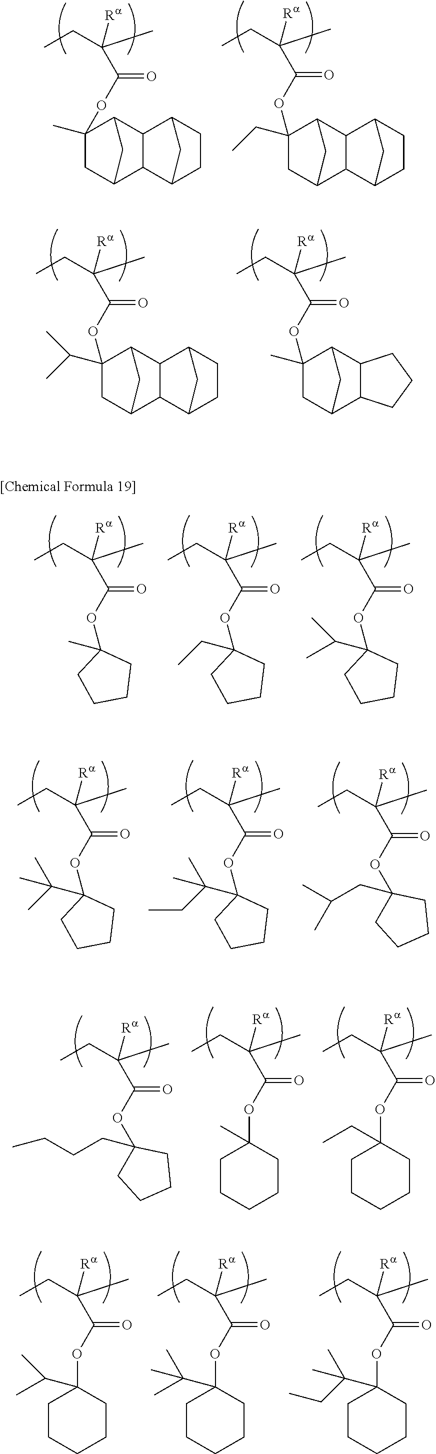

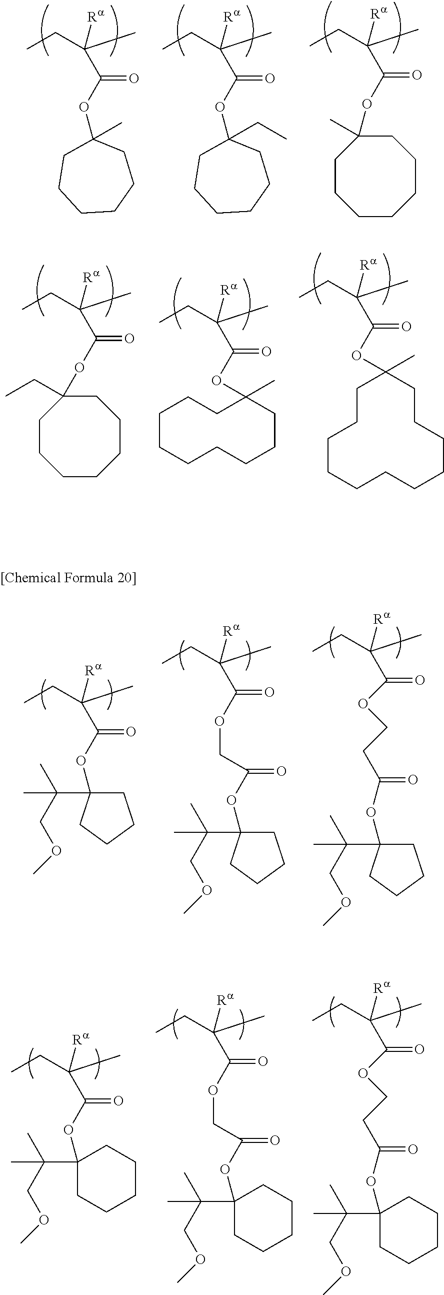

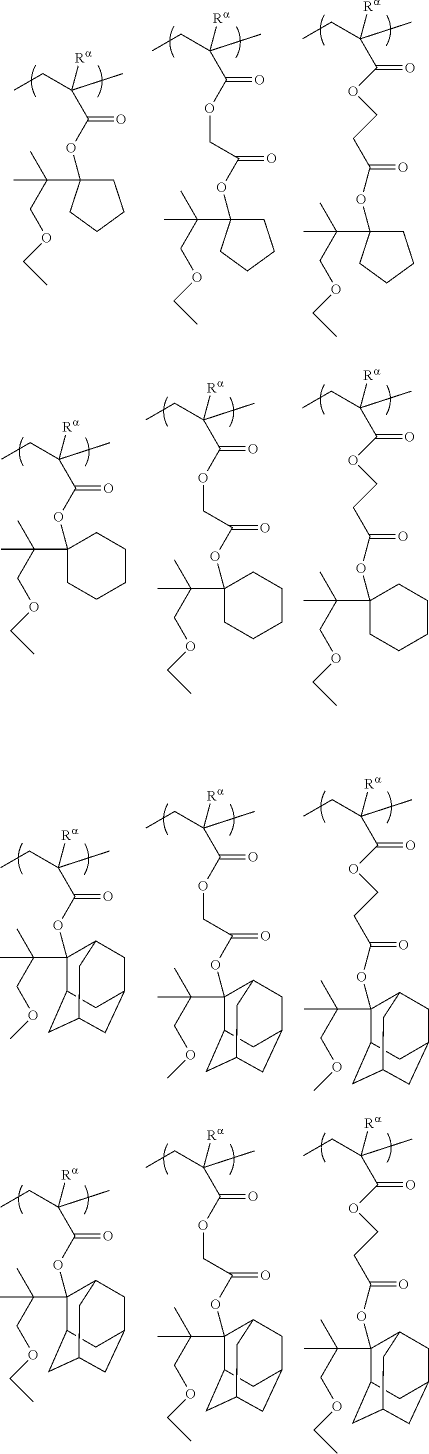

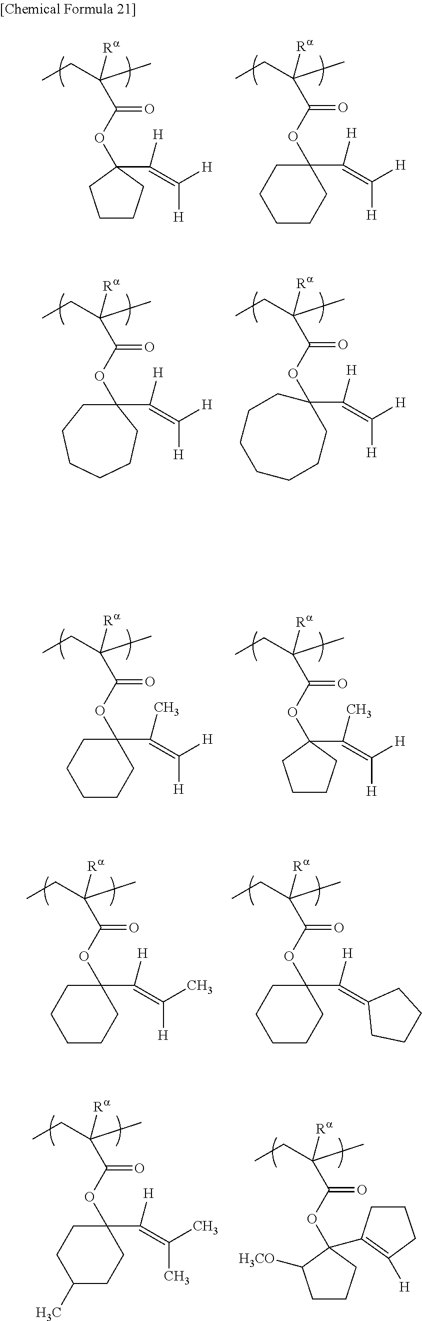

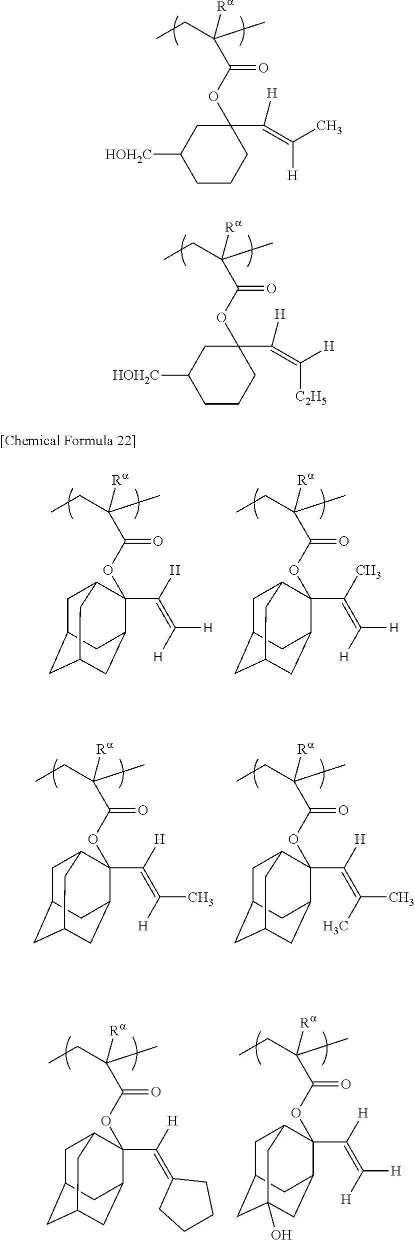

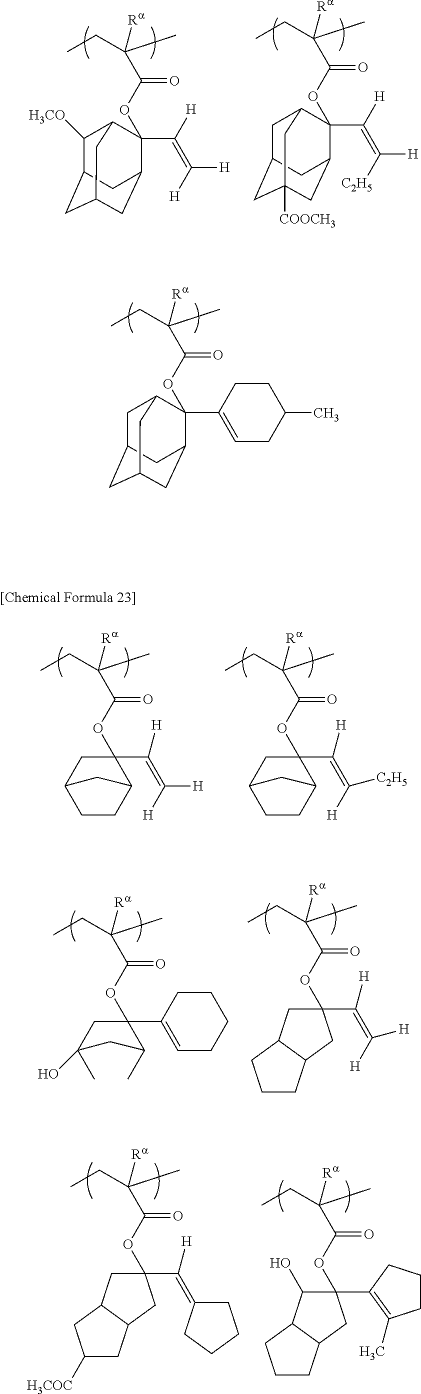

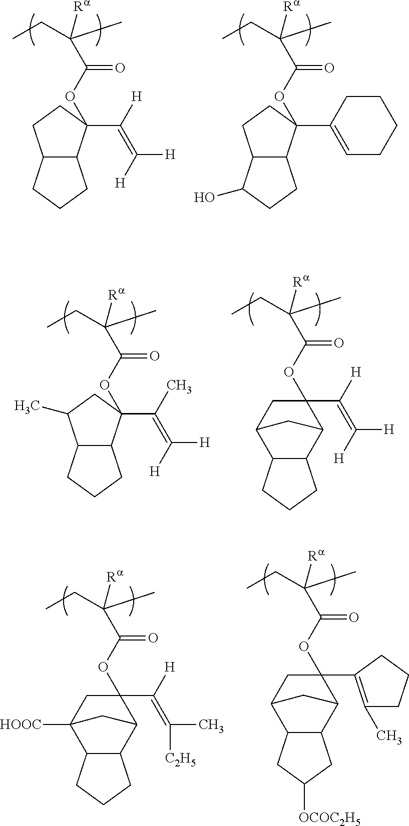

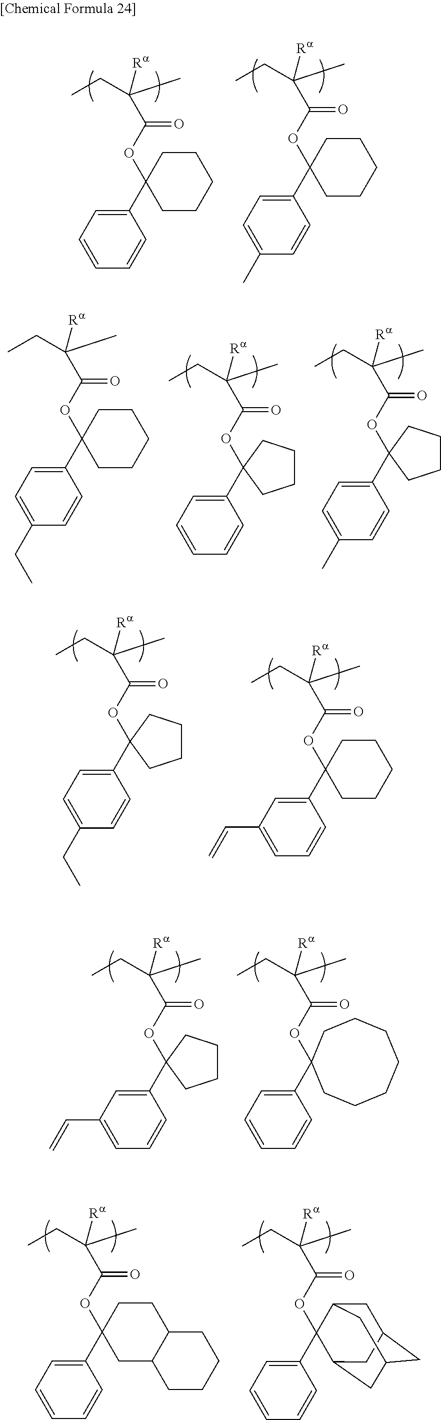

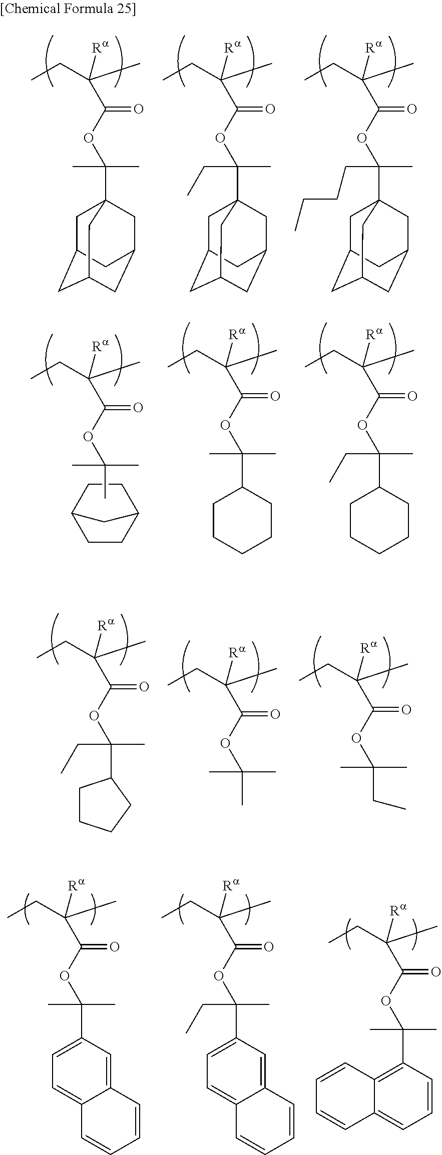

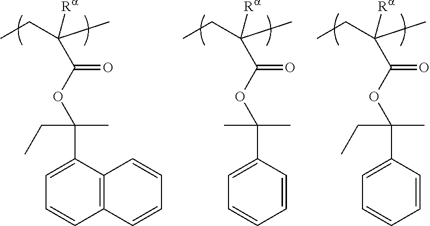

The constitutional unit (a1) included in the component (A1) may be used alone or two or more kinds thereof.

A constitutional unit represented by Formula (a1-1) is more preferable as the constitutional unit (a1).

Among the examples, as the constitutional unit (a1), those having a constitutional unit represented by General Formula (a1-1-1) are particularly preferable.

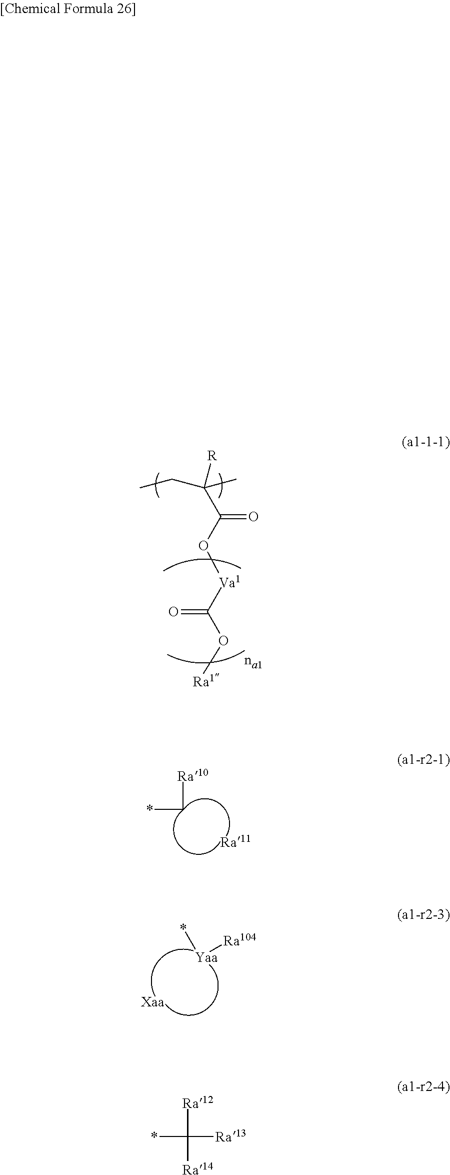

[In the formulae, Ra¹″ represents an acid dissociable group represented by General Formula (a1-r2-1), (a1-r2-3), or (a1-r2-4).]R, Va¹, and nₐ₁ in Formula (a1-1-1) each have the same definition as that for R, Va¹, and nₐ₁ in Formula (a1-1).

The description of the acid dissociable group represented by General Formula (a1-r2-1), (a1-r2-3), or (a1-r2-4) is the same as described above.

In Formula (a1-1-1), among the examples, it is preferable that Ra¹″ represents an acid dissociable group represented by General Formula (a1-r2-1) or (a1-r2-4).

The proportion of the constitutional unit (a1) in the component (A1) is preferably in a range of 5% to 60% by mole, more preferably in a range of 10% to 55% by mole, still more preferably in a range of 15% to 50% by mole, and particularly preferably in a range of 20% to 45% by mole with respect to the total amount (100% by mole) of all constitutional units constituting the component (A1).

By setting the proportion of the constitutional unit (a1) to be greater than or equal to the lower limits of the above-described preferable ranges, lithography characteristics of enhancement of the sensitivity and the resolution and reduction of the roughness are improved. Further, in a case where the proportion of the constitutional unit (a1) is less than or equal to the upper limits of the above-described preferable ranges, the constitutional unit (a1) and other constitutional units can be balanced, and the lithography characteristics are improved.

In Regard to Constitutional Unit (a10):

The constitutional unit (a10) is a constitutional unit represented by General Formula (a10-1).

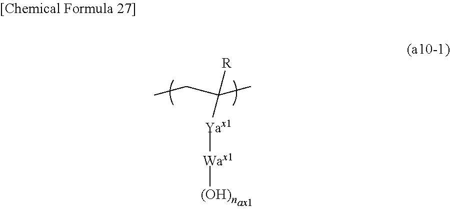

[In the formulae, R represents a hydrogen atom, an alkyl group having 1 to 5 carbon atoms, or a halogenated alkyl group having 1 to 5 carbon atoms. Ya^{x1} represents a single bond or a divalent linking group. Wa^{x1} represents an aromatic hydrocarbon group which may have a substituent. nₐₓ₁ represents an integer of 1 or greater.]

In the Formula (a10-1), R represents a hydrogen atom, an alkyl group having 1 to 5 carbon atoms, or a halogenated alkyl group having 1 to 5 carbon atoms.

R represents preferably a hydrogen atom, an alkyl group having 1 to 5 carbon atoms, or a fluorinated alkyl group having 1 to 5 carbon atoms, and from the viewpoint of industrial availability, more preferably a hydrogen atom, a methyl group, or trifluoromethyl group, still more preferably a hydrogen atom or a methyl group, and particularly preferably a hydrogen atom.

In Formula (a10-1), Ya^{x1} represents a single bond or a divalent linking group.

In the chemical formula, the divalent linking group as Ya^{x1} is not particularly limited, and suitable examples thereof include a divalent hydrocarbon group which may have a substituent and a divalent linking group having a heteroatom.

Ya^{x1} represents preferably a single bond, an ester bond [—C(═O)—O— or —O—C(═O)—], an ether bond (—O—), a linear or branched alkylene group, or a combination thereof and more preferably a single bond or an ester bond [—C(═O)—O— or —O—C(═O)—].

In Formula (a10-1), Wa^{x1} represents an aromatic hydrocarbon group which may have a substituent.

Examples of the aromatic hydrocarbon group as Wa^{x1} include a group in which (nₐₓ₁+1) hydrogen atoms have been removed from an aromatic ring which may have a substituent. The aromatic ring is not particularly limited as long as the aromatic ring is a cyclic conjugated system having (4n+2) n electrons. The aromatic ring has preferably 5 to 30 carbon atoms, more preferably 5 to 20 carbon atoms, still more preferably 6 to 15 carbon atoms, and particularly preferably 6 to 12 carbon atoms. Specific examples of the aromatic ring include aromatic hydrocarbon rings such as benzene, naphthalene, anthracene, and phenanthrene; and an aromatic heterocyclic ring obtained by substituting some carbon atoms constituting the above-described aromatic hydrocarbon ring with a heteroatom. Examples of the heteroatom in the aromatic heterocyclic rings include an oxygen atom, a sulfur atom, and a nitrogen atom. Specific examples of the aromatic heterocyclic ring include a pyridine ring and a thiophene ring.

Further, examples of the aromatic hydrocarbon group as Wa^{x1} also include a group in which (nₐₓ₁+1) hydrogen atoms have been removed from an aromatic compound having an aromatic ring (for example, biphenyl or fluorene) which may have two or more substituents.

Among the examples, Wa^{x1} represents preferably a group in which (nₐₓ₁+1) hydrogen atoms have been removed from benzene, naphthalene, anthracene, or biphenyl, more preferably a group in which (nₐₓ₁+1) hydrogen atoms have been removed from benzene or naphthalene, and still more preferably a group in which (nₐₓ₁+1) hydrogen atoms have been removed from benzene.

The aromatic hydrocarbon group as Wa^{x1} may or may not have a substituent. Examples of substituents include an alkyl group, an alkoxy group, a halogen atom, and a halogenated alkyl group. Examples of the alkyl group, the alkoxy group, the halogen atom, and the halogenated alkyl group as the substituent include those described as the substituent of the cyclic aliphatic hydrocarbon group as Ya^{x1}. The substituent is preferably a linear or branched alkyl group having 1 to 5 carbon atoms, more preferably a linear or branched alkyl group having 1 to 3 carbon atoms, still more preferably an ethyl group or a methyl group, and particularly preferably a methyl group. It is preferable that the aromatic hydrocarbon group as Wa^{x1} has no substituent.

In Formula (a10-1), nₐₓ₁ represents an integer of 1 or greater, preferably an integer of 1 to 10, more preferably an integer of 1 to 5, still more preferably 1, 2, or 3, and particularly preferably 1 or 2.

Specific examples of the constitutional unit (a10) represented by Formula (a10-1) are described below.

In the formulae shown below, R^{α} represents a hydrogen atom, a methyl group, or a trifluoromethyl group.

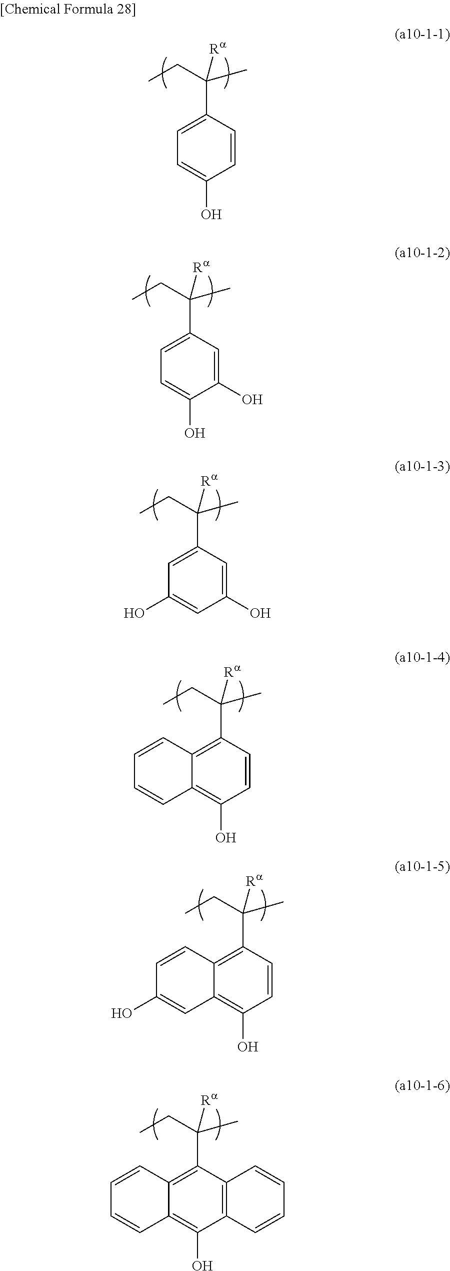

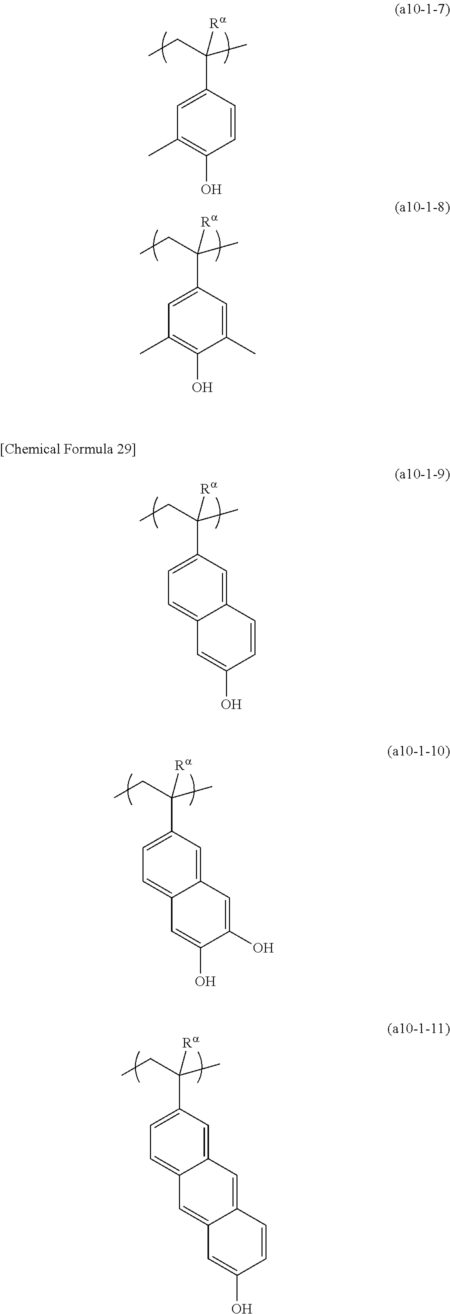

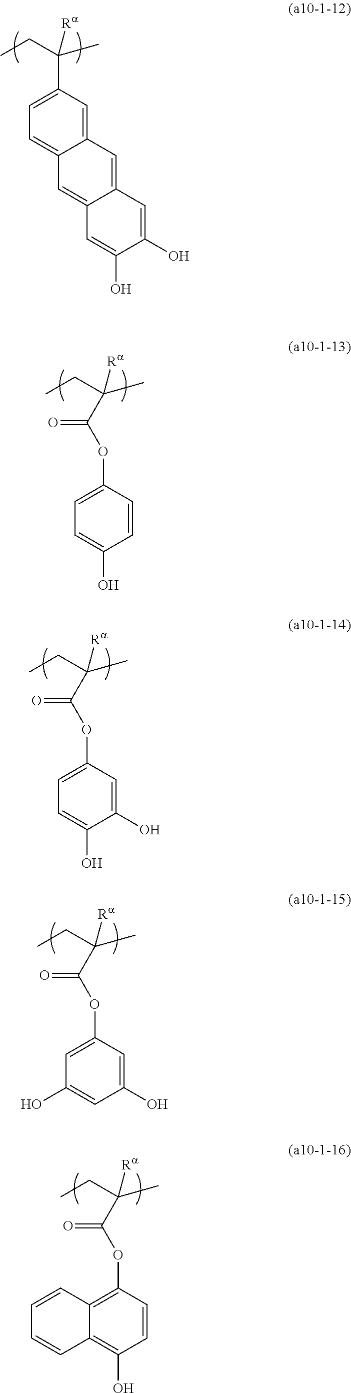

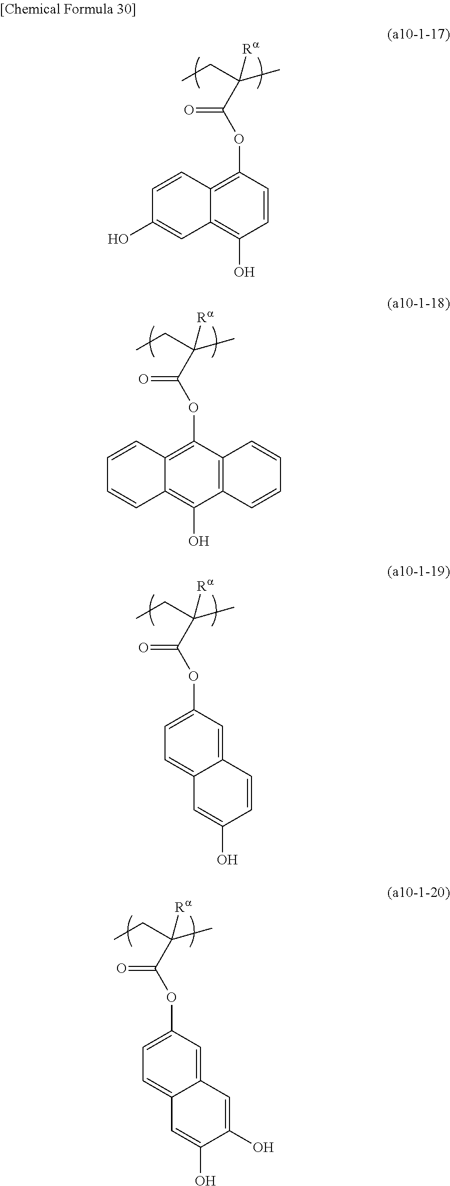

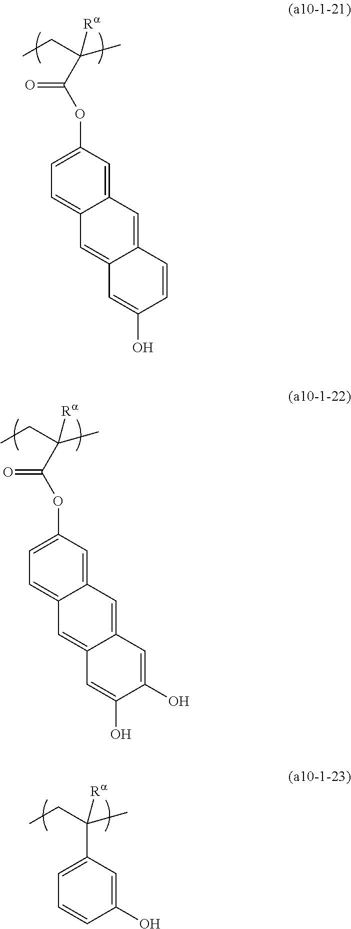

The constitutional unit (a10) included in the component (A1) may be used alone or two or more kinds thereof.

The proportion of the constitutional unit (a10) in the component (A1) is preferably in a range of 15% to 60% by mole, more preferably in a range of 20% to 55% by mole, still more preferably in a range of 25% to 50% by mole, and particularly preferably in a range of 30% to 45% by mole with respect to the total amount (100% by mole) of all constitutional units constituting the component (A1).

In a case where the proportion of the constitutional unit (a10) is set to be greater than or equal to the above-described lower limits, the shape of the resist pattern is likely to be enhanced. Meanwhile, in a case where the proportion thereof is set to be less than or equal to the above-described upper limits, the transmittance of the resist film is improved, the sensitivity even in a thick resist pattern is likely to be enhanced, and a resist pattern having a satisfactory shape is likely to be formed.

### In Regard to Constitutional Unit (a5):

The constitutional unit (a5) is a constitutional unit represented by General Formula (a5-1).

In a case where the component (A1) has the constitutional unit (a5), the light transmittance of the resist film can be increased as compared with a case where the component (A) has a constitutional unit containing an aromatic cyclic group. Further, the dry etching resistance of the formed resist pattern is improved, and in addition, the hydrophobicity of the component (A) is increased. The improvement in hydrophobicity contributes to the improvement in resolution, resist pattern shape, and the like, particularly in the case of forming a resist pattern by a solvent developing process.

The term “acid non-dissociable cyclic group” in the constitutional unit (a5) is a cyclic group that remains in the constitutional unit without being dissociated even in a case of an action of an acid during generation (for example, during generation of an acid from the component (B) described below) in the resist composition upon light exposure.

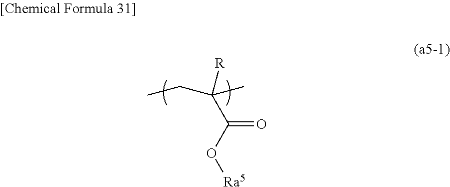

[In the formula, R represents a hydrogen atom, an alkyl group having 1 to 5 carbon atoms, or a halogenated alkyl group having 1 to 5 carbon atoms. Ra⁵ represents an acid non-dissociable aliphatic cyclic group in which some carbon atoms forming a ring skeleton may be substituted with oxygen atoms.]

In Formula (a5-1), as the alkyl group having 1 to 5 carbon atoms as R, a linear or branched alkyl group having 1 to 5 carbon atoms is preferable, and specific examples thereof include a methyl group, an ethyl group, a propyl group, an isopropyl group, an n-butyl group, an isobutyl group, a tert-butyl group, a pentyl group, an isopentyl group, and a neopentyl group. The halogenated alkyl group having 1 to 5 carbon atoms is a group in which some or all hydrogen atoms in the alkyl group having 1 to 5 carbon atoms have been substituted with halogen atoms. As the halogen atom, a fluorine atom is particularly preferable.

R represents preferably a hydrogen atom, an alkyl group having 1 to 5 carbon atoms, or a fluorinated alkyl group having 1 to 5 carbon atoms, more preferably a hydrogen atom or a methyl group, and still more preferably a hydrogen atom.

In Formula (a5-1), the acid non-dissociable aliphatic cyclic group as Ra⁵ may be a monocyclic group or a polycyclic group and is preferably a monocyclic group.

In this case, as the monocyclic group, a group in which one or more hydrogen atoms have been removed from a monocycloalkane is preferable. The monocycloalkane has more preferably 3 to 8 carbon atoms and still more preferably 5 to 8 carbon atoms, and specific examples thereof include cyclopentane, cyclohexane, and cyclooctane. In this case, a group in which one or more hydrogen atoms have been removed from a polycycloalkane is preferable as the polycyclic group. As the polycycloalkane, a group having 7 to 12 carbon atoms is preferable, and specific examples thereof include adamantane, norbornane, isobornane, tricyclodecane, and tetracyclododecane.

The monocyclic group and the polycyclic group each may have as a substituent, for example, a linear or branched alkyl group having 1 to 5 carbon atoms.

In Formula (a5-1), the acid non-dissociable aliphatic cyclic group as Ra⁵ may be formed such that some carbon atoms forming a ring skeleton are substituted with oxygen atoms. Examples of the acid non-dissociable aliphatic cyclic group in which some carbon atoms forming a ring skeleton are substituted with oxygen atoms include lactone-containing cyclic groups each represented by General Formulae (b2-r-1) to (b2-r-7). Among these, a lactone-containing cyclic group represented by General Formula (b2-r-1) is preferable.

Specific examples of the constitutional unit (a5) include constitutional units each represented by General Formulae (a5-1) to (a5-1).

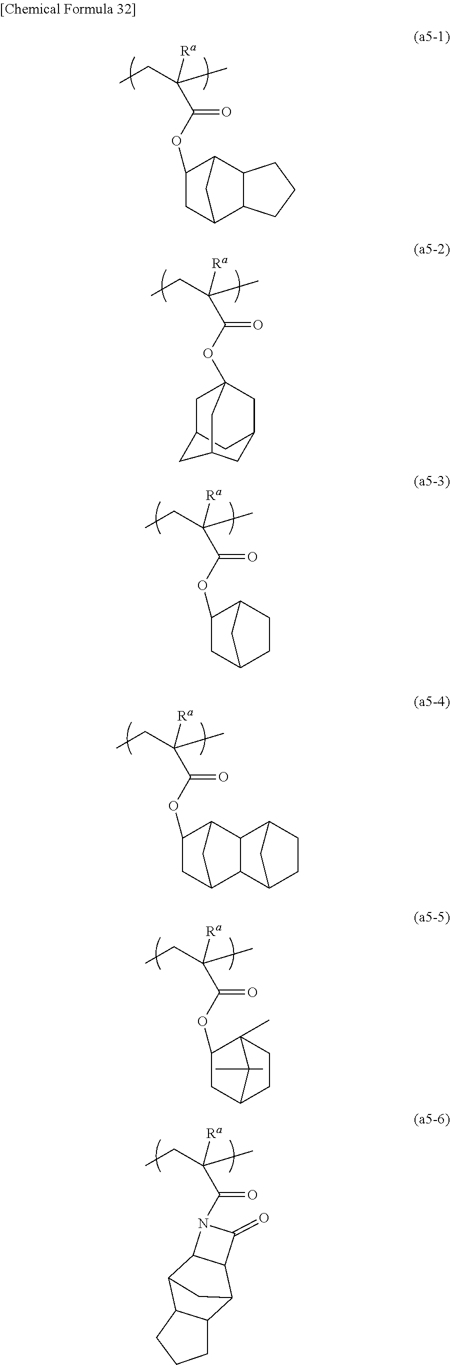

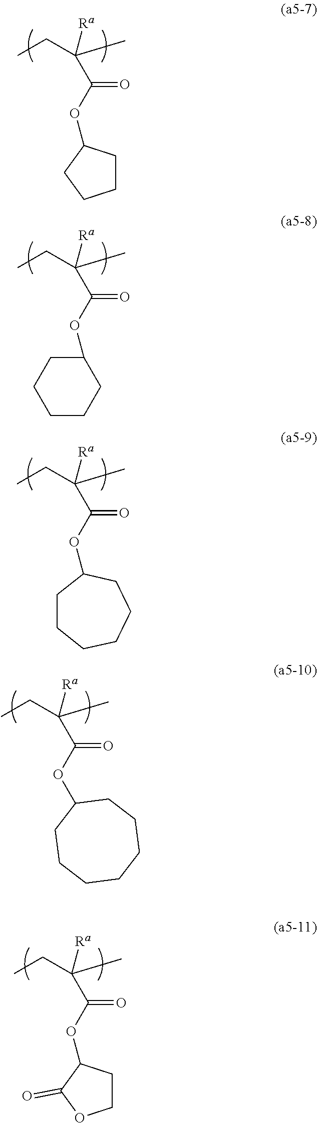

[In the formulae, R^{α} has the same definition as described above.]

The constitutional unit (a5) of the component (A1) may be used alone or in combination of two or more kinds thereof.

Among the examples, the constitutional unit (a5) is preferably a constitutional unit containing an acid non-dissociable and monocyclic aliphatic cyclic group and more preferably at least one selected from the group consisting of constitutional units represented by any of Chemical Formulae (a5-7) to (a5-11).

The proportion of the constitutional unit (a5) in the component (A1) is preferably in a range of 5% to 70% by mole, more preferably in a range of 10% to 65% by mole, and still more preferably in a range of 15% to 60% by mole with respect to the total amount (100% by mole) of all constitutional units constituting the component (A1).

In a case where the proportion of the constitutional unit (a5) is set to be greater than or equal to the lower limits of the above-described preferable ranges, the light transmittance of the resist film is further increased, the sensitivity is increased, and the resolution is further improved. Meanwhile, in a case where the proportion thereof is set to be less than or equal to the upper limits of the above-described preferable ranges, the constitutional unit (a5) and other constitutional units are likely to be balanced.

### <<Other Constitutional Units>>

The component (A1) may have other constitutional units (hereinafter, also referred to as “constitutional unit (a12)”) in addition to the constitutional unit (a1), the constitutional unit (a10), and the constitutional unit (a5).

Examples of a compound from which the constitutional unit (a12) is derived include styrene and derivatives thereof (excluding a compound from which the constitutional unit (a10) is derived); monocarboxylic acids such as acrylic acid, methacrylic acid, and crotonic acid; dicarboxylic acids such as maleic acid, fumaric acid, and itaconic acid; methacrylic acid derivatives having a carboxy group and an ester bond, such as 2-methacryloyloxyethyl succinic acid, 2-methacryloyloxyethyl maleic acid, 2-methacryloyloxyethyl phthalic acid, and 2-methacryloyloxyethyl hexahydrophthalic acid; (meth)acrylic acid alkyl esters such as methyl (meth)acrylate, ethyl (meth)acrylate, and butyl (meth)acrylate; (meth)acrylic acid hydroxyalkyl esters such as 2-hydroxyethyl (meth)acrylate and 2-hydroxypropyl (meth)acrylate; (meth)acrylic acid aryl esters such as phenyl (meth)acrylate and benzyl (meth)acrylate; dicarboxylic acid diesters such as diethyl maleate and dibutyl fumarate; vinyl group-containing aliphatic compounds such as vinyl acetate; conjugate diolefins such as butadiene and isoprene; nitrile group-containing polymerizable compounds such as acrylonitrile and methacrylonitrile; chlorine-containing polymerizable compounds such as vinyl chloride and vinylidene chloride; amide bond-containing polymerizable compounds such as acrylamide and methacrylamide; and epoxy group-containing polymerizable compounds.

The component (A1) may have one or two or more kinds of the constitutional units (a12).

In a case where the component (A1) has the constitutional unit (a12), the proportion of the constitutional unit (a12) in the component (A1) is preferably in a range of 1% to 50% by mole, more preferably in a range of 1% to 40% by mole, still more preferably in a range of 1% to 35% by mole, and particularly preferably in a range of 1 to 30% by mole with respect to the total amount (100% by mole) of all constitutional units constituting the component (A1).

In a case where the proportion of the constitutional unit (a12) is set to be greater than or equal to the above-described lower limits, etching resistance and lithography characteristics are further improved. Meanwhile, in a case where the proportion thereof is set to be less than or equal to the above-described upper limits, the constitutional unit (a12) and other constitutional units are likely to be balanced.

In the resist composition according to the present embodiment, the component (A) contains a polymer compound (A1) having the constitutional unit (a1), the constitutional unit (a10), and the constitutional unit (a5) (component (A1)).

Preferred examples of the component (A1) include a polymer compound having at least the constitutional unit (a1), the constitutional unit (a10), and the constitutional unit (a5). Specific suitable examples thereof include a polymer compound having a repeating structure of the constitutional unit (a1), the constitutional unit (a10), and the constitutional unit (a5) and a polymer compound having a repeating structure of the constitutional unit (a1), the constitutional unit (a10), the constitutional unit (a0), and the constitutional unit (a12).

The weight-average molecular weight (Mw) (in terms of polystyrene according to gel permeation chromatography (GPC)) of the component (A1) is not particularly limited, but is preferably in a range of 500 to 50,000, more preferably in a range of 1,000 to 30,000, and still more preferably in a range of 1,000 to 20,000.

In a case where Mw of the component (A1) is less than or equal to the upper limits of the above-described preferable ranges, the sufficient solubility in the resist solvent is exhibited in a case of using the composition as a resist. Meanwhile, in a case where Mw thereof is greater than or equal to the lower limits of the above-described preferable ranges, the dry etching resistance and the cross-sectional shape of the resist pattern are further enhanced.

The dispersity (Mw/Mn) of the component (A1) is not particularly limited, but is preferably in a range of 1.0 to 4.0, more preferably in a range of 1.0 to 3.0, and particularly preferably in a range of 1.0 to 2.5. In addition, Mn denotes the number average molecular weight.

Such a component (A1) can be produced by dissolving a monomer, from which each constitutional unit is derived, in a polymerization solvent and adding a radical polymerization initiator such as azobisisobutylonitrile (AIBN) or dimethyl azobisisobutyrate (for example, V-601) to the solution so that the polymerization is carried out.

Alternatively, the component (A1) can be produced by dissolving, in a polymerization solvent, a monomer from which the constitutional unit (a10) is derived and, as necessary, a monomer from which a constitutional unit other than the constitutional unit (a10) is derived, adding thereto a radical polymerization initiator such as described above to carry out polymerization, and then carrying out a deprotection reaction.

Further, a —C(CF₃)₂—OH group may be introduced to the terminal during the polymerization using a combination of chain transfer agents such as HS—CH₂—CH₂—CH₂—C(CF₃)₂—OH. As described above, a copolymer into which a hydroxyalkyl group, formed by substitution of some hydrogen atoms in the alkyl group with fluorine atoms, has been introduced is effective for reducing development defects and reducing line edge roughness (LER: uneven irregularities of a line side wall).

In addition, the component (A1) can be produced according to an anionic polymerization method by using, as a polymerization initiator, an organic alkali metal such as n-butyl lithium, s-butyl lithium, t-butyl lithium, ethyl lithium, ethyl sodium, 1,1-diphenylhexyl lithium, or 1,1-diphenyl-3-methylpentyl lithium.

### In Regard to Component (A2)

In the resist composition of the present embodiment, a base material component (hereinafter, also referred to as “component (A2)”) which does not correspond to the component (A1) and whose solubility in a developing solution is changed due to the action of an acid may be used in combination as the component (A).

The component (A2) is not particularly limited and may be optionally selected from a plurality of components of the related art which have been known as base material components for a chemically amplified resist composition and used.

As the component (A2), a polymer compound or a low-molecular-weight compound may be used alone or in combination of two or more kinds thereof.

The proportion of the component (A1) in the component (A) is preferably 25% by mass or greater, more preferably 50% by mass or greater, and still more preferably 75% by mass or greater, and may be 100% by mass with respect to the total mass of the component (A). In a case where the proportion thereof is 25% by mass or greater, a resist pattern having excellent various lithography characteristics such as high sensitivity, high resolution, and improved roughness is likely to be formed.

In the resist composition of the present embodiment, the content of the component (A) may be adjusted according to the thickness of the resist film intended to be formed.

### <Component (Z)>

The component (Z) is a resin component that has a constitutional unit (z1) represented by General Formula (z1-1) and contains no acid dissociable group. Here, “acid dissociable group” indicates both a group (i) having an acid dissociation property in which a bond between the acid dissociable group and an atom adjacent to the acid dissociable group can be cleaved due to the action of an acid; and a group (ii) in which some bonds are cleaved due to the action of an acid, a decarboxylation reaction occurs, and thus the bond between the acid dissociable group and the atom adjacent to the acid dissociable group can be cleaved.

That is, all the constitutional units constituting the component (Z) do not contain an acid dissociable group. Therefore, the component (Z) does not undergo a deprotection reaction by action of an acid.

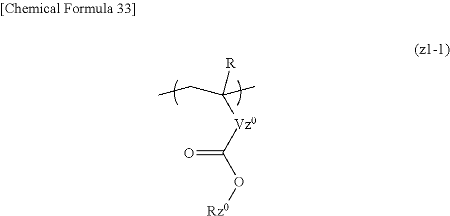

[In the formula, R represents a hydrogen atom, an alkyl group having 1 to 5 carbon atoms, or a halogenated alkyl group having 1 to 5 carbon atoms. Vz⁰ represents a single bond or a divalent hydrocarbon group which may contain a heteroatom. Here, in a case where Vz⁰ represents the divalent hydrocarbon group which may have a heteroatom, Vz⁰ does not include an acid dissociable group. Rz⁰ represents a hydrogen atom or a group represented by General Formula (z1-r-1).]

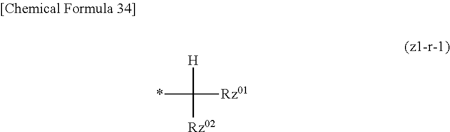

[In the formula, Rz⁰¹ represents a hydrocarbon group which may have a substituent. Rz⁰² represents a hydrogen atom or a hydrocarbon group which may have a substituent. Rz⁰¹ and Rz⁰² may be bonded to each other to form a ring structure. Here, Rz⁰¹ and Rz⁰² do not include an acid dissociable group. * represents a bonding site.]

<Constitutional Unit (z1)>>

In Formula (z1-1), R represents a hydrogen atom, an alkyl group having 1 to 5 carbon atoms, or a halogenated alkyl group having 1 to 5 carbon atoms.

As the alkyl group having 1 to 5 carbon atoms represented by R, a linear or branched alkyl group having 1 to 5 carbon atoms is preferable, and specific examples thereof include a methyl group, an ethyl group, a propyl group, an isopropyl group, an n-butyl group, an isobutyl group, a tert-butyl group, a pentyl group, an isopentyl group, and a neopentyl group.

The halogenated alkyl group having 1 to 5 carbon atoms as R is a group in which some or all hydrogen atoms of the above-described alkyl group having 1 to 5 carbon atoms have been substituted with halogen atoms. As the halogen atom, a fluorine atom, a chlorine atom, a bromine atom, and an iodine atom are exemplary examples. Among these, a fluorine atom is particularly preferable.

R is preferably a hydrogen atom, an alkyl group having 1 to 5 carbon atoms, or a fluorinated alkyl group having 1 to 5 carbon atoms, and in terms of industrial availability, R is more preferably a hydrogen atom, a methyl group, or trifluoromethyl group, and still more preferably a hydrogen atom or a methyl group.

In Formula (z1-1), examples of the divalent hydrocarbon group which may have a heteroatom as Vz⁰ include the same groups as those for the divalent hydrocarbon group which may have a substituent and the divalent linking group having a heteroatom, as Ya^{x1} in Formula (a10-1).

Here, in a case where Vz⁰ represents the divalent hydrocarbon group which may have a heteroatom, Vz⁰ does not include an acid dissociable group.

Among these, Vz⁰ represents preferably a single bond, —C(═O)—O—Y²¹—, or —C(═O)—O—Y²¹—O—C(═O)—Y²²— and more preferably a single bond. Y²¹ and Y²² each independently represent a divalent hydrocarbon group which may have a substituent. Examples of the divalent hydrocarbon group include the same groups described as the divalent linking group as Ya²¹ (divalent hydrocarbon group which may have a substituent).

In Formula (z1-1), Rz⁰ represents a hydrogen atom or a group represented by General Formula (z1-r-1).

In Formula (z1-r-1), examples of the hydrocarbon group which may have a substituent as Rz⁰¹ include a linear or branched alkyl group and a cyclic hydrocarbon group.

The linear alkyl group as Rz⁰¹ has preferably 1 to 10 carbon atoms and more preferably 1 to 5 carbon atoms. Specific examples thereof include a methyl group, an ethyl group, an n-propyl group, an n-butyl group, an n-pentyl group, an n-hexyl group, an n-heptyl group, an n-octyl group, an n-nonyl group, and an n-decyl group.

The branched alkyl group as Rz⁰¹ has preferably 3 to 10 carbon atoms and more preferably 3 to 5 carbon atoms. Specific examples include an isopropyl group, an isobutyl group, a tert-butyl group, an isopentyl group, a neopentyl group, a 1,1-diethylpropyl group, and a 2,2-dimethylbutyl group.

Some carbon atoms constituting the linear or branched alkyl group as Rz⁰¹ may be substituted with oxygen atoms (—O—). Here, in Formula (z1-r-1), Rz⁰¹ does not include an acid dissociable group. Accordingly, in Formula (z1-r-1), even in a case where some carbon atoms constituting the linear or branched alkyl group as Rz⁰¹ are substituted with oxygen atoms (—O—), Rz⁰¹ does not include an acetal type acid dissociable group represented by Formula (a1-r-1).

The cyclic hydrocarbon group as Rz⁰¹ may be an aliphatic hydrocarbon group or an aromatic hydrocarbon group and may be a polycyclic group or a monocyclic group.

As the aliphatic hydrocarbon group which is a monocyclic group, a group in which one hydrogen atom has been removed from a monocycloalkane is preferable. The monocycloalkane has preferably 3 to 6 carbon atoms, and specific examples thereof include cyclopentane and cyclohexane.

As the aliphatic hydrocarbon group which is a polycyclic group, a group in which one hydrogen atom has been removed from a polycycloalkane is preferable. As the polycycloalkane, a group having 7 to 12 carbon atoms is preferable, and specific examples thereof include adamantane, norbornane, isobornane, tricyclodecane, and tetracyclododecane.

In a case where the cyclic hydrocarbon group as Rz⁰¹ is an aromatic hydrocarbon group, the aromatic hydrocarbon group is a hydrocarbon group having at least one aromatic ring.

The aromatic ring is not particularly limited as long as the aromatic ring is a cyclic conjugated system having (4n+2) n electrons and may be monocyclic or polycyclic. The aromatic ring has preferably 5 to 30 carbon atoms, more preferably 5 to 20 carbon atoms, still more preferably 6 to 15 carbon atoms, and particularly preferably 6 to 12 carbon atoms.

Specific examples of the aromatic ring include aromatic hydrocarbon rings such as benzene, naphthalene, anthracene, and phenanthrene; and aromatic heterocyclic rings in which some of the carbon atoms constituting the above-described aromatic hydrocarbon rings are substituted with heteroatoms. Examples of the heteroatom in the aromatic heterocyclic rings include an oxygen atom, a sulfur atom, and a nitrogen atom. Specific examples of the aromatic heterocyclic ring include a pyridine ring and a thiophene ring.

Specific examples of the aromatic hydrocarbon group as Rz⁰¹ include a group in which one hydrogen atom has been removed from the above-described aromatic hydrocarbon ring or aromatic heterocyclic ring (such as an aryl group or a heteroaryl group); a group in which one hydrogen atom has been removed from an aromatic compound having two or more aromatic rings (such as biphenyl or fluorene); and a group in which one hydrogen atom of the above-described aromatic hydrocarbon ring or aromatic heterocyclic ring has been substituted with an alkylene group (for example, an arylalkyl group such as a benzyl group, a phenethyl group, a 1-naphthylmethyl group, a 2-naphthylmethyl group, a 1-naphthylethyl group, or a 2-naphthylethyl group). The number of carbon atoms in the alkylene group bonded to the aromatic hydrocarbon ring or aromatic heterocyclic ring is preferably in a range of 1 to 4, more preferably 1 or 2, and particularly preferably 1.

The cyclic hydrocarbon group as Rz⁰¹ may have a substituent. Examples of the substituent include the substituent “Ra^{x5}” that the hydrocarbon group as Ra′³ in Formula (a1-r-1) may have.

In Formula (z1-r-1), the hydrocarbon group which may have a substituent as Rz⁰² is the same as the hydrocarbon group which may have a substituent as Rz⁰¹.

In Formula (z1-r-1), in a case where Rz⁰¹ and Rz⁰² are bonded to each other to form a ring structure, examples of the ring structure include a group in which two hydrogen atoms have been removed from a monocycloalkane or a polycycloalkane. The monocycloalkane has preferably 3 to 6 carbon atoms, and specific examples thereof include cyclopentane and cyclohexane.

As the aliphatic hydrocarbon group which is a polycyclic group, a group in which one hydrogen atom has been removed from a polycycloalkane is preferable. As the polycycloalkane, a group having 7 to 12 carbon atoms is preferable, and specific examples thereof include adamantane, norbornane, isobornane, tricyclodecane, and tetracyclododecane.

In Formula (z1-r-1), it is preferable that Rz⁰¹ represents a linear alkyl group or a linear alkoxy group and Rz⁰² represents a hydrogen atom or Rz⁰¹ and Rz⁰² are bonded to each other to form a ring structure.

The constitutional unit (z1) of the component (Z) may be used alone or in combination of two or more kinds thereof.

Among them, the component (Z) preferably has, as the constitutional unit (z1), a constitutional unit represented by General Formula (z1-1-1) (hereinafter, may be referred to as “constitutional unit (z1-1-1)”) and a constitutional unit represented by General Formula (z1-1-2) (hereinafter, may be referred to as “constitutional unit (z1-1-2)”).

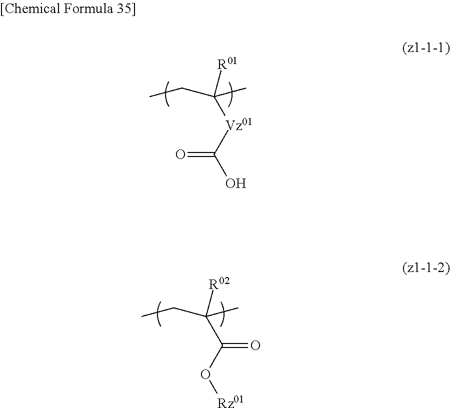

[In the formulae, R⁰¹ and R⁰² each independently represent a hydrogen atom, an alkyl group having 1 to 5 carbon atoms, or a halogenated alkyl group having 1 to 5 carbon atoms. Vz⁰¹ represents a single bond, —C(═O)—O—Y²¹—, or —C(═O)—O—Y²¹—O—C(═O)—Y²²—. Y²¹ and Y²² each independently represent a divalent hydrocarbon group which may have a substituent, and O represents an oxygen atom. Here, in a case where Vz⁰¹ represents —C(═O)—O—Y²¹— or —C(═O)—O—Y²¹—O—C(═O)—Y²²—, Vz⁰¹ does not include an acid dissociable group. Rz¹⁰ represents a linear alkyl group, -Rz¹¹-O-Rz¹²-, or a monovalent alicyclic hydrocarbon group. Rz¹¹ represents a linear alkylene group, and Rz¹² represents a linear alkyl group.]

In Formulae (z1-1-1) and (z1-1-2), R⁰¹ and R⁰² each have the same definition as that for R in Formula (z1-1). Among the examples, R⁰¹ represents preferably a hydrogen atom, a methyl group, or a trifluoromethyl group, more preferably a hydrogen atom or a methyl group, and still more preferably a methyl group. R⁰² represents preferably a hydrogen atom, a methyl group, or a trifluoromethyl group, more preferably a hydrogen atom or a methyl group, and still more preferably a hydrogen atom.

In Formula (z1-1-1), in a case where Vz⁰¹ represents —C(═O)—O—Y²¹— or —C(═O)—O—Y²¹—O—C(═O)—Y²²—, Y²¹ represents preferably a linear aliphatic hydrocarbon group, more preferably a linear alkylene group, still more preferably a linear alkylene group having 1 to 5 carbon atoms, and particularly preferably a methylene group or an ethylene group. Y²² represents preferably a linear or branched aliphatic hydrocarbon group and more preferably a methylene group, an ethylene group, or an alkylmethylene group. The alkyl group in the alkylmethylene group is preferably a linear alkyl group having 1 to 5 carbon atoms, more preferably a linear alkyl group having 1 to 3 carbon atoms, and most preferably a methyl group.

Among these, it is preferable that Vz⁰¹ represents a single bond.

In Formula (z1-1-1), the linear alkyl group as Rz¹⁰ has preferably 1 to 10 carbon atoms and more preferably 1 to 5 carbon atoms.

In Formula (z1-1-1), in a case where Rz¹⁰ represents -Rz¹¹-O-Rz¹², Rz¹⁰ represents preferably a linear alkylene group having 1 to 5 carbon atoms and more preferably a methylene group or an ethylene group. Rz¹¹ represents preferably a linear alkyl group having 1 to 5 carbon atoms and more preferably a methyl group or an ethyl group.

In Formula (z1-1-1), the monovalent alicyclic hydrocarbon group as Rz¹⁰ may be a polycyclic group or a monocyclic group.

As the aliphatic hydrocarbon group which is a monocyclic group, a group in which one hydrogen atom has been removed from a monocycloalkane is preferable. The monocycloalkane has preferably 3 to 6 carbon atoms, and specific examples thereof include cyclopentane and cyclohexane.

As the aliphatic hydrocarbon group which is a polycyclic group, a group in which one hydrogen atom has been removed from a polycycloalkane is preferable. As the polycycloalkane, a group having 7 to 12 carbon atoms is preferable, and specific examples thereof include adamantane, norbornane, isobornane, tricyclodecane, and tetracyclododecane.

Among these, it is preferable that the component (Z) has, as the constitutional unit (z1-1-2), a constitutional unit represented by General Formula (z1-1-21) (hereinafter, also referred to as “constitutional unit (z1-1-21)”) and a constitutional unit represented by General Formula (z1-1-22) (hereinafter, also referred to as “constitutional unit (z-1-22)”).

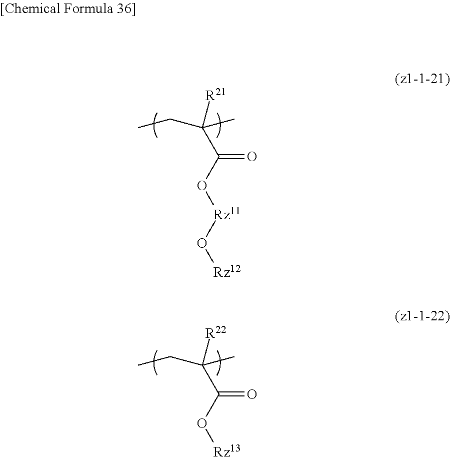

[In the formulae, R²¹ and R²² each independently represent a hydrogen atom, an alkyl group having 1 to 5 carbon atoms, or a halogenated alkyl group having 1 to 5 carbon atoms. Rz¹¹ represents a linear alkylene group. Rz¹² represents a linear alkyl group. Rz¹¹ represents a linear alkyl group or a monovalent alicyclic hydrocarbon group.]

In Formulae (z1-1-21) and (z-1-22), R²¹ and R²² each have the same definition as that for R⁰² in Formula (z1-1-2).

In Formula (z1-1-21), Rz¹¹ and Rz¹² each have the same definition as that for Rz¹¹ and Rz¹² in Formula (z1-1-2).

In Formula (z1-1-21), the linear alkyl group or the monovalent alicyclic hydrocarbon group as Rz¹³ is the same as the linear alkyl group or the monovalent alicyclic hydrocarbon group as Rz¹⁰ in Formula (z1-1-2).

Specific examples of the constitutional unit (z1) are as follows. In the formulae shown below, R^{α} represents a hydrogen atom, a methyl group, or a trifluoromethyl group.

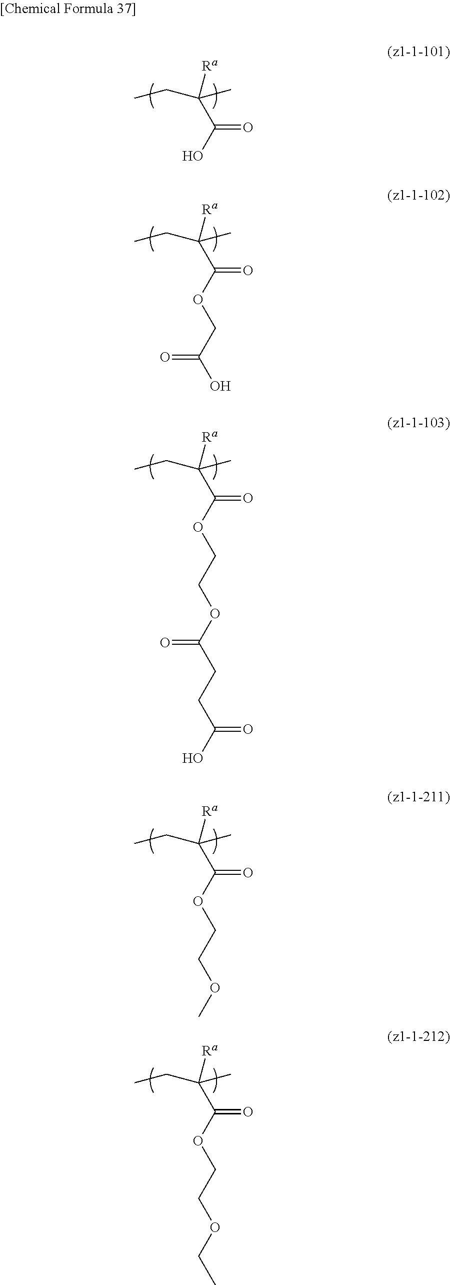

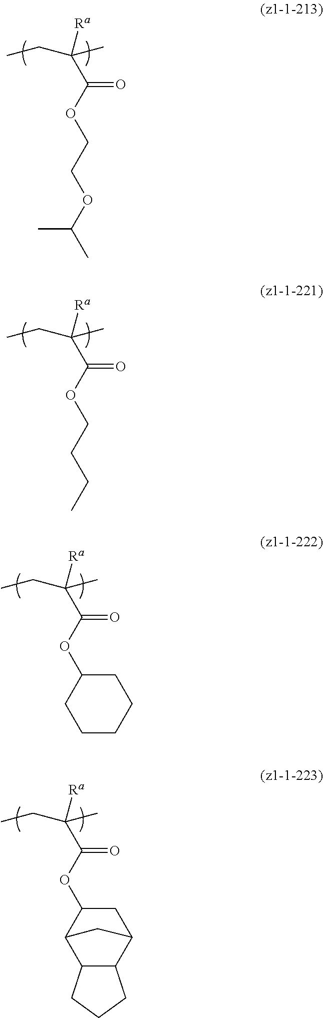

The proportion of the constitutional unit (z1) in the component (Z) is preferably in a range of 50% to 100% by mole, more preferably in a range of 60% to 100% by mole, and still more preferably in a range of 70% to 100% by mole, and may be 100% by mole with respect to the total amount (100% by mole) of all constitutional units constituting the component (Z).

In a case where the proportion of the constitutional unit (z1) is within the preferred range described above, the occurrence of cracking is easily suppressed and the occurrence of surface roughness is easily suppressed during etching.

In a case where the component (Z) contains, as the constitutional unit (z1), the constitutional unit (z1-1-1) and the constitutional unit (z1-1-2), the proportion of the constitutional unit (z1-1-1) in the component (Z) is preferably in a range of 1% to 30% by mole, more preferably in a range of 3% to 25% by mole, and still more preferably in a range of 5% to 20% by mole with respect to the total amount (100% by mole) of all constitutional units constituting the component (Z). The proportion of the constitutional unit (z1-1-2) in the component (Z) is preferably in a range of 70% to 99% by mole, more preferably in a range of 75% to 97% by mole, and still more preferably in a range of 80% to 95% by mole with respect to the total amount (100% by mole) of all constitutional units constituting the component (Z).

In a case where the proportions of the constitutional units (z1-1-1) and (z1-1-2) are set to be in the above-described preferable ranges, the occurrence of cracks is likely to be suppressed, and the viscosity of the resist composition is likely to be controlled in a range where the handleability is satisfactory.

In a case where the component (Z) contains, as the constitutional unit (z1), the constitutional unit (z1-1-1), the constitutional unit (z1-1-21), and the constitutional unit (z1-1-22), the proportion of the constitutional unit (z1-1-1) in the component (Z) is preferably in a range of 1% to 30% by mole, more preferably in a range of 3% to 25% by mole, and still more preferably in a range of 5% to 20% by mole with respect to the total amount (100% by mole) of all constitutional units constituting the component (Z). In addition, the proportion of the constitutional unit (z1-1-21) in the component (Z) is preferably in a range of 10% to 99% by mole, more preferably in a range of 15% to 97% by mole, still more preferably in a range of 20% to 95% by mole, and even still more preferably in a range of 20% to 70% by mole with respect to the total amount (100% by mole) of all constitutional units constituting the component (Z). In addition, the proportion of the constitutional unit (z1-1-22) in the component (Z) is preferably in a range of 0% to 80% by mole, more preferably in a range of 10% to 75% by mole, still more preferably in a range of 15% to 70% by mole, and even still more preferably in a range of 20% to 65% by mole with respect to the total amount (100% by mole) of all constitutional units constituting the component (Z).

In a case where the proportions of the constitutional unit (z1-1-1), the constitutional unit (z1-1-21), and the constitutional unit (z1-1-22) are set to be in the above-described preferable ranges, the viscosity of the resist composition is likely to be controlled in a range where the handleability is satisfactory.

### <<Other Constitutional Units>>

The component (Z) may have other constitutional units as necessary in addition to the constitutional unit (z1) described above.

Examples of other constitutional units include the constitutional unit (a10), a constitutional unit (st) derived from styrene or a styrene derivative, and the constitutional unit (a1).

In a case where the component (Z) has the constitutional unit (a10), the proportion of the constitutional unit (a10) in the component (Z) is preferably in a range of 5% to 50% by mole, more preferably in a range of 5% to 40% by mole, and still more preferably in a range of 10% to 30% by mole with respect to the total amount (100% by mole) of all constitutional units constituting the component (Z).

In a case where the proportion of the constitutional unit (a10) is set to be greater than or equal to the above-described lower limits, the sensitivity is likely to be enhanced. Meanwhile, in a case where the proportion thereof is set to be less than or equal to the above-described upper limits, the constitutional unit (a10) and other constitutional units are likely to be balanced.

In a case where the component (Z) has the constitutional unit (st), the proportion of the constitutional unit (st) in the component (Z) is preferably in a range of 1% to 30% by mole and more preferably in a range of 3% to 30% by mole with respect to the total amount (100% by mole) of all constitutional units constituting the component (Z).

The component (Z) contained in the resist composition may be used alone or in a combination of two or more kinds thereof.

In the resist composition according to the present embodiment, examples of the component (Z) include a polymer compound having a repeated structure of the constitutional unit (z1).

Preferred examples of the component (Z) include a polymer compound having a repeated structure of the constitutional unit (z1-1-1) and the constitutional unit (z1-1-21); and a polymer compound having a repeated structure of the constitutional unit (z1-1-1), the constitutional unit (z1-1-21), and the constitutional unit (z1-1-22).

The component (Z) can be produced by dissolving, in a polymerization solvent, each monomer from which the constitutional unit is derived, adding thereto a radical polymerization initiator such as azobisisobutyronitrile (AIBN) or dimethyl azobisisobutyrate (for example, V-601) to perform polymerization.

Alternatively, the component (Z) can be produced by dissolving, in a polymerization solvent, a monomer from which the constitutional unit (z1) is derived and, as necessary, a monomer from which a constitutional unit other than the constitutional unit (z1) is derived, and adding thereto a radical polymerization initiator such as described above to perform polymerization.

Further, a —C(CF₃)₂—OH group may be introduced to the terminal during the polymerization using a combination of chain transfer agents such as HS—CH₂—CH₂—CH₂—C(CF₃)₂—OH. As described above, a copolymer into which a hydroxyalkyl group, formed by substitution of some hydrogen atoms in the alkyl group with fluorine atoms, has been introduced is effective for reducing development defects and reducing line edge roughness (LER: uneven irregularities of a line side wall).

The weight-average molecular weight (Mw) of the component (Z) (in terms of polystyrene according to gel permeation chromatography (GPC)) is not particularly limited, but is preferably in a range of 5,000 to 200.000, more preferably in a range of 10,000 to 150.000, still more preferably in a range of 20,000 to 100,000, even still more preferably in a range of 30,000 to 90,000, and particularly preferably in a range of 35,000 to 85,000.

In a case in which the Mw of the component (Z) is in the above-described preferable ranges, the occurrence of cracks is likely to be suppressed, and the viscosity of the resist composition is likely to be controlled in a range where the handleability is satisfactory.

Further, the dispersity (Mw/Mn) of the component (Z) is not particularly limited, but is preferably in a range of 1.0 to 9.0, more preferably in a range of 1.5 to 7.0, and particularly preferably in a range of 3.0 to 6.0. Further, Mn represents the number average molecular weight.

In the resist composition according to the present embodiment, the component (Z) may be used alone or in combination of two or more kinds thereof.

The content of the component (Z) in the resist composition according to the present embodiment is preferably in a range of 1 to 50 parts by mass, more preferably in a range of 5 to 45 parts by mass, still more preferably in a range of 10 to 40 parts by mass, and even still more preferably in a range of 15 to 40 parts by mass with respect to 100 parts by mass of the component (A1).

In a case where the content of the component (Z) is in the above-described preferable ranges, the occurrence of cracks is likely to be suppressed, and the viscosity of the resist composition is likely to be controlled in a range where the handleability is satisfactory.

### <Other Components>

The resist composition according to the present embodiment may further contain other components in addition to the component (A) and the component (Z) described above. Examples of the other components include a component (B), a component (D), a component (E), a component (F), and a component (S), which are described below.

### <<Acid Generation Agent Component (B)>>

The resist composition according to the present embodiment may further contain an acid generation agent component (B) (hereinafter, referred to as “component (B)”) generating an acid upon exposure, in addition to the component (A) and the component (Z).

The component (B) is not particularly limited, and those which have been suggested so far as an acid generation agent for a chemically amplified resist composition in the related art can be used.

Examples of the acid generation agent include various acid generation agents, for example, onium salt-based acid generation agents such as iodonium salts and sulfonium salts; oxime sulfonate-based acid generation agents; diazomethane-based acid generation agents such as bisalkyl or bisaryl sulfonyl diazomethanes and poly(bis-sulfonyl)diazomethanes; nitrobenzyl sulfonate-based acid generation agents, iminosulfonate-based acid generation agents, and disulfone-based acid generation agents.

The component (B) preferably contains a compound (B1) composed of an onium salt (hereinafter, referred to as “component (B1)”).

### In Regard to Component (B1)

Examples of the component (B1) include a compound represented by General Formula (b-1) (hereinafter, also referred to as “component (b-1)”), a compound represented by General Formula (b-2) (hereinafter, also referred to as “component (b-2)”), and a compound represented by General Formula (b-3) (hereinafter, also referred to as “component (b-3)”).

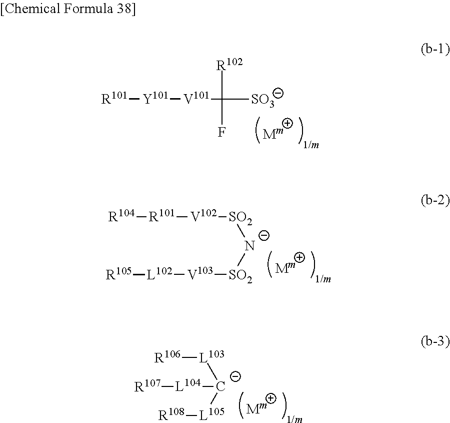

[In the formulae, R¹⁰¹ and R¹⁰⁴ to R¹⁰⁸ each independently represent a cyclic group which may have a substituent, a chain-like alkyl group which may have a substituent, or a chain-like alkenyl group which may have a substituent. R¹⁰⁴ and R¹⁰⁵ may be bonded to each other to form a ring structure. R¹⁰² represents a fluorinated alkyl group having 1 to 5 carbon atoms or a fluorine atom. Y¹⁰¹ represents a divalent linking group having an oxygen atom or a single bond. V¹⁰¹ to V¹⁰³ each independently represent a single bond, an alkylene group, or a fluorinated alkylene group. L¹⁰¹ and L¹⁰² each independently represent a single bond or an oxygen atom. L¹⁰³ to L¹⁰⁵ each independently represent a single bond, —CO—, or —SO₂—. m represents an integer of 1 or greater, and M^{m+} represents an m-valent onium cation.]

### (Anion Moiety)

Anions in Component (b-1)

In Formula (b-1), R¹⁰¹ represents a cyclic group which may have a substituent, a chain-like alkyl group which may have a substituent, or a chain-like alkenyl group which may have a substituent.

Cyclic Group which May have Substituent:

The cyclic group is preferably a cyclic hydrocarbon group, and the cyclic hydrocarbon group may be an aromatic hydrocarbon group or an aliphatic hydrocarbon group. The aliphatic hydrocarbon group indicates a hydrocarbon group that has no aromaticity. Further, the aliphatic hydrocarbon group may be saturated or unsaturated. In general, it is preferable that the aliphatic hydrocarbon group is saturated.

The aromatic hydrocarbon group as R¹⁰¹ is a hydrocarbon group having an aromatic ring. The aromatic hydrocarbon group has preferably 3 to 30 carbon atoms, more preferably 5 to 30 carbon atoms, still more preferably 5 to 20 carbon atoms, particularly preferably 6 to 15 carbon atoms, and most preferably 6 to 10 carbon atoms. Here, the number of carbon atoms in a substituent is not included in the number of carbon atoms.

Specific examples of the aromatic ring of the aromatic hydrocarbon group as R¹⁰¹ include benzene, fluorene, naphthalene, anthracene, phenanthrene, biphenyl, and an aromatic heterocyclic ring in which some carbon atoms constituting any of these aromatic rings are substituted with heteroatoms. Examples of the heteroatom in the aromatic heterocyclic rings include an oxygen atom, a sulfur atom, and a nitrogen atom.

Specific examples of the aromatic hydrocarbon group as R¹⁰¹ include a group in which one hydrogen atom has been removed from the aromatic ring (an aryl group such as a phenyl group or a naphthyl group) and a group in which one hydrogen atom in the aromatic ring has been substituted with an alkylene group (for example, an arylalkyl group such as a benzyl group, a phenethyl group, a 1-naphthylmethyl group, a 2-naphthylmethyl group, 1-naphthylethyl group, or a 2-naphthylethyl group). The alkylene group (alkyl chain in the arylalkyl group) has preferably 1 to 4 carbon atoms, more preferably 1 or 2 carbon atoms, and particularly preferably 1 carbon atom.

Examples of the cyclic aliphatic hydrocarbon group as R¹⁰¹ include an aliphatic hydrocarbon group having a ring in the structure thereof.

Examples of the aliphatic hydrocarbon group having a ring in the structure thereof include an alicyclic hydrocarbon group (a group in which one hydrogen atom has been removed from an aliphatic hydrocarbon ring), a group in which the alicyclic hydrocarbon group is bonded to the terminal of a linear or branched aliphatic hydrocarbon group, and a group in which the alicyclic hydrocarbon group is interposed in the middle of a linear or branched aliphatic hydrocarbon group.

The alicyclic hydrocarbon group has preferably 3 to 20 carbon atoms and more preferably 3 to 12 carbon atoms.

The alicyclic hydrocarbon group may be a polycyclic group or a monocyclic group. As the monocyclic alicyclic hydrocarbon group, a group in which one or more hydrogen atoms have been removed from a monocycloalkane is preferable. The monocycloalkane has preferably 3 to 6 carbon atoms, and specific examples thereof include cyclopentane and cyclohexane. As the polycyclic alicyclic hydrocarbon group, a group in which one or more hydrogen atoms have been removed from a polycycloalkane is preferable, and the number of carbon atoms of the polycycloalkane is preferably in a range of 7 to 30. Among these, a polycycloalkane having a crosslinked ring polycyclic skeleton such as adamantane, norbornane, isobornane, tricyclodecane, or tetracyclododecane; and a polycycloalkane having a condensed ring polycyclic skeleton such as a cyclic group having a steroid skeleton are preferable as the polycycloalkane.

Among these examples, as the cyclic aliphatic hydrocarbon group as R¹⁰¹, a group in which one or more hydrogen atoms have been removed from a monocycloalkane or a polycycloalkane is preferable, a group in which one hydrogen atom has been removed from a polycycloalkane is more preferable, an adamantyl group or a norbornyl group is still more preferable, and an adamantyl group is particularly preferable.

The linear aliphatic hydrocarbon group which may be bonded to the alicyclic hydrocarbon group has preferably 1 to 10 carbon atoms, more preferably 1 to 6 carbon atoms, still more preferably 1 to 4 carbon atoms, and most preferably 1 to 3 carbon atoms. As the linear aliphatic hydrocarbon group, a linear alkylene group is preferable, and specific examples thereof include a methylene group [—CH₂—], an ethylene group [—(CH₂)₂—], a trimethylene group [—(CH₂)₃—], a tetramethylene group [—(CH₂)₄—], and a pentamethylene group [—(CH₂)₅—].

The branched aliphatic hydrocarbon group which may be bonded to the alicyclic hydrocarbon group has preferably 2 to 10 carbon atoms, more preferably 3 to 6 carbon atoms, still more preferably 3 or 4 carbon atoms, and most preferably 3 carbon atoms. As the branched aliphatic hydrocarbon group, a branched alkylene group is preferable, and specific examples thereof include alkylalkylene groups, for example, alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂— and —CH₂CH(CH₃)CH₂—; and alkyltetramethylene groups such as —CH(CH₃)CH₂CH₂CH₂— and —CH₂CH(CH₃)CH₂CH₂—. As the alkyl group in the alkylalkylene group, a linear alkyl group having 1 to 5 carbon atoms is preferable.

Further, the cyclic hydrocarbon group as R¹⁰¹ may have a heteroatom such as a heterocyclic ring. Specific examples thereof include lactone-containing cyclic groups each represented by General Formulae (b2-r-1) to (b2-r-7), —SO₂-containing cyclic groups each represented by General Formulae (b5-r-1) to (b5-r-4), and other heterocyclic groups each represented by Chemical Formulae (r-hr-1) to (r-hr-16). Here, in Chemical Formulae (r-hr-1) to (r-hr-16), * represents a bonding site with respect to Y¹⁰¹ in Formula (b-1).

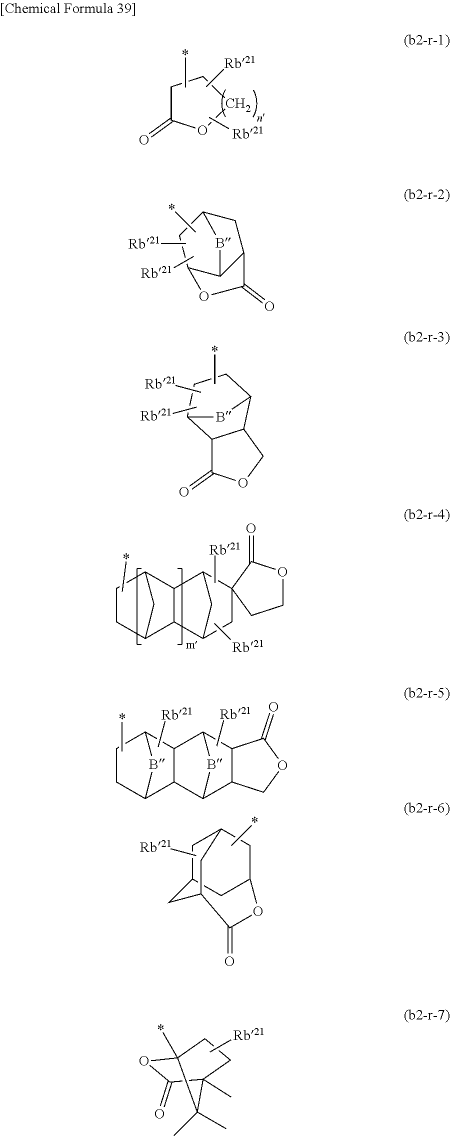

[In the formulae, Rb′²¹'s each independently represent a hydrogen atom, an alkyl group, an alkoxy group, a halogen atom, a halogenated alkyl group, a hydroxyl group, —COOR″, —OC(═O)R″, a hydroxyalkyl group, or a cyano group, R″ represents a hydrogen atom, an alkyl group, or a lactone-containing cyclic group, B″ represents an alkylene group having 1 to 5 carbon atoms which may have an oxygen atom (—O—) or a sulfur atom (—S—), an oxygen atom, or a sulfur atom, n′ represents an integer of 0 to 2, and m′ represents 0 or 1. * represents a bonding site.]

In General Formulae (b2-r-1) to (b2-r-7), an alkyl group having 1 to 6 carbon atoms is preferable as the alkyl group represented by Rb′²¹. Further, it is preferable that the alkyl group is linear or branched. Specific examples thereof include a methyl group, an ethyl group, a propyl group, an isopropyl group, an n-butyl group, an isobutyl group, a tert-butyl group, a pentyl group, an isopentyl group, a neopentyl group, and a hexyl group. Among these, a methyl group or ethyl group is preferable, and a methyl group is particularly preferable.

An alkoxy group having 1 to 6 carbon atoms is preferable as the alkoxy group represented by Rb′²¹. Further, it is preferable that the alkoxy group is linear or branched. Specific examples of the alkoxy groups include a group formed by linking the alkyl group described above as the alkyl group represented by Rb′²¹ to an oxygen atom (—O—).

As the halogen atom represented by Rb′²¹, a fluorine atom is preferable.

Examples of the halogenated alkyl group as Rb′²¹ include groups in which some or all hydrogen atoms in the alkyl group as Rb′²¹ have been substituted with the halogen atoms. As the halogenated alkyl group, a fluorinated alkyl group is preferable, and a perfluoroalkyl group is particularly preferable.

In both —COOR″ and —OC(═O)R″ as Rb′²¹, R″ represents a hydrogen atom, an alkyl group, or a lactone-containing cyclic group.

The alkyl group as R″ may be linear, branched, or cyclic and has preferably 1 to 15 carbon atoms.

In a case where R″ represents a linear or branched alkyl group, an alkyl group having 1 to 10 carbon atoms is preferable, an alkyl group having 1 to 5 carbon atoms is more preferable, and a methyl group or an ethyl group is particularly preferable.

In a case where R″ represents a cyclic alkyl group, the number of carbon atoms thereof is preferably in a range of 3 to 15, more preferably in a range of 4 to 12, and most preferably in a range of 5 to 10. Specific examples thereof include groups in which one or more hydrogen atoms have been removed from a monocycloalkane, which may or may not be substituted with a fluorine atom or a fluorinated alkyl group; and groups in which one or more hydrogen atoms have been removed from a polycycloalkane such as bicycloalkane, tricycloalkane, or tetracycloalkane. More specific examples thereof include groups in which one or more hydrogen atoms have been removed from a monocycloalkane such as cyclopentane or cyclohexane; and groups in which one or more hydrogen atoms have been removed from a polycycloalkane such as adamantane, norbornane, isobornane, tricyclodecane, or tetracyclododecane.

Examples of the lactone-containing cyclic group as R″ include the same groups as those for the groups each represented by General Formulae (b2-r-1) to (b2-r-7).

As the hydroxyalkyl group represented by Rb′²¹, a hydroxyalkyl group having 1 to 6 carbon atoms is preferable, and specific examples thereof include a group in which at least one hydrogen atom in the alkyl group as Rb′²¹ has been substituted with a hydroxyl group.

Among the examples, it is preferable that Rb′²¹'s each independently represent a hydrogen atom or a cyano group.

In General Formulae (b2-r-2), (b2-r-3), and (b2-r-5), as the alkylene group having 1 to 5 carbon atoms as B″, a linear or branched alkylene group is preferable, and examples thereof include a methylene group, an ethylene group, an n-propylene group, and an isopropylene group. In a case where the alkylene group has an oxygen atom or a sulfur atom, specific examples thereof include groups in which —O— or —S— is interposed in the terminal of the alkylene group or between the carbon atoms of the alkylene group. Further, examples thereof include —O—CH₂—, —CH₂—O—CH₂—, —S—CH₂—, and —CH₂—S—CH₂—. B″ represents preferably an alkylene group having 1 to 5 carbon atoms or —O—, more preferably an alkylene group having 1 to 5 carbon atoms, and most preferably a methylene group.

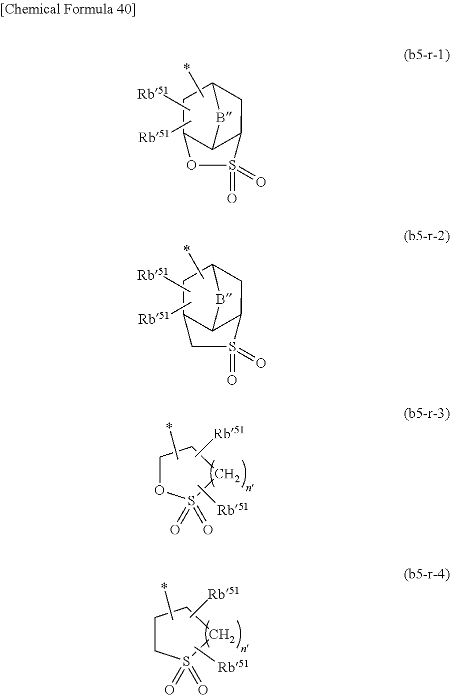

[In the formulae, Rb′⁵¹'s each independently represent a hydrogen atom, an alkyl group, an alkoxy group, a halogen atom, a halogenated alkyl group, a hydroxyl group, —COOR″, —OC(═O)R″, a hydroxyalkyl group, or a cyano group, R″ represents a hydrogen atom, an alkyl group, a lactone-containing cyclic group, or a —SO₂-containing cyclic group, B″ represents an alkylene group having 1 to 5 carbon atoms which may have an oxygen atom or a sulfur atom, an oxygen atom, or a sulfur atom, and n′ represents an integer of 0 to 2. * represents a bonding site.]

In General Formulae (b5-r-1) and (b5-r-2), B″ represents an alkylene group having 1 to 5 carbon atoms which may have an oxygen atom or a sulfur atom, an oxygen atom, or a sulfur atom.

B″ represents preferably an alkylene group having 1 to 5 carbon atoms or —O—, more preferably an alkylene group having 1 to 5 carbon atoms, and still more preferably a methylene group.

In General Formulae (b5-r-1) to (b5-r-4), Rb′⁵¹'s each independently represents a hydrogen atom, an alkyl group, an alkoxy group, a halogen atom, a halogenated alkyl group, a hydroxyl group, —COOR″, —OC(═O)R″, a hydroxyalkyl group, or a cyano group. Among these, it is preferable that Rb′⁵¹'s each independently represent a hydrogen atom or a cyano group.

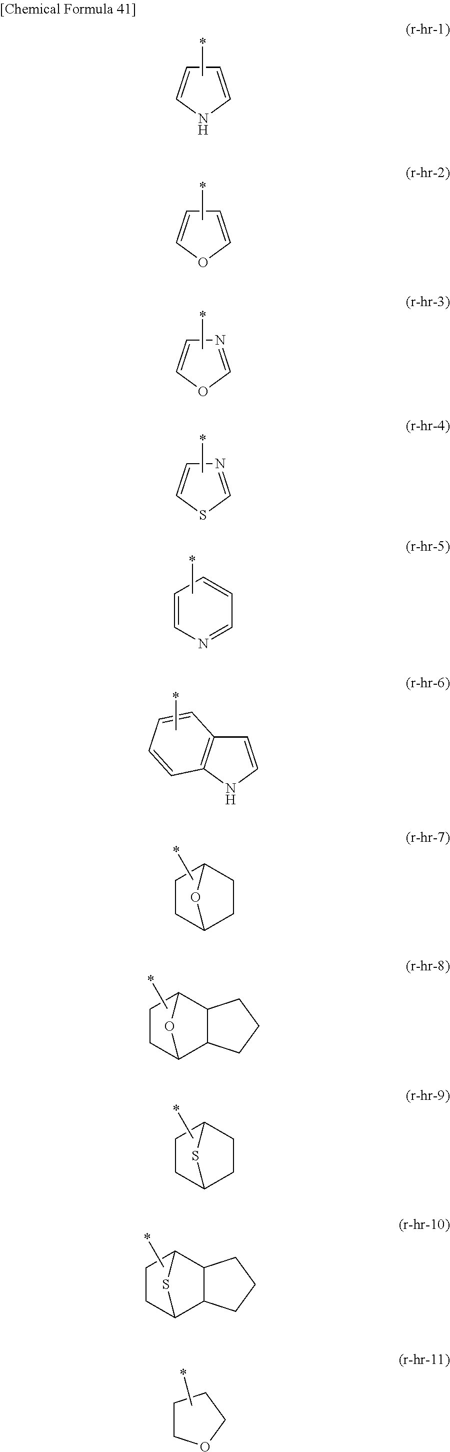

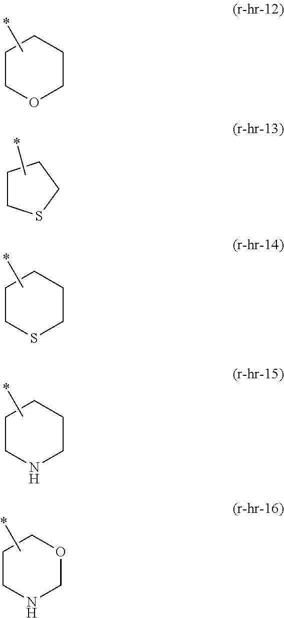

Examples of the substituent for the cyclic group as R¹⁰¹ include an alkyl group, an alkoxy group, a halogen atom, a halogenated alkyl group, a hydroxyl group, a carbonyl group, and a nitro group.

As the alkyl group as the substituent, an alkyl group having 1 to 5 carbon atoms is preferable, and a methyl group, an ethyl group, a propyl group, an n-butyl group, or a tert-butyl group is most preferable.

As the alkoxy group as the substituent, an alkoxy group having 1 to 5 carbon atoms is preferable, a methoxy group, an ethoxy group, an n-propoxy group, an iso-propoxy group, an n-butoxy group, or a tert-butoxy group is more preferable, and a methoxy group or an ethoxy group is most preferable.

Examples of the halogen atom as the substituent include a fluorine atom, a chlorine atom, a bromine atom, and an iodine atom. Among these, a fluorine atom is preferable.

Example of the above-described halogenated alkyl group as the substituent includes a group in which some or all hydrogen atoms in an alkyl group having 1 to 5 carbon atoms such as a methyl group, an ethyl group, a propyl group, an n-butyl group, or a tert-butyl group are substituted with the above-described halogen atoms.

The carbonyl group as the substituent is a group that substitutes a methylene group (—CH₂—) constituting the cyclic hydrocarbon group.

The cyclic hydrocarbon group as R¹⁰¹ may be a condensed cyclic group having a condensed ring in which an aliphatic hydrocarbon ring and an aromatic ring are condensed. Examples of the condensed ring include those obtained by condensing one or more aromatic rings with a polycycloalkane having a crosslinked ring polycyclic skeleton. Specific examples of the crosslinked ring polycycloalkane include a bicycloalkane such as bicyclo[2.2.1]heptane (norbornane) and bicyclo[2.2.2]octane. As the condensed cyclic group, a group having a condensed ring in which two or three aromatic rings are condensed with a bicycloalkane is preferable, and a group having a condensed ring in which two or three aromatic rings are condensed with bicyclo[2.2.2]octane is more preferable. Specific examples of the condensed cyclic group as R¹⁰¹ include those represented by Formulae (r-br-1) and (r-br-2). In the formulae, * represents a bonding site with respect to Y¹⁰¹ in Formula (b-1).

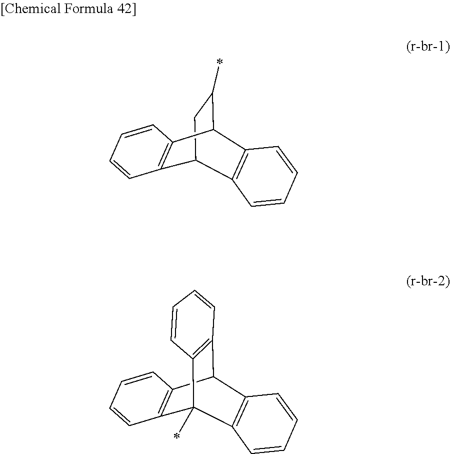

Examples of the substituent that the condensed cyclic group as R¹⁰¹ may have include an alkyl group, an alkoxy group, a halogen atom, a halogenated alkyl group, a hydroxyl group, a carbonyl group, a nitro group, an aromatic hydrocarbon group, and an alicyclic hydrocarbon group.

Examples of the alkyl group, the alkoxy group, the halogen atom, and the halogenated alkyl group as the substituent of the condensed cyclic group include those exemplified as the substituent of the cyclic group as R¹⁰¹.

Examples of the aromatic hydrocarbon group as the substituent of the condensed cyclic group include a group in which one hydrogen atom has been removed from the aromatic ring (an aryl group such as a phenyl group or a naphthyl group), a group in which one hydrogen atom in the aromatic ring has been substituted with an alkylene group (for example, an arylalkyl group such as a benzyl group, a phenethyl group, a 1-naphthylmethyl group, a 2-naphthylmethyl group, 1-naphthylethyl group, or a 2-naphthylethyl group), and a heterocyclic group represented by any of Formulae (r-hr-1) to (r-hr-6).

Examples of the alicyclic hydrocarbon group as the substituent of the condensed cyclic group include a group in which one hydrogen atom has been removed from a monocycloalkane such as cyclopentane or cyclohexane, a group in which one hydrogen atom has been removed from a polycycloalkane such as adamantane, norbornane, isobornane, tricyclodecane, or tetracyclododecane, a lactone-containing cyclic group represented by any of General Formulae (b2-r-1) to (b2-r-7), a —SO₂-containing cyclic group represented by any of General Formulae (b5-r-1) to (b5-r-4), and a heterocyclic group represented by any of Formulae (r-hr-7) to (r-hr-16).

Chain-Like Alkyl Group which May have Substituent:

The chain-like alkyl group as R¹⁰¹ may be linear or branched.

The linear alkyl group has preferably 1 to 20 carbon atoms, more preferably 1 to 15 carbon atoms, and most preferably 1 to 10 carbon atoms.

The branched alkyl group has preferably 3 to 20 carbon atoms, more preferably 3 to 15 carbon atoms, and most preferably 3 to 10 carbon atoms. Specific examples thereof include a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group, and a 4-methylpentyl group.

Chain-Like Alkenyl Group which May have Substituent:

The chain-like alkenyl group as R¹⁰¹ may be linear or branched, and the number of carbon atoms thereof is preferably in a range of 2 to 10, more preferably in a range of 2 to 5, still more preferably in a range of 2 to 4, and particularly preferably 3. Examples of the linear alkenyl group include a vinyl group, a propenyl group (an allyl group), and a butynyl group. Examples of the branched alkenyl group include a 1-methylvinyl group, a 2-methylvinyl group, a 1-methylpropenyl group, and a 2-methylpropenyl group.

Among the examples, as the chain-like alkenyl group, a linear alkenyl group is preferable, a vinyl group or a propenyl group is more preferable, and a vinyl group is particularly preferable.

Examples of the substituent for the chain-like alkyl group or alkenyl group as R¹⁰¹ include an alkoxy group, a halogen atom, a halogenated alkyl group, a hydroxyl group, a carbonyl group, a nitro group, an amino group, and a cyclic group as R¹⁰¹.

Among the examples, R¹⁰¹ represents preferably a cyclic group which may have a substituent and more preferably a cyclic hydrocarbon group which may have a substituent. More specifically, as the cyclic hydrocarbon group, a phenyl group, a naphthyl group, or a group in which one or more hydrogen atoms have been removed from a polycycloalkane, a lactone-containing cyclic group represented by any of General Formulae (b2-r-1) to (b2-r-7), or a —SO₂-containing cyclic group represented by any of General Formulae (b5-r-1) to (b5-r-4) is preferable, a group in which one or more hydrogen atoms have been removed from a polycycloalkane or a —SO₂-containing cyclic group represented by any of General Formulae (b5-r-1) to (b5-r-4) is more preferable, and an adamantyl group or a —SO₂-containing cyclic group represented by General Formula (b5-r-1) is still more preferable.

In a case where the cyclic hydrocarbon group has a substituent, it is preferable that the substituent is a hydroxyl group.

In Formula (b-1), Y¹⁰¹ represents a single bond or a divalent linking group having an oxygen atom.

In a case where Y¹⁰¹ represents a divalent linking group containing an oxygen atom, Y¹⁰¹ may contain an atom other than the oxygen atom. Examples of atoms other than an oxygen atom include a carbon atom, a hydrogen atom, a sulfur atom, and a nitrogen atom.

Examples of the divalent linking group having an oxygen atom include a non-hydrocarbon oxygen atom-containing linking group such as an oxygen atom (an ether bond: —O—), an ester bond (—C(═O)—O—), an oxycarbonyl group (—O—C(═O)—), an amide bond (—C(═O)—NH—), a carbonyl group (—C(═O)—), or a carbonate bond (—O—C(═O)—O—); and combinations of the above-described non-hydrocarbon oxygen atom-containing linking groups with an alkylene group. Further, a sulfonyl group (—SO₂—) may be further linked to the combination. Examples of the divalent linking group having an oxygen atom include linking groups each represented by General Formulae (y-al-1) to (y-al-7). Further, in General Formulae (y-al-1) to (y-al-7), V′¹⁰¹ in General Formulae (y-al-1) to (y-al-7) is bonded to R¹⁰¹ in Formula (b-1).

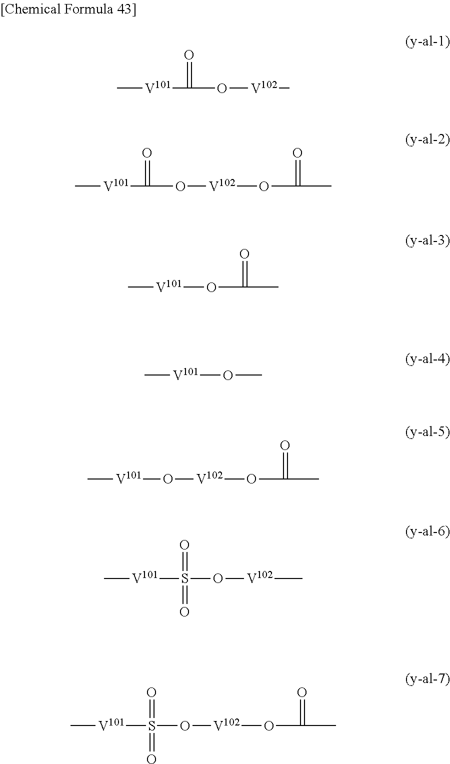

[In the formulae, V′¹⁰¹ represents a single bond or an alkylene group having 1 to 5 carbon atoms, and V′¹⁰² represents a divalent saturated hydrocarbon group having 1 to 30 carbon atoms.]

As the divalent saturated hydrocarbon group as V′¹⁰², an alkylene group having 1 to 30 carbon atoms is preferable, an alkylene group having 1 to 10 carbon atoms is more preferable, and an alkylene group having 1 to 5 carbon atoms is still more preferable.

The alkylene group as V′¹⁰¹ and V′¹⁰² may be a linear alkylene group or a branched alkylene group, and a linear alkylene group is preferable.

Specific examples of the alkylene group as V′¹⁰¹ and V′¹⁰² include a methylene group [—CH₂—]; an alkylmethylene group such as —CH(CH₃)—, —CH(CH₂CH₃)—, —C(CH₃)₂—, —C(CH₃)(CH₂CH₃)—, —C(CH₃)(CH₂CH₂CH₃)—, or —C(CH₂CH₃)₂—; an ethylene group [—CH₂CH₂—]; an alkylethylene group such as —CH(CH₃)CH₂—, —CH(CH₃)CH(CH₃)—, —C(CH₃)₂CH₂—, or —CH(CH₂CH₃)CH₂—; a trimethylene group (n-propylene group) [—CH₂CH₂CH₂—]; an alkyltrimethylene group such as —CH(CH₃)CH₂CH₂— or —CH₂CH(CH₃)CH₂—; a tetramethylene group [—CH₂CH₂CH₂CH₂—]; an alkyltetramethylene group such as —CH(CH₃)CH₂CH₂CH₂— or —CH₂CH(CH₃)CH₂CH₂—; and a pentamethylene group [—CH₂CH₂CH₂CH₂CH₂—].

Further, a part of methylene group in the alkylene group as V′¹⁰¹ and V′¹⁰² may be substituted with a divalent aliphatic cyclic group having 5 to 10 carbon atoms. As the aliphatic cyclic group, a divalent group in which one hydrogen atom has been further removed from the cyclic aliphatic hydrocarbon group (a monocyclic aliphatic hydrocarbon group or a polycyclic aliphatic hydrocarbon group) as Ra′³ in Formula (a1-r-1) is preferable, and a cyclohexylene group, a 1,5-adamantylene group, or a 2,6-adamantylene group is more preferable.

Y¹⁰¹ represents preferably a divalent linking group having an ester bond or a divalent linking group having an ether bond and more preferably a linking group represented by any of Formulae (y-al-1) to (y-al-5).

In Formula (b-1), V¹⁰¹ represents a single bond, an alkylene group, or a fluorinated alkylene group. It is preferable that the alkylene group and the fluorinated alkylene group as V¹⁰¹ have 1 to 4 carbon atoms. Examples of the fluorinated alkylene group as V¹⁰¹ include a group in which some or all hydrogen atoms in the alkylene group as V¹⁰¹ have been substituted with fluorine atoms. Among these examples, it is preferable that V¹⁰¹ represents a single bond or a fluorinated alkylene group having 1 to 4 carbon atoms.

In Formula (b-1), R¹⁰² represents a fluorine atom or a fluorinated alkyl group having 1 to 5 carbon atoms. R¹⁰² represents preferably a fluorine atom or a perfluoroalkyl group having 1 to 5 carbon atoms and more preferably a fluorine atom.

In a case where Y¹⁰¹ represents a single bond, specific example of the anion moiety represented by Formula (b-1) include a fluorinated alkylsulfonate anion such as a trifluoromethanesulfonate anion or a perfluorobutanesulfonate anion. Further, in a case where Y¹⁰¹ represents a divalent linking group having an oxygen atom, specific examples thereof include an anion represented by any of Formulae (an-1) to (an-4).

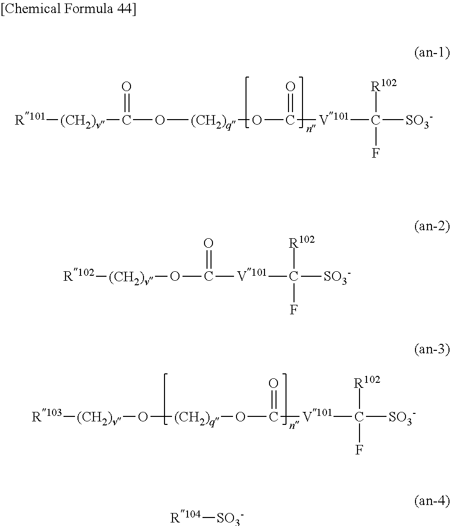

[In the formulae, R″¹⁰¹ represents an aliphatic cyclic group which may have a substituent, a monovalent heterocyclic group represented by any of Chemical Formulae (r-hr-1) to (r-hr-6), a condensed cyclic group represented by Formula (r-br-1) or (r-br-2), or a chain-like alkyl group which may have a substituent. R″¹⁰² represents an aliphatic cyclic group which may have a substituent, a condensed cyclic group represented by Formula (r-br-1) or (r-br-2), a lactone-containing cyclic group represented by any of General Formulae (a2-r-1) and (a2-r-3) to (a2-r-7), or a —SO₂-containing cyclic group represented by any of General Formulae (b5-r-1) to (b5-r-4). R″¹⁰³ represents an aromatic cyclic group which may have a substituent, an aliphatic cyclic group which may have a substituent, or a chain-like alkenyl group which may have a substituent. V″¹⁰¹ represents a single bond, an alkylene group having 1 to 4 carbon atoms, or a fluorinated alkylene group having 1 to 4 carbon atoms. R¹⁰² represents a fluorine atom or a fluorinated alkyl group having 1 to 5 carbon atoms. Each v″ independently represents an integer of 0 to 3, each q″ independently represents an integer of 0 to 20, and n″ represents 0 or 1. R″¹⁰⁴ represents a fluorinated alkyl group.]

As the aliphatic cyclic group as R″¹⁰¹, R″¹⁰², and R″¹⁰³ which may have a substituent, the same groups as those for the cyclic aliphatic hydrocarbon group as R¹⁰¹ in Formula (b-1) are preferable. Examples of the substituent include the same groups as those for the substituent which may substitute the cyclic aliphatic hydrocarbon group as R¹⁰¹ in Formula (b-1).

As the aromatic cyclic group as R″¹⁰³ which may have a substituent, the same groups as those for the aromatic hydrocarbon group in the cyclic hydrocarbon group as R¹⁰¹ in Formula (b-1) are preferable. Examples of the substituent include the same groups as those for the substituent which may substitute the aromatic hydrocarbon group as R¹⁰¹ in Formula (b-1).

As the chain-like alkyl group as R″¹⁰¹ which may have a substituent, the same groups as those for the chain-like alkyl group as R¹⁰¹ in Formula (b-1) are preferable.

As the chain-like alkenyl group as R″¹⁰³ which may have a substituent, the same groups as those for the chain-like alkenyl group as R¹⁰¹ in Formula (b-1) are preferable.

As the fluorinated alkyl group as R″¹⁰⁴ a linear or branched fluorinated alkyl group having 1 to 5 carbon atoms is preferable, a linear or branched perfluoroalkyl group having 1 to 5 carbon atoms is more preferable, and a nonafluorobutyl group is still more preferable.

Anions in Component (b-2)

In Formula (b-2), R¹⁰⁴ and R¹⁰⁵ each independently represent a cyclic group which may have a substituent, a chain-like alkyl group which may have a substituent, or a chain-like alkenyl group which may have a substituent, and examples thereof include the same groups as those for R¹⁰¹ in Formula (b-1). Here, R¹⁰⁴ and R¹⁰⁵ may be bonded to each other to form a ring.

R¹⁰⁴ and R¹⁰⁵ represent preferably a chain-like alkyl group which may have a substituent and more preferably a linear or branched alkyl group or a linear or branched fluorinated alkyl group.

The chain-like alkyl group has preferably 1 to 10 carbon atoms, more preferably 1 to 7 carbon atoms, and still more preferably 1 to 3 carbon atoms. It is preferable that the number of carbon atoms in the chain-like alkyl group as R¹⁰⁴ and R¹⁰⁵ decreases within the range of the number of carbon atoms from the viewpoint that the solubility in a solvent for a resist is also satisfactory. Further, in the chain-like alkyl group as R¹⁰⁴ and R¹⁰⁵, it is preferable that the number of hydrogen atoms substituted with fluorine atoms is as large as possible from the viewpoint that the acid strength increases and the transparency to high energy light or electron beams having a wavelength of 250 nm or less is improved. The proportion of fluorine atoms in the chain-like alkyl group, that is, the fluorination ratio is preferably in a range of 70% to 100% and more preferably in a range of 90% to 100%, and it is most preferable that the chain-like alkyl group is a perfluoroalkyl group in which all hydrogen atoms are substituted with fluorine atoms.

In Formula (b-2). V¹⁰² and V¹⁰³ each independently represent a single bond, an alkylene group, or a fluorinated alkylene group, and examples thereof include the same groups as those for V¹⁰¹ in Formula (b-1).

In Formula (b-2), L¹⁰¹ and L¹⁰² each independently represent a single bond or an oxygen atom.

Anions in Component (b-3)

In Formula (b-3), R¹⁰⁶ to R¹⁰⁸ each independently represent a cyclic group which may have a substituent, a chain-like alkyl group which may have a substituent, or a chain-like alkenyl group which may have a substituent, and examples thereof include the same groups as those for R¹⁰¹ in Formula (b-1).

In Formula (b-3), L¹⁰³ to L¹⁰⁵ each independently represent a single bond, —CO—, or —SO₂—.

Among the examples, as the anion moiety of the component (B), an anion in the component (b-1) is preferable. Among the examples, an anion represented by any of General Formulae (an-1) to (an-3) is more preferable, an anion represented by General Formula (an-1) or (an-2) is still more preferable, and an anion represented by General Formula (an-2) is particularly preferable.

### {Cation Moiety}

In Formulae (b-1), (b-2), and (b-3). M^{m+} represents an m-valent onium cation. Among these, a sulfonium cation and an iodonium cation are preferable.

m represents an integer of 1 or greater.

Preferred examples of the cation moiety ((M^{m+})_{t/m}) include organic cations each represented by General Formulae (ca-1) to (ca-5).

Among the examples, a cation represented by General Formula (ca-1) is preferable as the cation moiety ((M^{m+})_{t/m}).

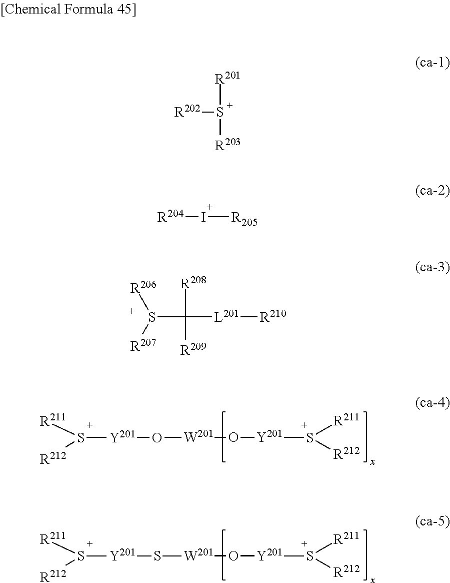

[In the formulae, R²⁰¹ to R²⁰⁷, R²¹¹, and R²¹² each independently represent an aryl group which may have a substituent, an alkyl group which may have a substituent, or an alkenyl group which may have a substituent. R²⁰¹ to R²⁰³, R²⁰⁶ and R²⁰⁷, and R²¹¹ and R²¹² may be bonded to each other to form a ring with the sulfur atom in the formula. R²⁰⁸ and Rx each independently represent a hydrogen atom or an alkyl group having 1 to 5 carbon atoms. R²¹⁰ represents an aryl group which may have a substituent, an alkyl group which may have a substituent, an alkenyl group which may have a substituent, or a SO₂-containing cyclic group which may have a substituent. L²⁰¹ represents —C(═O)— or —C(═O)—O—. Y²⁰¹'s each independently represent an arylene group, an alkylene group, or an alkenylene group. x represents 1 or 2. W²⁰¹ represents an (x+1)-valent linking group.]

In General Formulae (ca-1) to (ca-5), examples of the aryl group as R²⁰¹ to R²⁰⁷, R²¹¹, and R²¹² include an unsubstituted aryl group having 6 to 20 carbon atoms. Among these, a phenyl group or a naphthyl group is preferable.

The alkyl group as R²⁰¹ to R²⁰⁷, R²¹¹, and R²¹² is a chain-like or cyclic alkyl group, and the number of carbon atoms thereof is preferably in a range of 1 to 30.

It is preferable that the alkenyl group as R²⁰¹ to R²⁰⁷, R²¹¹, and R²¹² has 2 to 10 carbon atoms.

Examples of the substituent which may be included in R²⁰¹ to R²⁰⁷ and R²¹⁰ to R²¹² include an alkyl group, a halogen atom, a halogenated alkyl group, a carbonyl group, a cyano group, an amino group, an aryl group, and groups each represented by General Formulae (ca-r-1) to (ca-r-7).

In General Formulae (ca-1) to (ca-5), in a case where R²⁰¹ to R²⁰³, R²⁰⁶ and R²⁰⁷, and R²¹¹ and R²¹² are bonded to each other to form a ring with a sulfur atom in the formula, these groups may be bonded to each other via a heteroatom such as a sulfur atom, an oxygen atom, or a nitrogen atom, or a functional group such as a carbonyl group, —SO—, —SO₂—, —SO₃—, —COO—, —CONH— or —N(RN)— (here, RN represents an alkyl group having 1 to 5 carbon atoms). As a ring to be formed, a ring containing the sulfur atom in the formula in the ring skeleton thereof is preferably a 3- to 10-membered ring and particularly preferably a 5- to 7-membered ring containing the sulfur atom. Specific examples of the ring to be formed include a thiophene ring, a thiazole ring, a benzothiophene ring, a benzothiophene ring, a dibenzothiophene ring, a 9H-thioxanthene ring, a thioxanthone ring, a thianthrene ring, a phenoxathiin ring, a tetrahydrothiophenium ring, and a tetrahydrothiopyranium ring.

R²⁰⁸ and R²⁰⁹ each independently represent a hydrogen atom or an alkyl group having 1 to 5 carbon atoms and preferably a hydrogen atom or an alkyl group having 1 to 3 carbon atoms. In a case where R²⁰⁸ and R²⁰⁹ represent an alkyl group, R²⁰⁸ and R²⁰⁹ may be bonded to each other to form a ring.

R²¹⁰ represents an aryl group which may have a substituent, an alkyl group which may have a substituent, an alkenyl group which may have a substituent, or a SO₂-containing cyclic group which may have a substituent.

Examples of the aryl group as R²¹⁰ include an unsubstituted aryl group having 6 to 20 carbon atoms. Among these, a phenyl group or a naphthyl group is preferable.

As the alkyl group as R²¹⁰, a chain-like or cyclic alkyl group having 1 to 30 carbon atoms is preferable.

It is preferable that the alkenyl group as R²¹⁰ has 2 to 10 carbon atoms.

As the SO₂-containing cyclic group as R²¹⁰ which may have a substituent. “—SO₂-containing polycyclic group” is preferable, and a group represented by General Formula (b5-r-1) is more preferable.

Y²⁰¹'s each independently represent an arylene group, an alkylene group, or an alkenylene group.

Examples of the arylene group as Y²⁰¹ include a group in which one hydrogen atom has been removed from an aryl group exemplified as the aromatic hydrocarbon group represented by R¹⁰¹ in Formula (b-1).

Examples of the alkylene group and alkenylene group as Y²⁰¹ include a group in which one hydrogen atom has been removed from the group exemplified as the chain-like alkyl group or the chain-like alkenyl group as R¹⁰¹ in Formula (b-1).

In Formula (ca-4), x represents 1 or 2.

W²⁰¹ represents an (x+1)-valent linking group, that is, a divalent or trivalent linking group.

As the divalent linking group represented by W²⁰¹, a divalent hydrocarbon group which may have a substituent is preferable, and examples thereof include the same divalent hydrocarbon groups which may have a substituent as those for Lz¹ in General Formula (z-1). The divalent linking group as W may be any of linear, branched, or cyclic and is preferably cyclic. Among these, a group in which two carbonyl groups are combined with both ends of the arylene group is preferable. Examples of the arylene group include a phenylene group and a naphthylene group. Among these, a phenylene group is particularly preferable.

Examples of the trivalent linking group as W²⁰¹ include a group in which one hydrogen atom has been removed from the above-described divalent linking group as W²⁰¹ and a group obtained by bonding the divalent linking group to another divalent linking group described above. As the trivalent linking group as W²⁰¹, a group obtained by bonding two carbonyl groups to an arylene group is preferable.

Specific examples of suitable cations represented by Formula (ca-1) include cations each represented by Chemical Formulae (ca-1-1) to (ca-1-70).

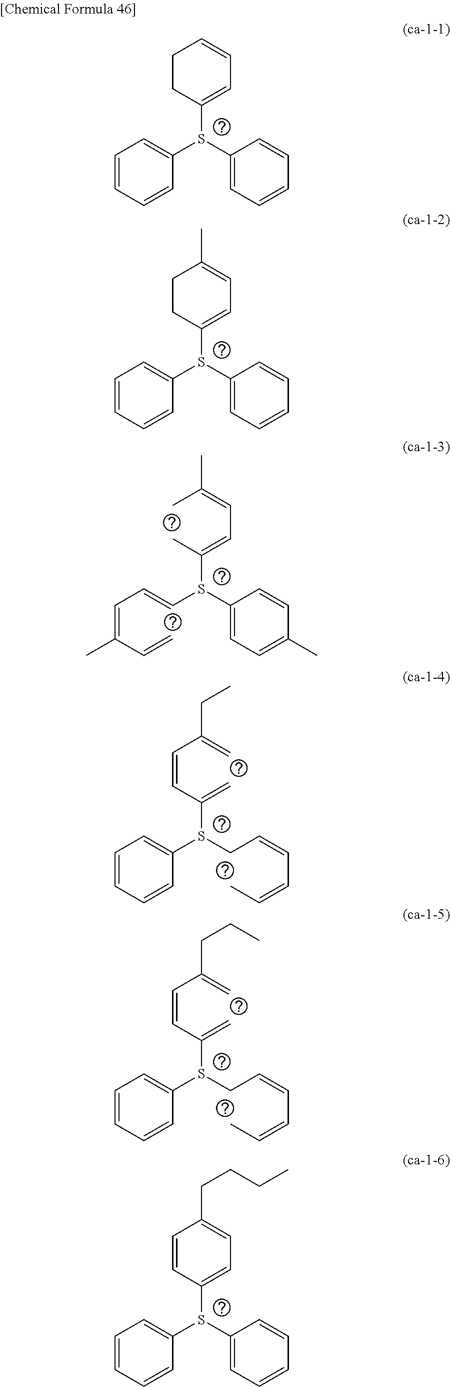

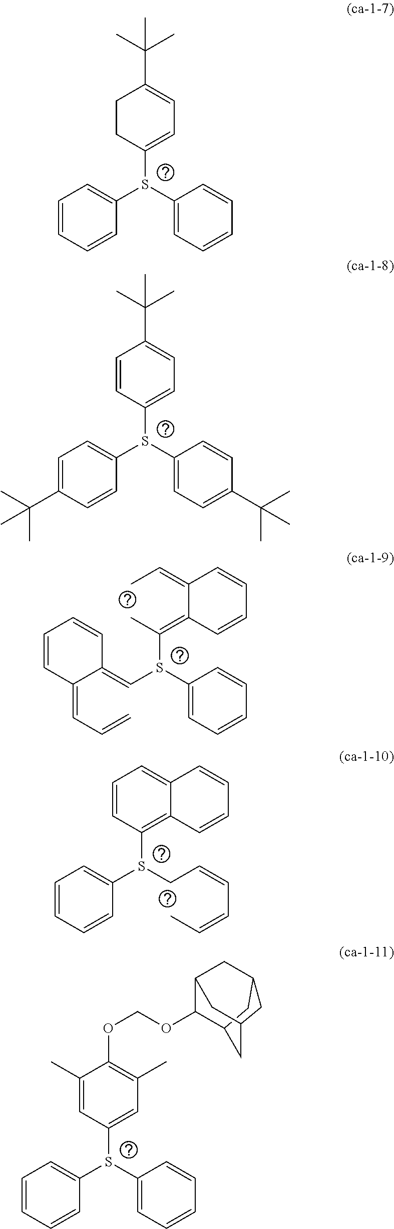

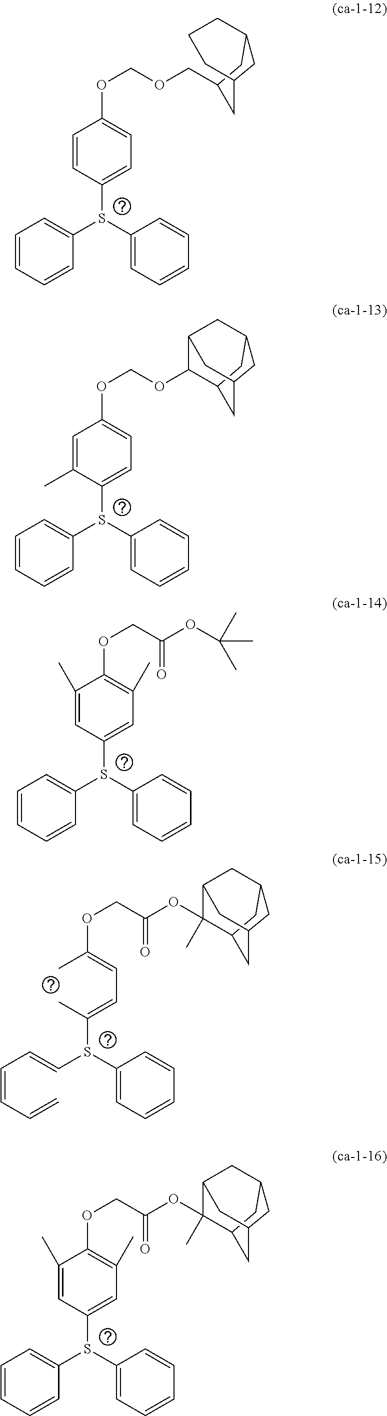

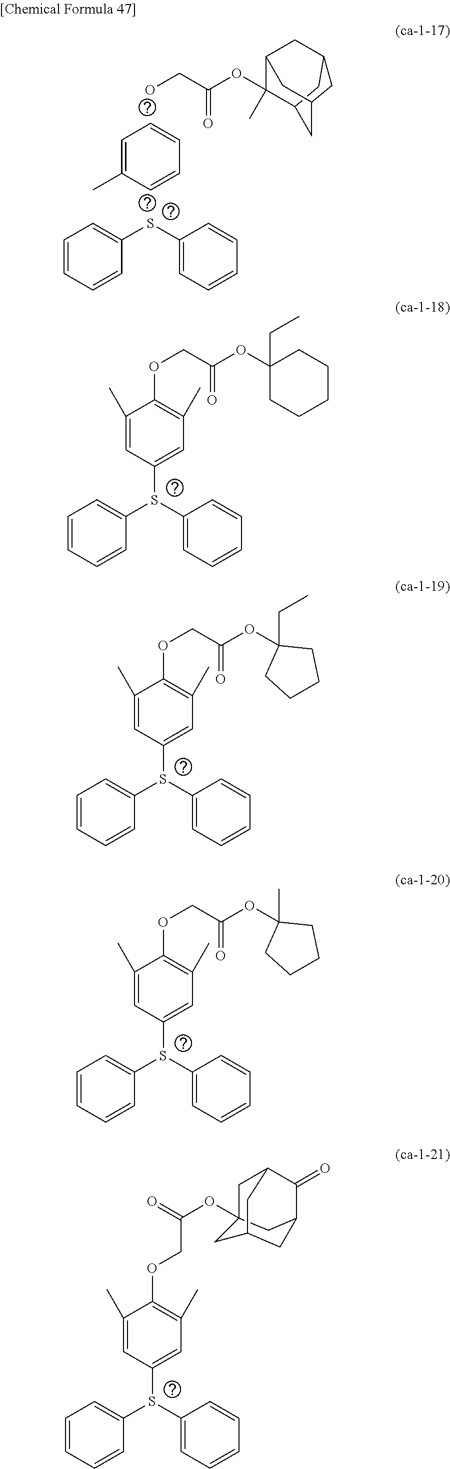

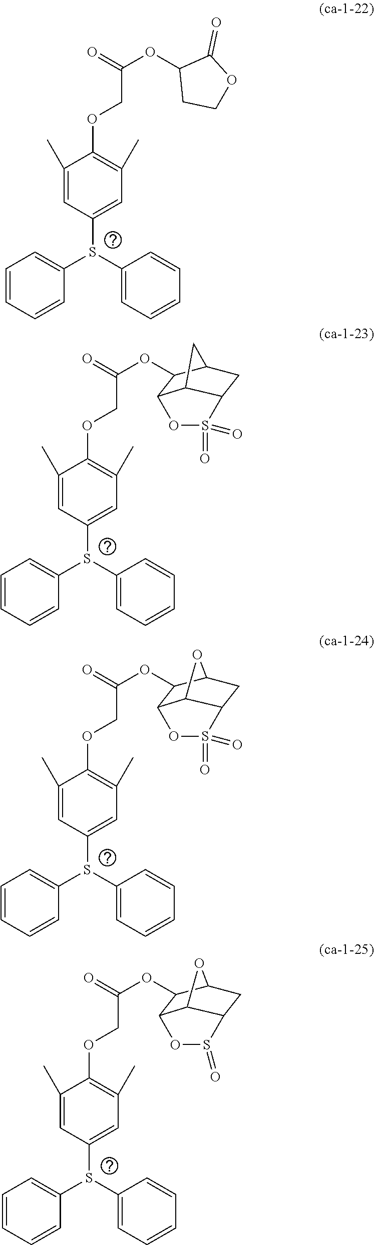

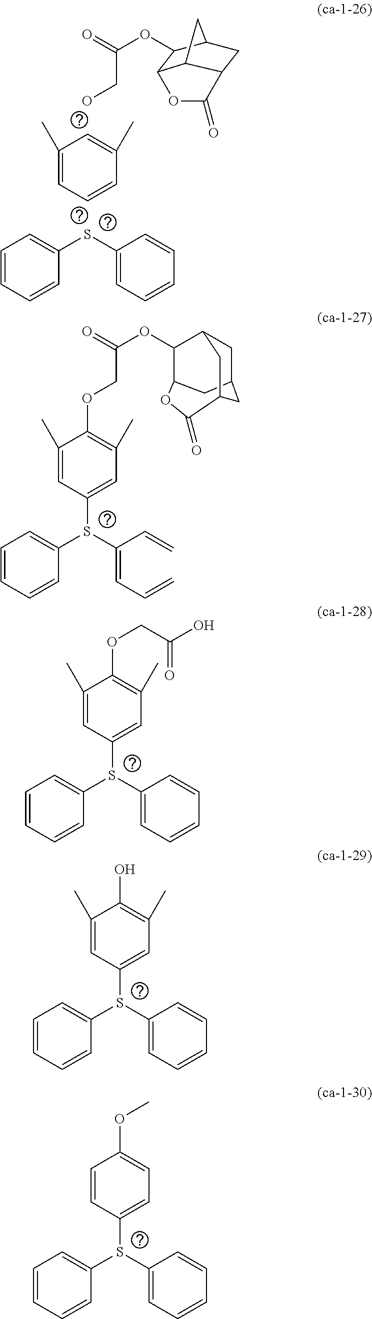

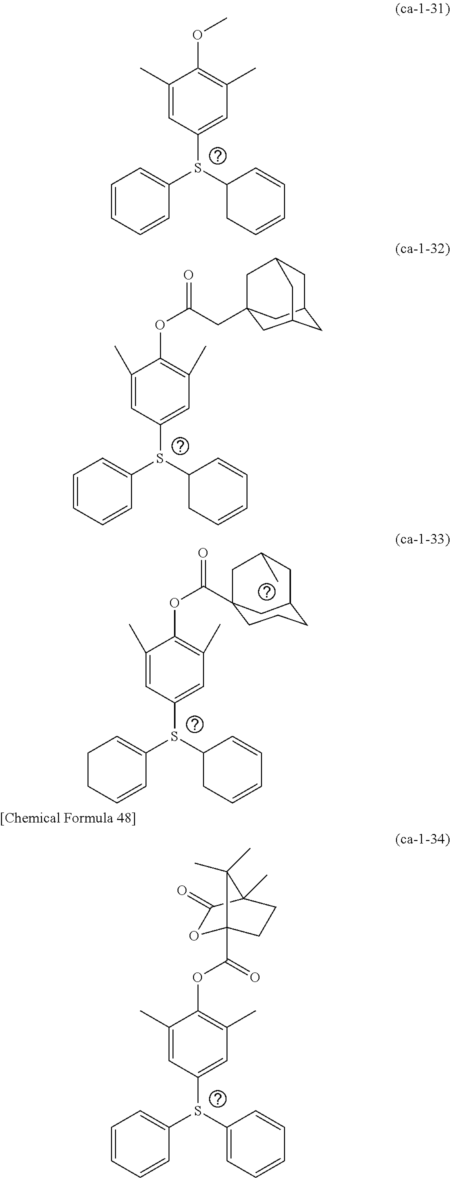

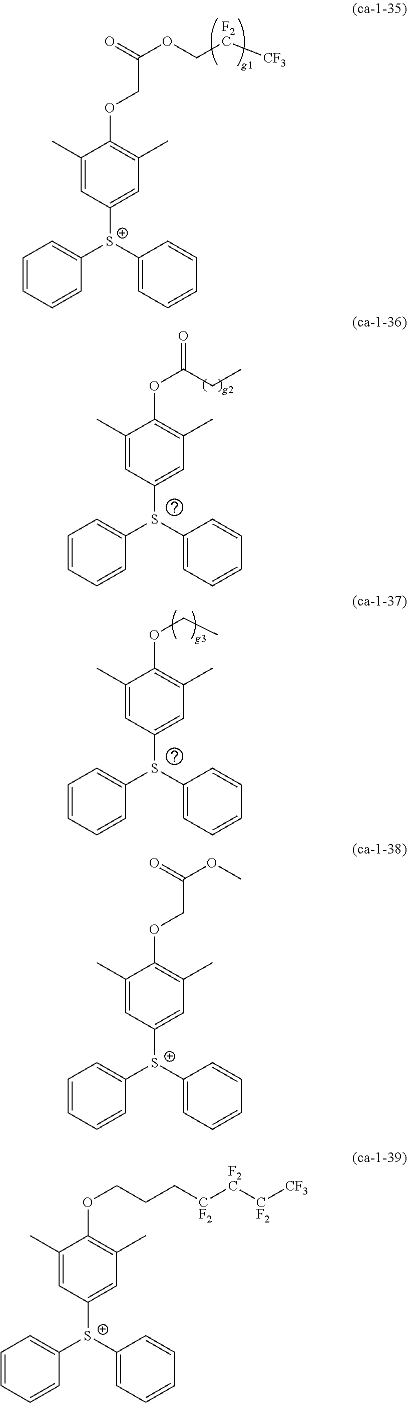

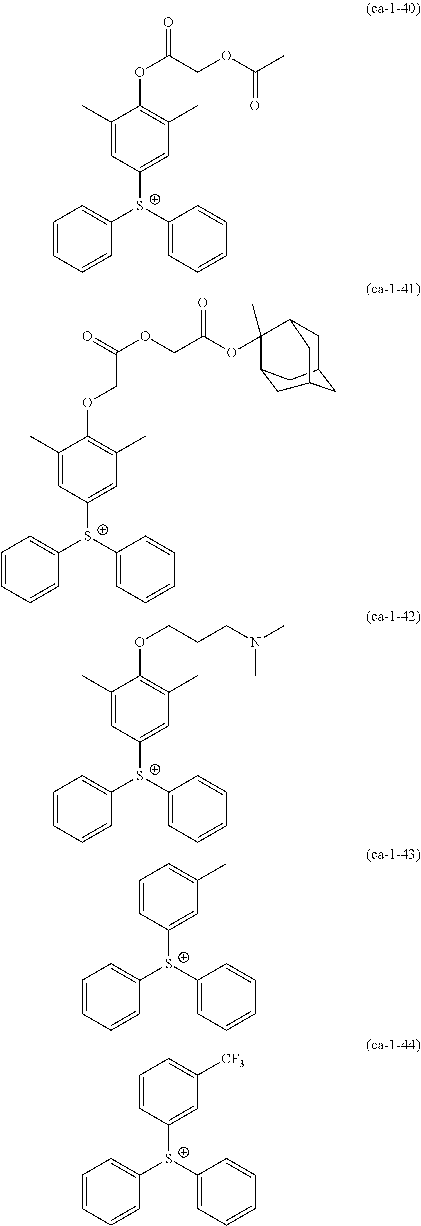 [SMILES: CC(=O)OCC(=O)Oc1c(C)cc([S+](c2ccccc2)c2ccccc2)cc1C ; Cc1cc([S+](c2ccccc2)c2ccccc2)cc(C)c1OCC(=O)OCC(=O)OC1(C)C2CC3CC(C2)CC1C3 ; Cc1cc([S+](c2ccccc2)c2ccccc2)cc(C)c1OCCCN(C)C ; Cc1cccc([S+](c2ccccc2)c2ccccc2)c1 ; FC(F)(F)c1cccc([S+](c2ccccc2)c2ccccc2)c1]

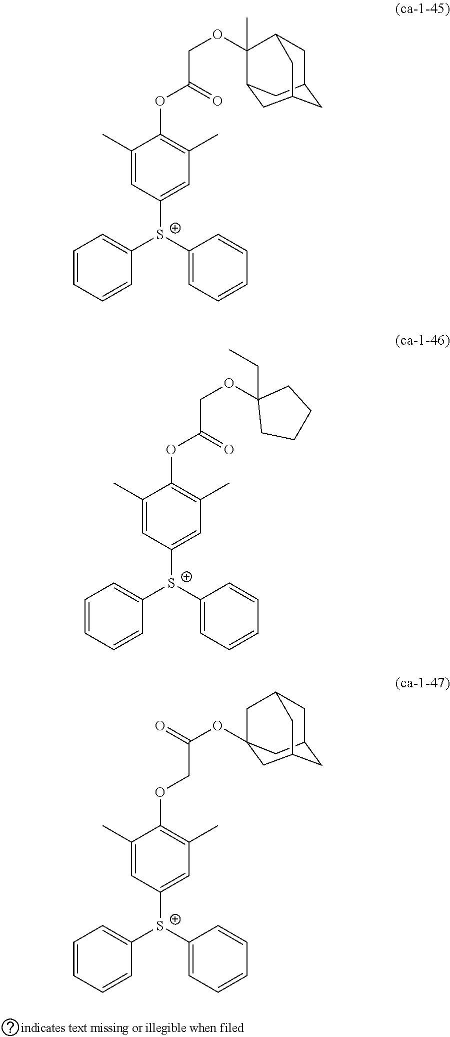 [SMILES: Cc1cc([S+](c2ccccc2)c2ccccc2)cc(C)c1OC(=O)COC1(C)C2CC3CC(C2)CC1C3 ; CCC1(OCC(=O)Oc2c(C)cc([S+](c3ccccc3)c3ccccc3)cc2C)CCCC1 ; Cc1cc([S+](c2ccccc2)c2ccccc2)cc(C)c1OCC(=O)OC12CC3CC(CC(C3)C1)C2]

[In the formulae, g1, g2, and g3 represent a repeating number, g1 represents an integer of 1 to 5, g2 represents an integer of 0 to 20, and g3 represents an integer of 0 to 20.]

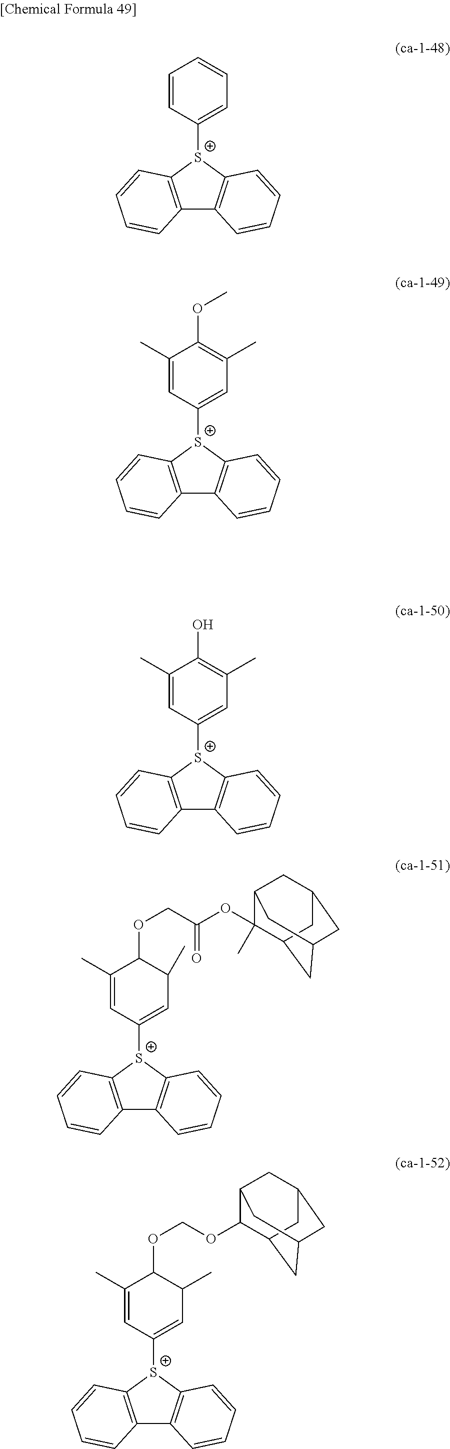 [SMILES: c1ccc(-[s+]2c3ccccc3c3ccccc32)cc1 ; COc1c(C)cc(-[s+]2c3ccccc3c3ccccc32)cc1C ; Cc1cc(-[s+]2c3ccccc3c3ccccc32)cc(C)c1O ; CC1=CC([s+]2c3ccccc3c3ccccc32)=CC(C)C1OCC(=O)OC1(C)C2CC3CC(C2)CC1C3 ; CC1=CC([s+]2c3ccccc3c3ccccc32)=CC(C)C1OCOC1C2CC3CC(C2)CC1C3]

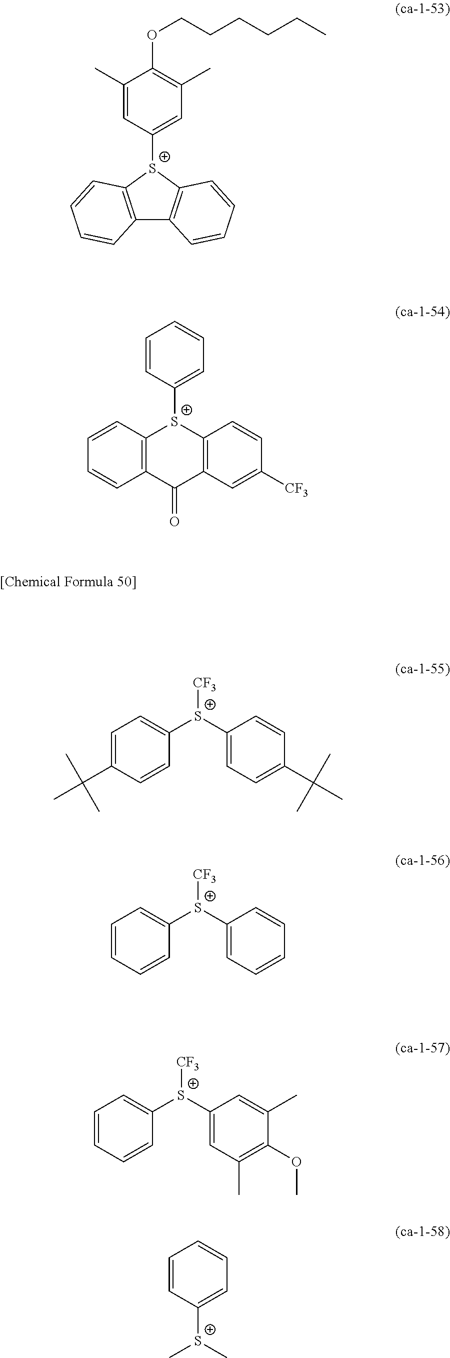

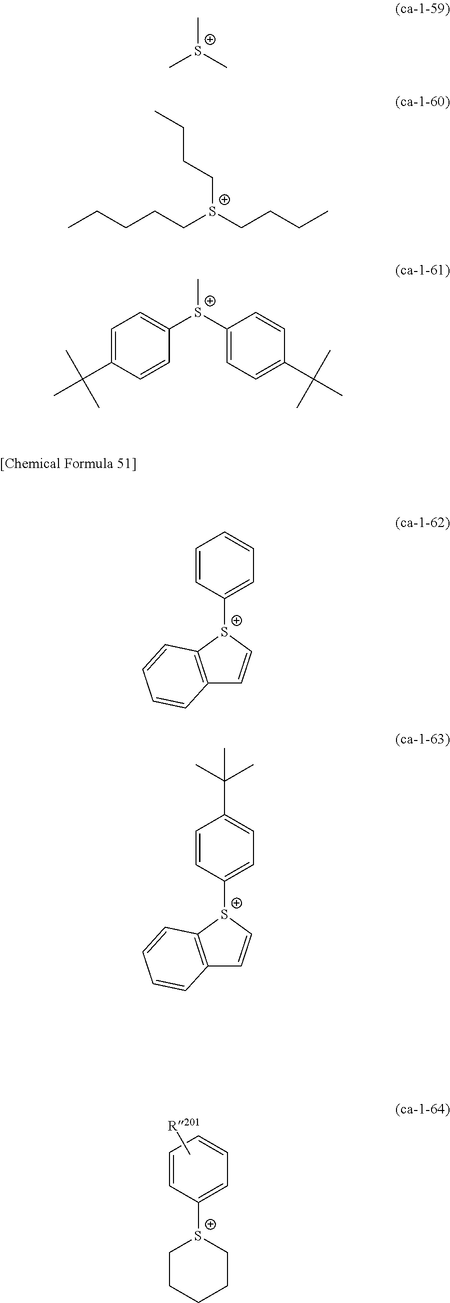

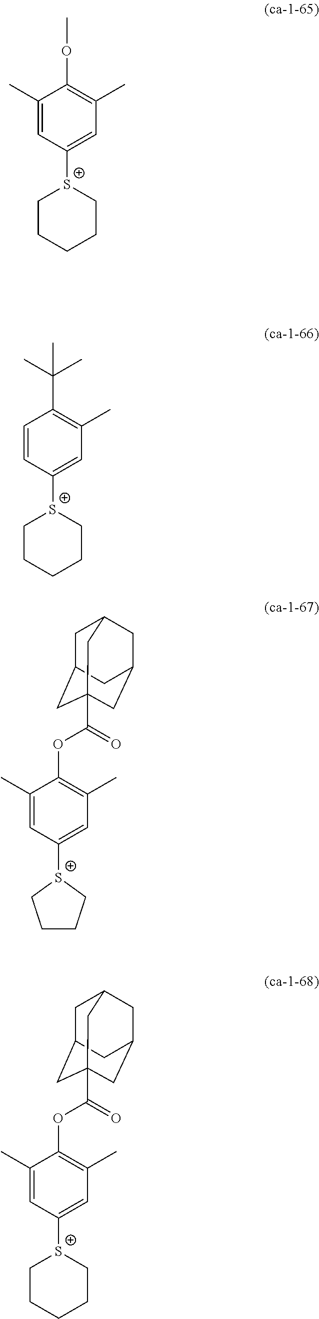

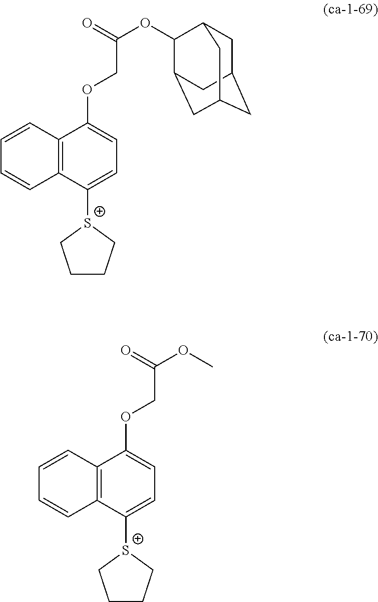 [SMILES: O=C(COc1ccc([S+]2CCCC2)c2ccccc12)OC1C2CC3CC(C2)CC1C3 ; COC(=O)COc1ccc([S+]2CCCC2)c2ccccc12]

[In the formulae, R″²⁰¹ represents a hydrogen atom or a substituent, and examples of the substituent include the same groups as those for the substituents that R²⁰¹ to R²⁰⁷ and R²¹⁰ to R²¹² may have.]

Specific examples of suitable cations represented by Formula (ca-2) include a diphenyliodonium cation and a bis(4-tert-butylphenyl)iodonium cation.

Specific examples of suitable cations represented by Formula (ca-3) include cations each represented by Formulae (ca-3-1) to (ca-3-6).

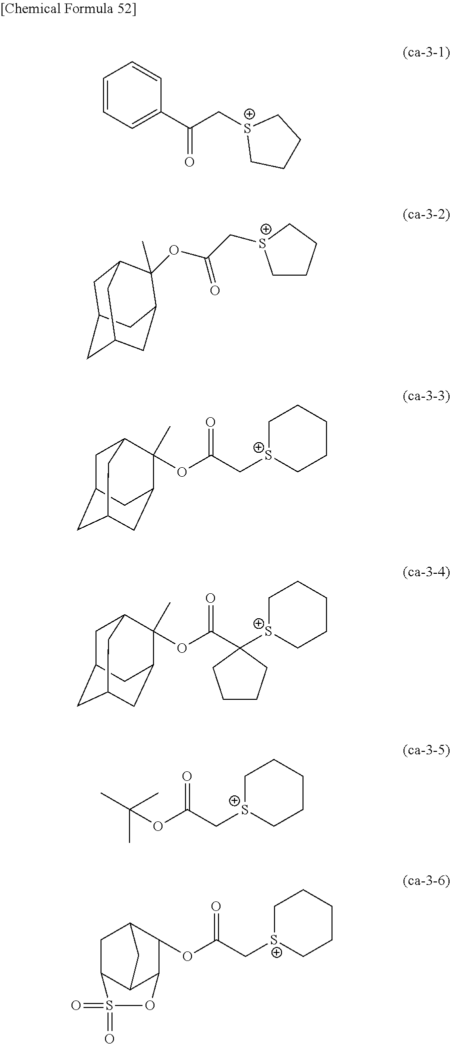 [SMILES: O=C(C[S+]1CCCC1)c1ccccc1 ; CC1(OC(=O)C[S+]2CCCC2)C2CC3CC(C2)CC1C3 ; CC1(OC(=O)C[S+]2CCCCC2)C2CC3CC(C2)CC1C3 ; CC1(OC(=O)C2([S+]3CCCCC3)CCCC2)C2CC3CC(C2)CC1C3 ; CC(C)(C)OC(=O)C[S+]1CCCCC1 ; O=C(C[S+]1CCCCC1)OC1C2CC3C1OS(=O)(=O)C3C2]

Specific examples of suitable cations represented by Formula (ca-4) include cations each represented by Formulae (ca-4-1) and (ca-4-2).

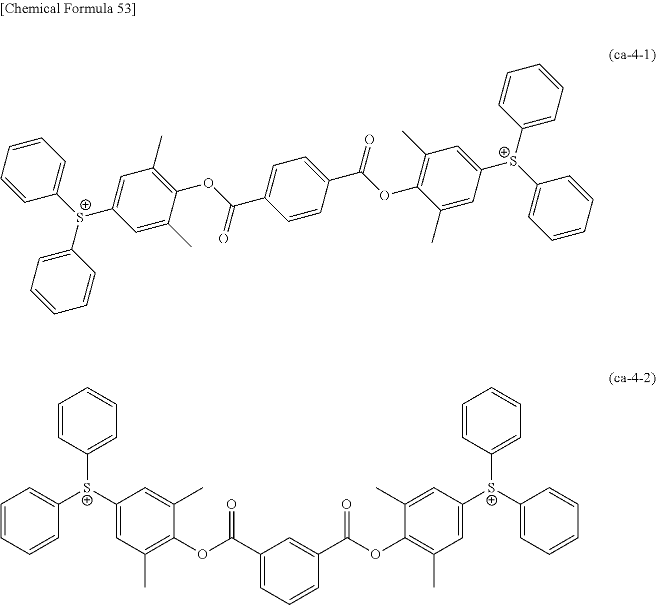 [SMILES: Cc1cc([S+](c2ccccc2)c2ccccc2)cc(C)c1OC(=O)c1ccc(C(=O)Oc2c(C)cc([S+](c3ccccc3)c3ccccc3)cc2C)cc1 ; Cc1cc([S+](c2ccccc2)c2ccccc2)cc(C)c1OC(=O)c1cccc(C(=O)Oc2c(C)cc([S+](c3ccccc3)c3ccccc3)cc2C)c1]

Specific examples of suitable cations represented by Formula (ca-5) include cations each represented by General Formulae (ca-5-1) and (ca-5-3).

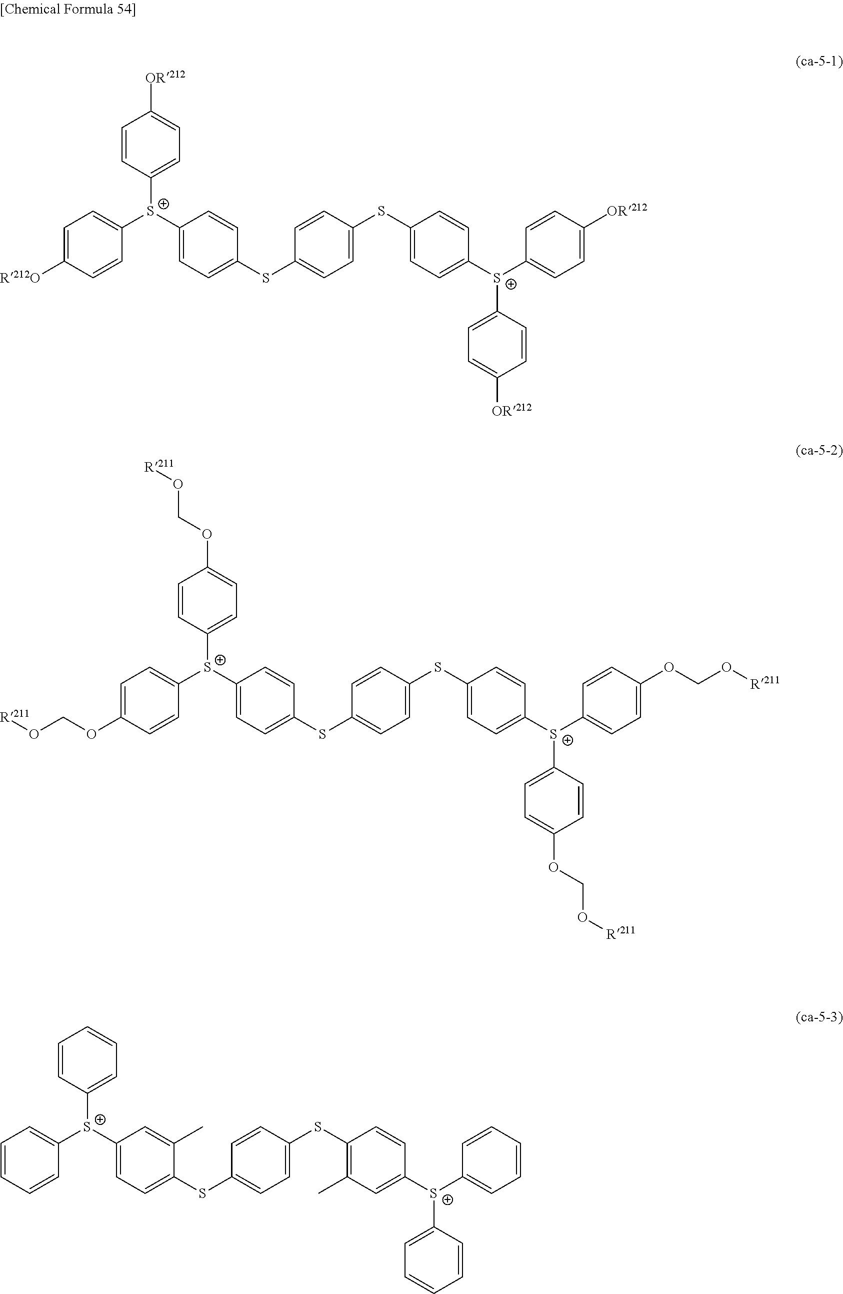

Among the examples, a cation represented by General Formula (ca-1) is preferable as the cation moiety ((M^{m+})_{t/m}).

In the present embodiment, it is preferable that the component (B1) contains an acid generation agent (B1-1) represented by General Formula (b1-1).

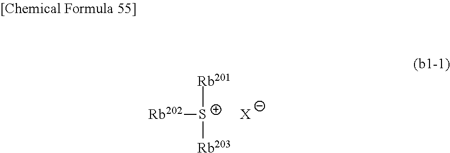

[In the formula, Rb²⁰¹ to Rb²⁰³ each independently represent an aryl group which may have a substituent, an alkyl group which may have a substituent, or an alkenyl group which may have a substituent. R²⁰¹ to R²⁰³ may be bonded to each other to form a ring with the sulfur atoms in the formula. X⁻ represents a counter anion.]

In Formula (b1-1), Rb²⁰¹ and Rb²⁰³ each have the same definition as that for R²⁰¹ to R²⁰³ in Formula (ca-1). Among the examples, it is preferable that Rb²⁰³ to Rb²⁰³ each independently represent an aryl group which may have a substituent or Rb²⁰¹ represents an aryl group which may have a substituent and Rb²⁰² and Rb²⁰³ are bonded to each other to form a ring with the sulfur atom in the formula, more preferable that Rb²⁰¹ represents an aryl group which may have a substituent and Rb²⁰² and Rb²⁰³ are bonded to each other to form a ring with the sulfur atom in the formula, and still more preferable that Rb²⁰¹ represents an aryl group which may have a substituent and Rb²⁰² and Rb²⁰³ are bonded to each other to form a tetrahydrothiophenium ring or a tetrahydrothiopyranium ring with the sulfur atom in the formula.

In Formula (b1-1), as the counter anion represented by X⁻, an anion of the component (b-1), an anion of the component (b-2), or an anion of the component (b-3) is preferable, an anion of the component (b-1) is more preferable, an anion represented by any of Formulae (an-1) to (an-4) is still more preferable, and an anion represented by Formula (an-1) or (an-4) is even still more preferable.

In the resist composition according to the present embodiment, the component (B1) may be used alone or in combination of two or more kinds thereof.

The content of the component (B1) in the resist composition according to the present embodiment is preferably in a range of 50 parts by mass or less, more preferably in a range of 0.1 to 40 parts by mass, still more preferably in a range of 0.1 to 30 parts by mass, and particularly preferably in a range of 0.1 to 20 parts by mass with respect to 100 parts by mass of the component (A1).

In a case where the content of the component (B1) is set to be in the above-described preferable ranges, pattern formation can be sufficiently carried out. Further, it is preferable that each component of the resist composition is dissolved in an organic solvent from the viewpoint that a uniform solution is easily obtained and the storage stability of the resist composition is improved.

### <Optional Components>

### <<Component (D)>>

The resist composition according to the present embodiment may further contain an acid diffusion control agent component (hereinafter, referred to as “component (D)”). The component (D) acts as a quencher (an acid diffusion control agent) which traps the acid generated in the resist composition upon light exposure.

Examples of the component (D) include a nitrogen-containing organic compound (D1) (hereinafter, referred to as “component (D1)”) and a photodecomposable base (D2) (hereinafter, referred to as “component (D2)”) which does not correspond to the component (D1) and has acid diffusion controllability that is lost by the decomposition upon light exposure.

In a case where a resist composition containing the component (D) is obtained, the contrast between the exposed portion and the unexposed portion of the resist film can be further improved at the time of the formation of a resist pattern.

From the viewpoint of improving the transmittance of the resist film to the exposure light source in a case of forming a thick resist pattern, the component (D1) is preferable as the component (D).

### In Regard to Component (D1)

The component (D1) is a base component and is a nitrogen-containing organic compound component that acts as an acid diffusion control agent in the resist composition.

The component (D1) is not particularly limited as long as the component acts as an acid diffusion control agent, and examples thereof include aliphatic amines and an aromatic amines.

Among these, the aliphatic amine is preferably a secondary aliphatic amine or a tertiary aliphatic amine.

The aliphatic amine is an amine containing one or more aliphatic groups, and the number of carbon atoms in the aliphatic group is preferably in a range of 1 to 12.

Examples of the aliphatic amine include an amine obtained by substituting at least one hydrogen atom of ammonia NH₃ with an alkyl group or hydroxyalkyl group having 12 or less carbon atoms (an alkylamine or an alkylalcoholamine) and a cyclic amine.

Specific examples of the alkylamines and the alkylalcoholamines include monoalkylamines such as n-hexylamine, n-heptylamine, n-octylamine, n-nonylamine, and n-decylamine; dialkylamines such as diethylamine, di-n-propylamine, di-n-heptylamine, di-n-octylamine, and dicyclohexylamine; trialkylamines such as trimethylamine, triethylamine, tri-n-propylamine, tri-n-butylamine, tri-n-pentylamine, tri-n-hexylamine, tri-n-heptylamine, tri-n-octylamine, tri-n-nonylamine, tri-n-decylamine, and tri-n-dodecylamine; and alkylalcoholamines such as diethanolamine, triethanolamine, diisopropanolamine, triisopropanolamine, di-n-octanolamine, and tri-n-octanolamine. Among these, trialkylamine having 6 to 30 carbon atoms is preferable, and tri-n-pentylamine or tri-n-octylamine is particularly preferable.

Examples of the cyclic amine include a heterocyclic compound having a nitrogen atom as a heteroatom. The heterocyclic compound may be a monocyclic compound (aliphatic monocyclic amine) or a polycyclic compound (aliphatic polycyclic amine).

Specific examples of the aliphatic monocyclic amine include piperidine and piperazine.

The aliphatic polycyclic amine preferably has 6 to 10 carbon atoms, and specific examples thereof include 1, 5-diazabicyclo[4.3.0]-5-nonene, 1,8-diazabicyclo[5.4.0]-7-undecene, hexamethylenetetramine, and 1,4-diazabicyclo[2.2.2]octane.

Examples of other aliphatic amines include tris(2-methoxymethoxyethyl)amine, tris{2-(2-methoxyethoxy)ethyl}amine, tris{2-(2-methoxyethoxymethoxy)ethyl}amine, tris{2-(1-methoxyethoxy)ethyl}amine, tris{2-(1-ethoxyethoxy)ethyl}amine, tris{2-(1-ethoxypropoxy)ethyl}amine, tris[2-{2-(2-hydroxyethoxy)ethoxy}ethyl]amine and triethanol amine triacetate, and triethanol amine triacetate is preferable.

Examples of aromatic amines include 4-dimethylaminopyridine, pyrrole, indole, pyrazole, imidazole, and derivatives thereof, tribenzylamine, an aniline compound such as 2,6-diisopropylaniline, 2,6-di-tert-butylpyridine, and N-tert-butoxycarbonylpyrrolidine.

The component (D1) may be used alone or in a combination of two or more kinds thereof.

Among the examples, the component (D1) is preferably an alkyl amine or an aromatic amine, more preferably an alkyl amine, and still more preferably a trialkyl amine having 6 to 30 carbon atoms.

In a case where the resist composition contains the component (D1), the content of the component (D1) in the resist composition is preferably in a range of 0.001 to 10 parts by mass, more preferably in a range of 0.002 to 1 part by mass, and still more preferably in a range of 0.005 to 0.1 parts by mass with respect to 100 parts by mass of the component (A).

In a case where the content of the component (D1) is greater than or equal to the lower limits of the above-described preferable ranges, satisfactory lithography characteristics and a satisfactory resist pattern shape are likely to be obtained. Meanwhile, in a case where the content thereof is less than or equal to the above-described upper limits, the balance between the component (D1) and other components can be achieved, and thus various lithography characteristics are enhanced.

### In Regard to Component (D2)

The component (D2) is not particularly limited as long as the component is decomposed upon light exposure and loses the acid diffusion controllability, and one or more compounds selected from the group consisting of a compound represented by Formula (d2-1) (hereinafter, referred to as “component (d2-1)”), a compound represented by Formula (d2-2) (hereinafter, referred to as “component (d2-2)”), and a compound represented by Formula (d2-3) (hereinafter, referred to as “component (d2-3)”) are preferable.

At exposed portions of the resist film, the components (d2-1) to (d2-3) are decomposed and then lose the acid diffusion controllability (basicity), and therefore the components (d2-1) to (d2-3) cannot act as a quencher, whereas the components (d2-1) to (d2-3) act as a quencher at unexposed portions of the resist film.

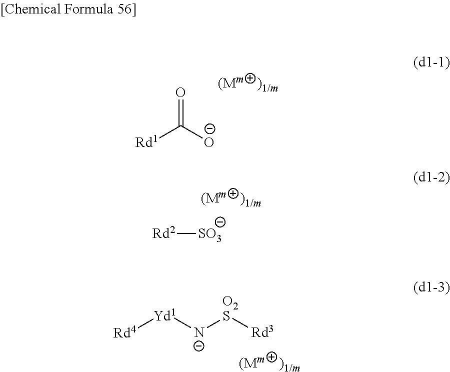

[In the formulae, Rd¹ to Rd⁴ represent a cyclic group which may have a substituent, a chain-like alkyl group which may have a substituent, or a chain-like alkenyl group which may have a substituent. Here, the carbon atom adjacent to the S atom as Rd² in General Formula (d2-2) has no fluorine atom bonded thereto. Yd¹ represents a single bond or a divalent linking group. m represents an integer of 1 or greater, and M′^{m+}'s each independently represent an m-valent onium cation.]

{Component (d2-1)}

### Anion Moiety

In Formula (d2-1), Rd¹ represents a cyclic group which may have a substituent, a chain-like alkyl group which may have a substituent, or a chain-like alkenyl group which may have a substituent, and examples thereof include the same groups as those for R¹⁰¹ in Formula (b-1).

Among these, it is preferable that Rd¹ represents an aromatic hydrocarbon group which may have a substituent, an aliphatic cyclic group which may have a substituent, or a chain-like alkyl group which may have a substituent. Examples of the substituent that these groups may have include a hydroxyl group, an oxo group, an alkyl group, an aryl group, a fluorine atom, a fluorinated alkyl group, the lactone-containing cyclic groups each represented by General Formulae (a2-r-1) to (a2-r-7), an ether bond, an ester bond, or a combination thereof. In a case where an ether bond or an ester bond is included as the substituent, the substituent may be bonded through an alkylene group, and a linking group represented by any of Formulae (y-al-1) to (y-al-5) is preferable as the substituent.

Suitable examples of the aromatic hydrocarbon group include a phenyl group, a naphthyl group, and a polycyclic structure (for example, a polycyclic structure composed of a ring structure of a bicyclooctane skeleton and a ring structure other than the bicyclooctane skeleton).

As the aliphatic cyclic group, a group in which one or more hydrogen atoms have been removed from a polycycloalkane such as adamantane, norbornane, isobornane, tricyclodecane or tetracyclododecane is more preferable.

It is preferable that the chain-like alkyl group has 1 to 10 carbon atoms, and specific examples thereof include a linear alkyl group such as a methyl group, an ethyl group, a propyl group, a butyl group, a pentyl group, a hexyl group, a heptyl group, an octyl group, a nonyl group, or a decyl group; and a branched alkyl group such as a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group, or a 4-methylpentyl group.

In a case where the chain-like alkyl group is a fluorinated alkyl group having a fluorine atom or a fluorinated alkyl group as a substituent, the fluorinated alkyl group has preferably 1 to 11 carbon atoms, more preferably 1 to 8 carbon atoms, and still more preferably 1 to 4 carbon atoms. The fluorinated alkyl group may have an atom other than a fluorine atom. Examples of the atom other than a fluorine atom include an oxygen atom, a sulfur atom, and a nitrogen atom.

Rd¹ represents preferably a fluorinated alkyl group in which some or all hydrogen atoms constituting a linear alkyl group have been substituted with fluorine atoms and particularly preferably a fluorinated alkyl group (linear perfluoroalkyl group) in which all hydrogen atoms constituting a linear alkyl group have been substituted with a fluorine atom.

Specific preferred examples of the anion moiety in the component (d2-1) are shown below.

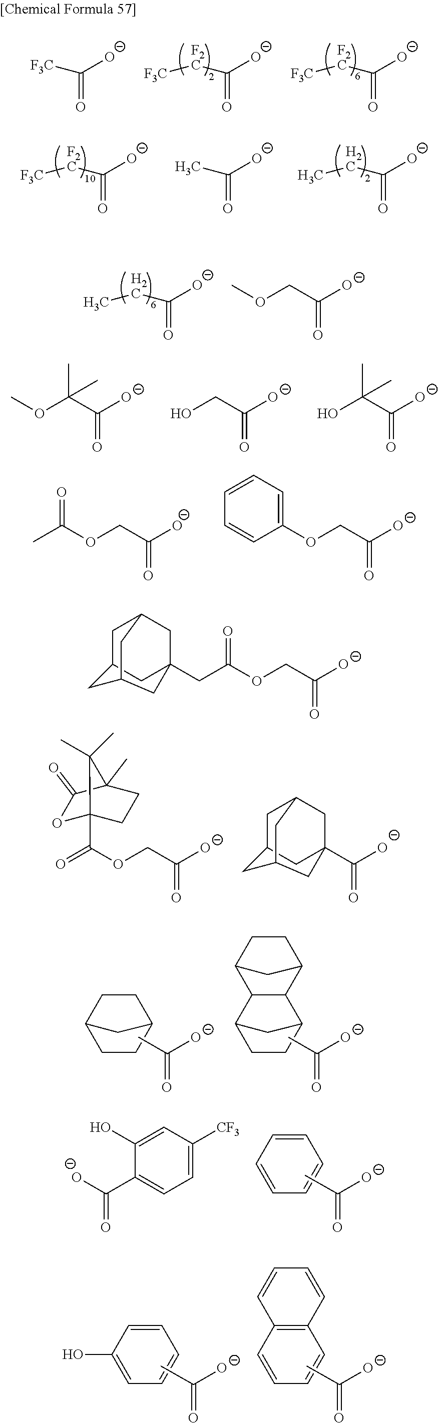

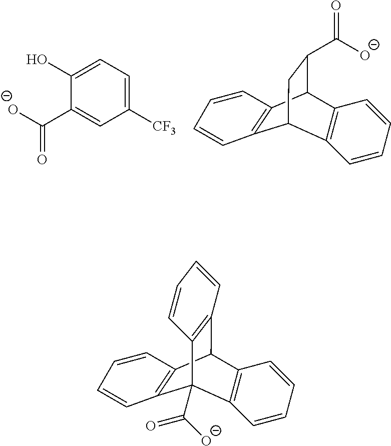 [SMILES: O=C([O-])c1cc(C(F)(F)F)ccc1O ; O=C([O-])C1CC2c3ccccc3C1c1ccccc12 ; O=C([O-])C12c3ccccc3C(c3ccccc31)c1ccccc12]

### Cation Moiety

In Formula (d2-1), M′^{m+} represents an m-valent onium cation.

Suitable examples of the onium cation as M′^{m+} include the same cations as the cations each represented by General Formulae (ca-1) to (ca-4), a cation represented by General Formula (ca-1) is more preferable, and a cation represented by any of Formulae (ca-1-1) to (ca-1-78) and (ca-1-101) to (ca-1-149) are still more preferable.

The component (d2-1) may be used alone or in combination of two or more kinds thereof.

{Component (d2-2)}

### Anion Moiety

In Formula (d2-2), Rd² represents a cyclic group which may have a substituent, a chain-like alkyl group which may have a substituent, or a chain-like alkenyl group which may have a substituent, and examples thereof include the same groups as those for R¹⁰¹ in Formula (b-1).

Here, no fluorine atom is bonded to the carbon atom adjacent to the S atom in Rd² (the carbon atom is not substituted with fluorine). In this manner, the anion of the component (d2-2) is an appropriately weak acid anion, and thus the quenching ability of the component (D2) is improved.

It is preferable that Rd² represents a chain-like alkyl group which may have a substituent or an aliphatic cyclic group which may have a substituent. The chain-like alkyl group has preferably 1 to 10 carbon atoms and more preferably 3 to 10 carbon atoms. As the aliphatic cyclic group, a group in which one or more hydrogen atoms have been removed from adamantane, norbornane, isobornane, tricyclodecane, or tetracyclododecane (a group which may have a substituent); and a group in which one or more hydrogen atoms have been removed from camphor are more preferable.

The hydrocarbon group as Rd² may have a substituent. Examples of the substituent include the same substituents as the substituents that the hydrocarbon group (an aromatic hydrocarbon group, an aliphatic cyclic group, or a chain-like alkyl group) as Rd¹ in Formula (d2-1) may have.

Specific preferred examples of the anion moiety in the component (d2-2) are shown below.

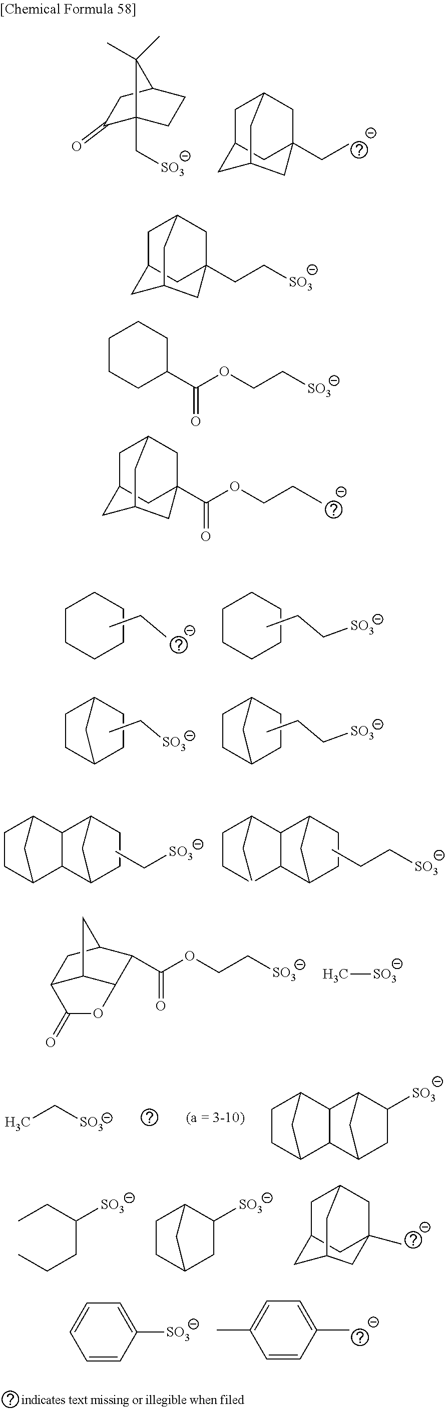

### Cation Moiety

In Formula (d2-2), M′^{m+} represents an m-valent onium cation and has the same definition as that for M′^{m+} in Formula (d2-1).

The component (d2-2) may be used alone or in combination of two or more kinds thereof.

{Component (d2-3)}

### Anion Moiety

In Formula (d2-3), Rd³ represents a cyclic group which may have a substituent, a chain-like alkyl group which may have a substituent, or a chain-like alkenyl group which may have a substituent, examples thereof include the same groups as those for R¹⁰¹ in Formula (b-1). Among the examples, a cyclic group having a fluorine atom, a chain-like alkyl group, or a chain-like alkenyl group is preferable. Among these, a fluorinated alkyl group is preferable, and the same groups as those for the fluorinated alkyl group represented by Rd¹ are more preferable.

In Formula (d2-3), Rd⁴ represents a cyclic group which may have a substituent, a chain-like alkyl group which may have a substituent, or a chain-like alkenyl group which may have a substituent, and examples thereof include the same groups as those for R¹⁰¹ in Formula (b-1).

Among these, an alkyl group which may have a substituent, an alkoxy group which may have a substituent, an alkenyl group which may have a substituent, or a cyclic group which may have a substituent is preferable.

As the alkyl group represented by Rd⁴, a linear or branched alkyl group having 1 to 5 carbon atoms is preferable, and specific examples thereof include a methyl group, an ethyl group, a propyl group, an isopropyl group, an n-butyl group, an isobutyl group, a tert-butyl group, a pentyl group, an isopentyl group, and a neopentyl group. Some hydrogen atoms in the alkyl group as Rd⁴ may be substituted with a hydroxyl group, a cyano group, or the like.

As the alkoxy group represented by Rd⁴, an alkoxy group having 1 to 5 carbon atoms is preferable, and specific examples of the alkoxy group having 1 to 5 carbon atoms include a methoxy group, an ethoxy group, an n-propoxy group, an iso-propoxy group, an n-butoxy group, and a tert-butoxy group. Among these, a methoxy group and an ethoxy group are preferable.

Examples of the alkenyl group as Rd⁴ include the same groups as those for R¹⁰¹ in Formula (b-1). Among the examples, a vinyl group, a propenyl group (an allyl group), a 1-methylpropenyl group, or a 2-methylpropenyl group is preferable. These groups may have an alkyl group having 1 to 5 carbon atoms or a halogenated alkyl group having 1 to 5 carbon atoms as a substituent.

Examples of the cyclic group as Rd⁴ include the same groups as those for R¹⁰¹ in Formula (b-1). Among the examples, an alicyclic group in which one or more hydrogen atoms have been removed from a cycloalkane such as cyclopentane, cyclohexane, adamantane, norbornane, isobornane, tricyclodecane, or tetracyclododecane or an aromatic group such as a phenyl group or a naphthyl group is preferable. In a case where Rd⁴ represents an alicyclic group, the resist composition is satisfactorily dissolved in an organic solvent so that the lithography characteristics are enhanced.

In Formula (d2-3), Yd¹ represents a single bond or a divalent linking group.

The divalent linking group as Yd¹ is not particularly limited, and examples thereof include a divalent hydrocarbon group (an aliphatic hydrocarbon group or an aromatic hydrocarbon group) which may have a substituent and a divalent linking group having a heteroatom. Examples of the divalent linking groups are the same as those for the divalent hydrocarbon group which may have a substituent and the divalent linking group having a heteroatom, described in the section of the divalent linking group as Ya^{x1} in Formula (a10-1).

It is preferable that Yd¹ represents a carbonyl group, an ester bond, an amide bond, an alkylene group, or a combination thereof. As the alkylene group, a linear or branched alkylene group is more preferable, and a methylene group or an ethylene group is still more preferable.

Specific preferred examples of the anion moiety in the component (d2-3) are shown below.

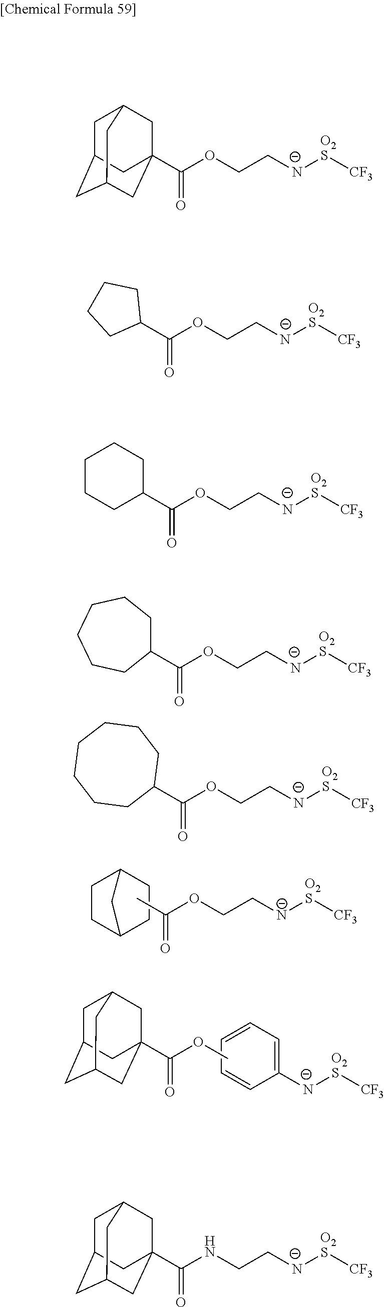

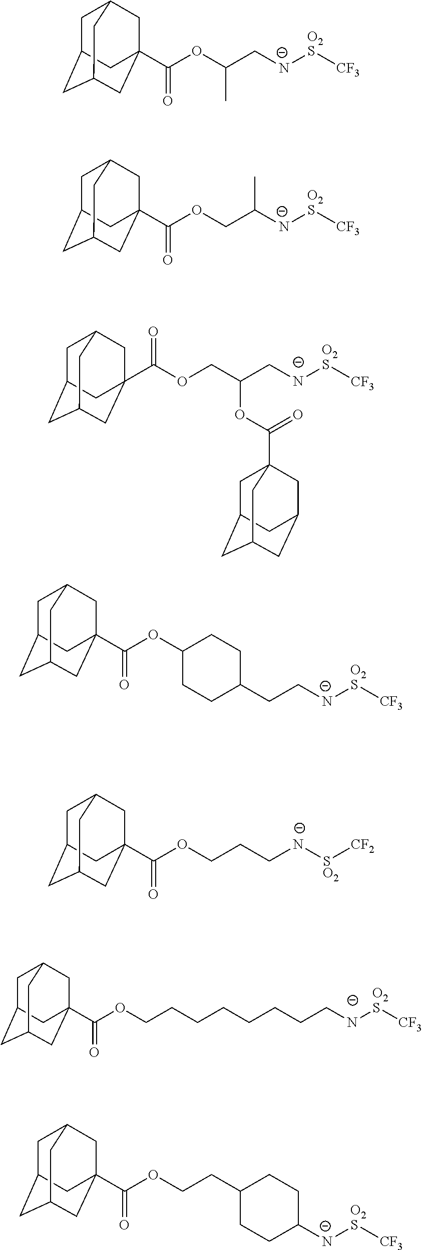

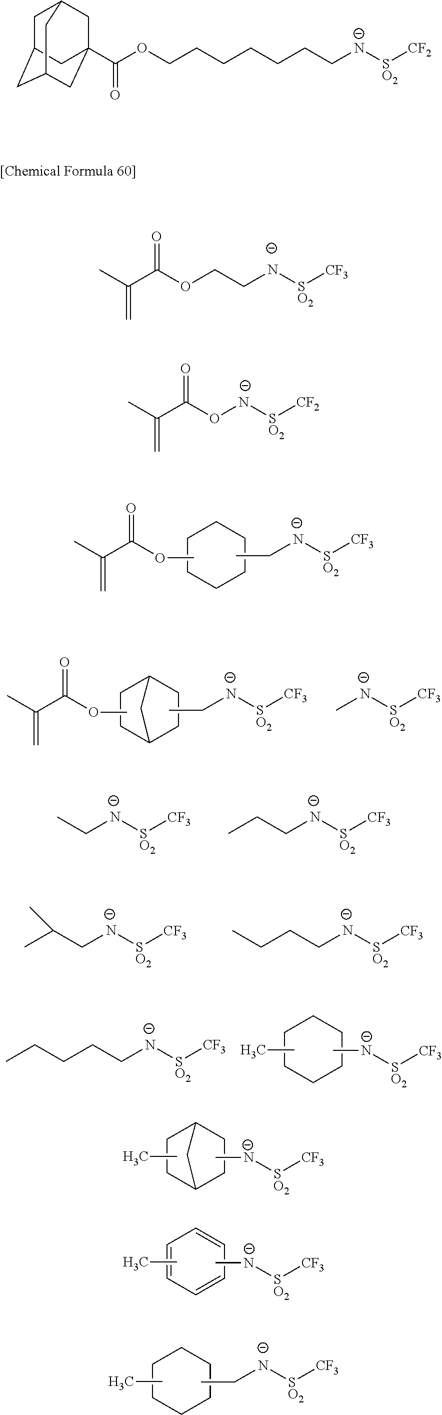

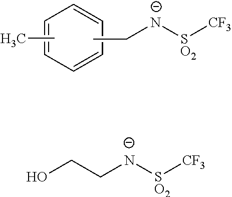

### Cation Moiety

In Formula (d2-3), M′^{m+} represents an m-valent onium cation and has the same definition as that for M′^{m+} in Formula (d2-1).

The component (d2-3) may be used alone or in combination of two or more kinds thereof.

As the component (D2), only one of the above-described components (d2-1) to (d2-3) or a combination of two or more kinds thereof may be used.

In a case where the resist composition contains the component (D2), the content of the component (D2) in the resist composition is preferably in a range of 0.5 to 35 parts by mass, more preferably in a range of 1 to 25 parts by mass, still more preferably in a range of 2 to 20 parts by mass, and particularly preferably in a range of 3 to 15 parts by mass with respect to 100 parts by mass of the component (A).

In a case where the content of the component (D2) is greater than or equal to the lower limits of the above-described preferable ranges, particularly satisfactory lithography characteristics and an excellent resist pattern shape are likely to be obtained. Meanwhile, in a case where the content thereof is less than or equal to the above-described upper limits, the balance between the component (D2) and other components can be achieved, and thus various lithography characteristics are enhanced.

### Method for Producing Component (D2):

The methods of producing the components (d2-1) and (d2-2) are not particularly limited, and the components (d2-1) and (d2-2) can be produced by known methods.

Further, the method for producing the component (d2-3) is not particularly limited, and the component (d2-3) can be produced in the same manner as disclosed in United States Patent Application, Publication No. 2012-0149916.

<<At Least One Compound (E) Selected from Group Consisting of Organic Carboxylic Acids, Phosphorus Oxo Acids, and Derivatives Thereof>>

For the purpose of preventing any deterioration in sensitivity and improving the resist pattern shape and the post-exposure temporal stability, the resist composition according to the present embodiment may contain, as an optional component, at least one compound (E) (hereinafter referred to as “component (E)”) selected from the group consisting of an organic carboxylic acid, and a phosphorus oxo acid and a derivative thereof.

Specific examples of the organic carboxylic acid include acetic acid, malonic acid, citric acid, malic acid, succinic acid, benzoic acid, and salicylic acid. Among these, salicylic acid is preferable.

Examples of the phosphorus oxo acid include phosphoric acid, phosphonic acid, and phosphinic acid. Among these, phosphonic acid is particularly preferable.

Examples of the phosphorus oxo acid derivative include an ester obtained by substituting a hydrogen atom in the above-described oxo acid with a hydrocarbon group.

Examples of the hydrocarbon group include an alkyl group having 1 to 5 carbon atoms and an aryl group having 6 to 15 carbon atoms.

Examples of the phosphoric acid derivatives include phosphoric acid esters such as phosphoric acid di-n-butyl ester and phosphoric acid diphenyl ester.

Examples of the phosphonic acid derivatives include phosphonic acid esters such as phosphonic acid dimethyl ester, phosphonic acid di-n-butyl ester, phenylphosphonic acid, phosphonic acid diphenyl ester, and phosphonic acid dibenzyl ester.

Examples of the phosphinic acid derivatives include phosphinic acid ester and phenylphosphinic acid.

In the resist composition of the present embodiment, the component (E) may be used alone or in combination of two or more kinds thereof.

In a case where the resist composition contains the component (E), the content of the component (E) is preferably in a range of 0.01 to 5 parts by mass and more preferably in a range of 0.05 to 3 parts by mass with respect to 100 parts by mass of the component (A). Within the above range, the lithography characteristics are further improved.

### <<Fluorine Additive Component (F)>>

The resist composition according to the present embodiment may further contain a fluorine additive component (hereinafter, referred to as “component (F)”) as a hydrophobic resin.

The component (F) is used to impart water repellency to the resist film and used as a resin different from the component (A), and thus the lithography characteristics are enhanced.

As the component (F), for example, the fluorine-containing polymer compounds described in Japanese Unexamined Patent Application, First Publication Nos. 2010-002870, 2010-032994, 2010-277043, 2011-13569, and 2011-128226 can be used.

Specific examples of the component (F) include a polymer having a constitutional unit (f1) represented by General Formula (f1-1). As the polymer, a polymer (homopolymer) formed of only the constitutional unit (f1) represented by Formula (f1-1); a copolymer of the constitutional unit (f1) and the constitutional unit (a1); or a copolymer of the constitutional unit (f1), a constitutional unit derived from acrylic acid or methacrylic acid, and the constitutional unit (a1) is preferable, and a copolymer of the constitutional unit (f1) and the constitutional unit (a1) is more preferable. Here, as the constitutional unit (a1) copolymerized with the constitutional unit (f1), a constitutional unit derived from 1-ethyl-1-cyclooctyl (meth)acrylate or a constitutional unit derived from 1-methyl-1-adamantyl (meth)acrylate is preferable, and a constitutional unit derived from 1-ethyl-1-cyclooctyl (meth)acrylate is more preferable.

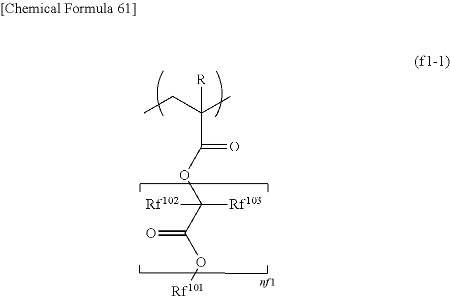

[In the formula, R has the same definition as described above, Rf¹⁰² and Rf¹⁰³ each independently represent a hydrogen atom, a halogen atom, an alkyl group having 1 to 5 carbon atoms, or a halogenated alkyl group having 1 to 5 carbon atoms, and Rf¹⁰² and Rf¹⁰³ may be the same as or different from each other. nf¹ represents an integer of 0 to 5, and Rf¹⁰¹ represents an organic group having a fluorine atom.]

In Formula (f1-1), R bonded to the carbon atom at the α-position has the same definition as described above. It is preferable that R represents a hydrogen atom or a methyl group.

In Formula (f1-1), a fluorine atom is preferable as the halogen atom as Rf¹⁰² and Rf¹⁰³. Examples of the alkyl group having 1 to 5 carbon atoms as Rf¹⁰² and Rf¹⁰³ include the same groups as those for the alkyl group having 1 to 5 carbon atoms as R. Among the examples, a methyl group or an ethyl group is preferable. Specific examples of the halogenated alkyl group having 1 to 5 carbon atoms as Rf¹⁰² and Rf¹⁰³ include groups in which some or all hydrogen atoms of an alkyl group having 1 to 5 carbon atoms are substituted with halogen atoms. Among these, a fluorine atom is preferable as the halogen atom. Among these, Rf¹⁰² and Rf¹⁰³ represent preferably a hydrogen atom, a fluorine atom, or an alkyl group having 1 to 5 carbon atoms, more preferably a hydrogen atom, a fluorine atom, a methyl group, or an ethyl group, and still more preferably a hydrogen atom.

In Formula (f1-1), nf¹ represents an integer of 0 to 5, preferably an integer of 0 to 3, and more preferably 1 or 2.

In Formula (f1-1). Rf¹⁰¹ represents an organic group having a fluorine atom and preferably a hydrocarbon group having a fluorine atom.

The hydrocarbon group having a fluorine atom may be linear, branched, or cyclic, and the number of carbon atoms thereof is preferably in a range of 1 to 20, more preferably in a range of 1 to 15, and particularly preferably in a range of 1 to 10.

In the hydrocarbon group having a fluorine atom, preferably 25% or more of the hydrogen atoms in the hydrocarbon group are fluorinated, more preferably 50% or more thereof are fluorinated, and particularly preferably 60% or more thereof are fluorinated from the viewpoint of increasing the hydrophobicity of the resist film during immersion exposure.

Among the examples, Rf¹⁰¹ represents more preferably a fluorinated hydrocarbon group having 1 to 6 carbon atoms and particularly preferably a trifluoromethyl group. —CH₂—CF₃, —CH₂—CF₂—CF₃, —CH(CF₃)₂, —CH₂—CH₂—CF₃, or —CH₂—CH₂—CF₂—CF₂—CF₂—CF₃.

The weight-average molecular weight (Mw) (in terms of polystyrene according to gel permeation chromatography) of the component (F) is preferably in a range of 1,000 to 50,000, more preferably in a range of 5,000 to 40,000, and most preferably in a range of 10,000 to 30,000. In a case where the weight-average molecular weight thereof is less than or equal to the upper limits of the above-described ranges, the resist composition exhibits a satisfactory solubility in a solvent for a resist enough to be used as a resist. Meanwhile, in a case where the weight-average molecular weight thereof is greater than or equal to the lower limits of the above-described ranges, water repellency of the resist film is improved.

Further, the dispersity (Mw/Mn) of the component (F) is preferably in a range of 1.0 to 5.0, more preferably in a range of 1.0 to 3.0, and most preferably in a range of 1.0 to 2.5.

In the resist composition according to the present embodiment, the component (F) may be used alone or in combination of two or more kinds thereof.

In a case where the resist composition contains the component (F), the content of the component (F) is preferably in a range of 0.5 to 10 parts by mass and more preferably in a range of 1 to 10 parts by mass with respect to 100 parts by mass of the component (A).

### <<Organic Solvent Component (S)>>

The resist composition of the present embodiment can be produced by dissolving the resist materials in an organic solvent component (hereinafter, referred to as “component (S)”).

The component (S) may be any organic solvent which can dissolve each component to be used to obtain a uniform solution, and an optional organic solvent can be appropriately selected from those which have been known as solvents of a chemically amplified resist composition and then used.

Examples of the component (S) include lactones such as γ-butyrolactone; ketones such as acetone, methyl ethyl ketone, cyclohexanone, methyl-n-pentyl ketone, methyl isopentyl ketone, and 2-heptanone; polyhydric alcohols such as ethylene glycol, diethylene glycol, propylene glycol, and dipropylene glycol; compounds having an ester bond, such as ethylene glycol monoacetate, diethylene glycol monoacetate, propylene glycol monoacetate, and dipropylene glycol monoacetate; polyhydric alcohol derivatives of compounds having an ether bond such as monoalkyl ether or monophenyl ether, such as monomethylether, monoethylether, monopropylether, or monobutylether of polyhydric alcohols or compounds having an ester bond [among these, propylene glycol monomethyl ether acetate (PGMEA) and propylene glycol monomethyl ether (PGME) are preferable]; cyclic ethers such as dioxane; esters such as methyl lactate, ethyl lactate (EL), methyl acetate, ethyl acetate, butyl acetate, methyl pyruvate, ethyl pyruvate, methyl methoxypropionate, and ethyl ethoxypropionate; aromatic organic solvents such as anisole, ethylbenzylether, cresylmethylether, diphenylether, dibenzylether, phenetole, butylphenylether, ethylbenzene, diethylbenzene, pentylbenzene, isopropylbenzene, toluene, xylene, cymene, and mesitylene; and dimethylsulfoxide (DMSO).

In the resist composition of the present embodiment, the component (S) may be used alone or in the form of a mixed solvent of two or more kinds thereof. Among these, PGMEA, PGME, γ-butyrolactone, EL, or cyclohexanone is preferable.

Further, a mixed solvent obtained by mixing PGMEA with a polar solvent is also preferable as the component (S). The blending ratio (mass ratio) of the mixed solvent can be appropriately determined in consideration of the compatibility between PGMEA and the polar solvent, but is preferably in the range of 1:9 to 9:1 and more preferably in a range of 2:8 to 8:2.

More specifically, in a case where EL or cyclohexanone is blended as the polar solvent, the mass ratio of PGMEA to EL or cyclohexanone is preferably in a range of 1:9 to 9:1 and more preferably in a range of 2:8 to 8:2. Further, in a case where PGME is blended as the polar solvent, the mass ratio of PGMEA to PGME is preferably in a range of 1:9 to 9:1, more preferably in a range of 2:8 to 8:2, and still more preferably in a range of 3:7 to 7:3. Further, a mixed solvent of PGMEA, PGME, and cyclohexanone is also preferable.

Further, a mixed solvent of 7-butyrolactone and at least one selected from PGMEA and EL is also preferable as the component (S). In this case, as the mixing ratio, the mass ratio between the former and the latter is preferably in a range of 70:30 to 95:5.

The solid content concentration of the resist composition is not particularly limited, but the amount of the component (S) to be used is preferably in a range of 15% to 60% by mass, more preferably in a range of 20% to 55% by mass, still more preferably in a range of 25% to 50% by mass, and even more preferably in a range of 30% to 50% by mass.

In the present specification, the solid content in the resist composition denotes components other than the component (S). The solid content concentration of the resist composition is calculated by the following equation.

Solid content concentration (% by mass)=total mass of components other than component (S)/total mass of resist composition×100

For example, in a case where the resist composition consists of the component (A), the component (Z), the component (B), the component (D), and the component (S), an equation of “solid content concentration (% by mass)=[(component (A)+component (Z)+component (B)+component (D))/(component (A)+component (Z)+component (B)+component (D)+component (S)]×100” is satisfied.

In a case where the solid content concentration of the resist composition to be in the above-described preferable ranges, a thick resist film (for example, with a film thickness of 2 μm to 20 μm) can be formed in a case where a substrate is coated with the resist composition to form a resist film. The solid content concentration of the resist composition can be appropriately determined according to the film thickness of a desired resist film. Typically, the film thickness of the resist film increases as the solid content concentration increases.

As desired, miscible additives such as additive resins, dissolution inhibitors, plasticizers, stabilizers, colorants, halation prevention agents, and dyes for improving the performance of the resist film can be added to the resist composition of the present embodiment, as appropriate.

After the resist material is dissolved in the component (S), impurities may be removed from the resist composition of the present embodiment using a porous polyimide film, a porous polyamideimide film, or the like. For example, the resist composition may be filtered using a filter formed of a porous polyimide film, a filter formed of a porous polyamideimide film, a filter formed of a porous polyimide film and a porous polyamideimide film, or the like. Examples of the porous polyimide film and the porous polyamideimide film include those described in Japanese Unexamined Patent Application, First Publication No. 2016-155121.

The resist composition according to the present embodiment described above contains the resin component (A1) having the constitutional unit (a1) that contains an acid decomposable group whose polarity is increased due to the action of an acid, the constitutional unit (a10) represented by General Formula (a10-1), and the constitutional unit (a5) represented by General Formula (a5-1), and the resin component (Z) having the constitutional unit (z1) represented by General Formula (z1-1) and no acid dissociable group.

In a thick resist film, cracks are likely to occur in the resist pattern. Further, since the exposure light source does not reach the bottom portion of the resist film in the thick resist, a difference (ΔCD) between the CD in the upper portion of the pattern (CD-top) and the CD in the bottom portion of the pattern (CD-bottom) is likely to increase, and the rectangularity of the pattern shape is likely to be reduced. Further, in a case where the resist is formed into a thick film, the viscosity may increase, and the handleability may be deteriorated.

Since the resist composition according to the present embodiment contains the component (A1), the light transmittance of the resist film with a large film thickness is increased. In this manner, even in a case of forming a resist film with a large film thickness, the sensitivity is increased and the resolution is improved to reduce the ΔCD, and thus a resist pattern having a satisfactory shape can be formed.

In addition, since the resist composition according to the present embodiment contains the component (Z), the crack resistance is enhanced, and the viscosity of the resist composition can be controlled in a range where the handleability is enhanced.

Further, it is assumed that the resist composition according to the present embodiment is unlikely to be affected by the process during the pattern formation due to the synergistic effect of the component (A1) and the component (Z).

### (Method for Forming Resist Pattern)

A method for forming a resist pattern according to the second aspect according to the present invention is a method including a step of forming a resist film on a support using the resist composition according to the first aspect of the present invention described above, a step of exposing the resist film to light, and a step of developing the resist film exposed to light to form a resist pattern.

According to the embodiment of the method for forming a resist pattern, a method for forming a resist pattern by performing processes as described below is an exemplary example.

First, a support is coated with the resist composition of the above-described embodiment using a spinner or the like, and a bake (post applied bake (PAB)) treatment is performed under a temperature condition of 80° C. to 150° C. for 40 to 120 seconds and preferably 60 to 90 seconds to form a resist film.

Following the selective exposure carried out on the resist film by, for example, exposure through a mask (mask pattern) having a predetermined pattern formed on the mask by using an exposure apparatus such as an electron beam lithography apparatus or an ArF exposure apparatus, or direct irradiation of the resist film for drawing with an electron beam without using a mask pattern, a bake treatment (post exposure bake (PFB)) is carried out, for example, under a temperature condition in a range of 80° C. to 150° C. for 40 to 120 seconds and preferably 60 to 90 seconds.

Next, the resist film is subjected to a developing treatment. The developing treatment is conducted using an alkali developing solution in a case of an alkali developing process and using a developing solution containing an organic solvent (organic developing solution) in a case of a solvent developing process.

After the developing treatment, it is preferable to conduct a rinse treatment. As the rinse treatment, water rinsing using pure water is preferable in a case of the alkali developing process, and rinsing using a rinse solution containing an organic solvent is preferable in a case of the solvent developing process.

In a case of the solvent developing process, after the developing treatment or the rinse treatment, the developing solution or the rinse solution attached onto the pattern may be removed by a treatment using a supercritical fluid.

After the developing treatment or the rinse treatment, drying is conducted. As desired, a bake treatment (post bake) may be conducted after the developing treatment.

In this manner, a resist pattern can be formed.

The support is not particularly limited and a known support of the related art can be used, and examples thereof include a substrate for an electronic component and a substrate on which a predetermined wiring pattern has been formed. Specific examples thereof include a metal substrate such as a silicon wafer, copper, chromium, iron, or aluminum; and a glass substrate. As the materials of the wiring pattern, copper, aluminum, nickel, or gold can be used.

The method for forming a resist pattern according to the embodiment is a method useful at the time of being carried out by forming a thick resist film. Even in a case where the film thickness of the resist film formed by coating a substrate with the resist composition is, for example, in a range of 5 to 20 μm, a resist pattern can be stably formed in a satisfactory shape.

The wavelength used for light exposure is not particularly limited and the exposure can be conducted using radiation such as an ArF excimer laser, a KrF excimer laser, an F2 excimer laser, extreme ultraviolet rays (EUV), vacuum ultraviolet rays (VUV), electron beams (EB), X-rays, and soft X-rays. The resist composition is highly useful for a KrF excimer laser, an ArF excimer laser, EB, or EUV, more useful for ultraviolet rays such as g-line and i-line, KrF excimer laser light, or ArF excimer laser light, and particularly useful for ultraviolet rays such as g-line and i-line, and KrF excimer laser light. That is, the method for forming a resist pattern according to the present embodiment is a method particularly useful in a case where the step of exposing the resist film to light is performed by irradiating the resist film with ultraviolet rays such as g-line and i-line, or KrF excimer laser light.

The method of exposure the resist film to light can be a general exposure (dry exposure) conducted in air or an inert gas such as nitrogen, or liquid immersion exposure (liquid immersion lithography).

The liquid immersion exposure is an exposure method in which the region between the resist film and the lens at the lowermost position of the exposure apparatus is filled with a solvent (liquid immersion medium) in advance that has a refractive index greater than the refractive index of air, and the exposure (immersion exposure) is conducted in this state.

As the liquid immersion medium, a solvent having a refractive index greater than the refractive index of air but less than the refractive index of the resist film to be exposed is preferable, and examples thereof include water, a fluorine-based inert liquid, a silicon-based solvent, and a hydrocarbon-based solvent.

As the liquid immersion medium, water is preferably used.

As the alkali developing solution used for the developing treatment in the alkali developing process, a 0.1 to 10 mass % tetramethylammonium hydroxide (TMAH) aqueous solution is an exemplary example.

The organic solvent contained in the organic developing solution used for the developing treatment in the solvent developing process may be any solvent that is capable of dissolving the component (A) (the component (A) before light exposure) and can be appropriately selected from known organic solvents. Specific examples thereof include a polar solvent such as a ketone-based solvent, an ester-based solvent, an alcohol-based solvent, a nitrile-based solvent, an amide-based solvent, and an ether-based solvent, and a hydrocarbon-based solvent.

The ketone-based solvent is an organic solvent containing C—C(═O)—C in the structure thereof. The ester-based solvent is an organic solvent containing C—C(═O)—O—C in the structure thereof. The alcohol-based solvent is an organic solvent containing an alcoholic hydroxyl group in the structure thereof. The term “alcoholic hydroxyl group” indicates a hydroxyl group bonded to a carbon atom of an aliphatic hydrocarbon group. The nitrile-based solvent is an organic solvent containing a nitrile group in the structure thereof. The amide-based solvent is an organic solvent containing an amide group in the structure thereof. The ether-based solvent is an organic solvent containing C—O—C in the structure thereof.

Some organic solvents have a plurality of the functional groups which characterize each of the solvents in the structure thereof. In such a case, the organic solvents are considered to correspond to all the solvents containing the functional groups. For example, diethylene glycol monomethylether corresponds to both the alcohol-based solvent and the ether-based solvent which have been classified above.

The hydrocarbon-based solvent is a hydrocarbon solvent which is formed of a hydrocarbon that may be halogenated and does not have a substituent other than halogen atoms. Among these, a fluorine atom is preferable as the halogen atom.

Among the examples, as the organic solvent contained in the organic developing solution, a polar solvent is preferable. Further, a ketone-based solvent, an ester-based solvent, and a nitrile-based solvent are preferable.

Examples of the ketone-based solvent include 1-octanone, 2-octanone, 1-nonanone, 2-nonanone, acetone, 4-heptanone, 1-hexanone, 2-hexanone, diisobutyl ketone, cyclohexanone, methylcyclohexanone, phenylacetone, methyl ethyl ketone, methyl isobutyl ketone, acetylacetone, acetonylacetone, ionone, diacetonylalcohol, acetylcarbinol, acetophenone, methyl naphthyl ketone, isophorone, propylenecarbonate, γ-butyrolactone, and methyl amyl ketone (2-heptanone). Among these examples, methyl amyl ketone (2-heptanone) is preferable as the ketone-based solvent.

Examples of the ester-based solvent include methyl acetate, butyl acetate, ethyl acetate, isopropyl acetate, amyl acetate, isoamyl acetate, ethyl methoxyacetate, ethyl ethoxyacetate, ethylene glycol monoethyl ether acetate, ethylene glycol monopropyl ether acetate, ethylene glycol monobutyl ether acetate, ethylene glycol monophenyl ether acetate, diethylene glycol monomethyl ether acetate, diethylene glycol monopropyl ether acetate, diethylene glycol monophenyl ether acetate, diethylene glycol monobutyl ether acetate, diethylene glycol monoethyl ether acetate, 2-methoxybutyl acetate, 3-methoxybutyl acetate, 4-methoxybutyl acetate, 3-methyl-3-methoxybutyl acetate, 3-ethyl-3-methoxybutyl acetate, propylene glycol monomethyl ether acetate, propylene glycol monoethyl ether acetate, propylene glycol monopropyl ether acetate, 2-ethoxybutyl acetate, 4-ethoxybutyl acetate, 4-propoxybutyl acetate, 2-methoxypentyl acetate, 3-methoxypentyl acetate, 4-methoxypentyl acetate, 2-methyl-3-methoxypentyl acetate, 3-methyl-3-methoxypentyl acetate, 3-methyl-4-methoxypentyl acetate, 4-methyl-4-methoxypentyl acetate, propylene glycol diacetate, methyl formate, ethyl formate, butyl formate, propyl formate, ethyl lactate, butyl lactate, propyl lactate, ethyl carbonate, propyl carbonate, butyl carbonate, methyl pyruvate, ethyl pyruvate, propyl pyruvate, butyl pyruvate, methyl acetoacetate, ethyl acetoacetate, methyl propionate, ethyl propionate, propyl propionate, isopropyl propionate, methyl 2-hydroxypropionate, ethyl 2-hydroxypropionate, methyl-3-methoxypropionate, ethyl-3-methoxypropionate, ethyl-3-ethoxypropionate, and propyl-3-methoxypropionate. Among these examples, butyl acetate is preferable as the ester-based solvent.

Examples of the nitrile-based solvent include acetonitrile, propionitrile, valeronitrile, and butyronitrile.

Known additives can be blended into the organic developing solution as necessary. Examples of the additive include a surfactant. The surfactant is not particularly limited, and for example, an ionic or non-ionic fluorine-based and/or silicon-based surfactant can be used. As the surfactant, a non-ionic surfactant is preferable, and a non-ionic fluorine-based surfactant or a non-ionic silicon-based surfactant is more preferable.

In a case where a surfactant is blended into the solution, the amount of the surfactant to be blended is typically in a range of 0.001% to 5% by mass, preferably in a range of 0.005% to 2% by mass, and more preferably in a range of 0.01% to 0.5% by mass with respect to the total amount of the organic developing solution.

The developing treatment can be performed according to a known developing method, and examples thereof include a method for immersing a support in a developing solution for a certain time (a dip method), a method for raising a developing solution on the surface of a support using the surface tension and maintaining the state for a certain time (a puddle method), a method for spraying a developing solution to the surface of a support (spray method), and a method for continuously ejecting a developing solution onto a support rotating at a certain rate while scanning a developing solution ejection nozzle at a certain rate (dynamic dispense method).

As the organic solvent contained in the rinse solution used for the rinse treatment after the developing treatment in the solvent developing process, a solvent that is unlikely to dissolve a resist pattern can be appropriately selected from the organic solvents described as the organic solvent used in the organic developing solution and then used. Typically, at least one solvent selected from a hydrocarbon-based solvent, a ketone-based solvent, an ester-based solvent, an alcohol-based solvent, an amide-based solvent, and an ether-based solvent is used. Among these, at least one solvent selected from a hydrocarbon-based solvent, a ketone-based solvent, an ester-based solvent, an alcohol-based solvent, and an amide-based solvent is preferable, at least one solvent selected from an alcohol-based solvent and an ester-based solvent is more preferable, and an alcohol-based solvent is particularly preferable.

As the alcohol-based solvent used in the rinse solution, a monohydric alcohol having 6 to 8 carbon atoms is preferable, and the monohydric alcohol may be linear, branched, or cyclic. Specific examples thereof include 1-hexanol, 1-heptanol, 1-octanol, 2-hexanol, 2-heptanol, 2-octanol, 3-hexanol, 3-heptanol, 3-octanol, 4-octanol, and benzyl alcohol. Among these, 1-hexanol, 2-heptanol, and 2-hexanol are preferable, and 1-hexanol and 2-hexanol are more preferable.

These organic solvents may be used alone or in combination of two or more kinds thereof. Further, an organic solvent other than the above-described solvents and water may be mixed and used. However, in consideration of the development characteristics, the amount of water to be blended into the rinse solution is preferably 30% by mass or less, more preferably 10% by mass or less, still more preferably 5% by mass or less, and particularly preferably 3% by mass or less with respect to the total amount of the rinse solution.

A known additive can be blended into the rinse solution as necessary. Examples of the additive include a surfactant. As the surfactant, the same surfactants as those described above are exemplary examples. Among these, a non-ionic surfactant is preferable, and a non-ionic fluorine-based surfactant or a non-ionic silicon-based surfactant is more preferable.

In a case where a surfactant is blended into the solution, the amount of the surfactant to be blended is typically in a range of 0.001% to 5% by mass, preferably in a range of 0.005% to 2% by mass, and more preferably in a range of 0.01% to 0.5% by mass with respect to the total amount of the rinse solution.

The rinse treatment carried out using a rinse solution (washing treatment) can be performed according to a known rinse method. Examples of the method for performing the rinse treatment include a method for continuously ejecting a rinse solution onto a support rotating at a certain rate (rotary coating method), a method for immersing a support in a rinse solution for a certain time (dip method), and a method for spraying a rinse solution to the surface of a support (spray method).

According to the method for forming a resist pattern of the present embodiment described above, since the above-described resist composition is used, the resist composition is unlikely to be affected by the process during the pattern formation, the occurrence of cracks is reduced, and a thick resist pattern having a satisfactory shape can be formed.

The method for forming a resist pattern of the present embodiment is a method useful for manufacturing a three-dimensional structure device and is suitable for use in processing a multi-step staircase structure (overlapping or the like). By applying the method for forming a resist pattern according to the present invention, the lamination of memory films (three-dimensionalization and production of a large-capacity memory) can be achieved with high accuracy.

It is preferable that various materials that are used in the resist composition according to the above-described embodiment and the pattern forming method according to the above-described embodiment (for example, a resist solvent, a developing solution, a rinse solution, a composition for forming an antireflection film, and a composition for forming a top coat) do not contain impurities such as a metal, a metal salt containing halogen, an acid, an alkali, and a component having a sulfur atom or phosphorus atom. Here, examples of the impurities containing metal atoms include Na, K, Ca, Fe, Cu, Mn, Mg, Al, Cr, Ni, Zn, Ag, Sn, Pb, Li, and salts thereof. The content of the impurities contained in these materials is preferably 200 ppb or less, more preferably 1 ppb or less, still more preferably 100 parts per trillion (ppt) or less, particularly preferably 10 ppt or less, and most preferably substantially zero (less than or equal to the detection limit of the measuring device).

### EXAMPLES

Hereinafter, the present invention will be described in more detail based on examples, but the present invention is not limited to these examples.

### <Preparation of Resist Composition>

### Examples 1 to 46 and Comparative Examples 1 to 22

Each component listed in Tables 1 to 6 was mixed and dissolved to prepare each resist composition (solid content concentration of 45% by mass) of each example.

TABLE 1

| | Component | Component | Component | Component | Component | | |
|---|---|---|---|---|---|---|---|
| | (A) | (B) | (D) | (Z) | (S) | | |
| Example | (A)-1 | (B)-1 | (D)-1 | (Z)-1-1 | (S)-1 | (S)-2 | (S)-3 |
| 1 | [100] | [1.0] | [0.01] | [5.0] | [52] | [52] | [26] |
| Example | (A)-1 | (B)-1 | (D)-1 | (Z)-1-1 | (S)-1 | (S)-2 | (S)-3 |
| 2 | [100] | [1.0] | [0.01] | [20.0] | [59] | [59] | [30] |
| Example | (A)-1 | (B)-1 | (D)-1 | (Z)-1-1 | (S)-1 | (S)-2 | (S)-3 |
| 3 | [100] | [1.0] | [0.01] | [35.0] | [66] | [66] | [33] |
| Example | (A)-1 | (B)-1 | (D)-1 | (Z)-2-1 | (S)-1 | (S)-2 | (S)-3 |
| 4 | [100] | [1.0] | [0.01] | [20.0] | [59] | [59] | [30] |
| Example | (A)-1 | (B)-1 | (D)-1 | (Z)-1-2 | (S)-1 | (S)-2 | (S)-3 |
| 5 | [100] | [1.0] | [0.01] | [5.0] | [52] | [52] | [26] |
| Example | (A)-1 | (B)-1 | (D)-1 | (Z)-1-2 | (S)-1 | (S)-2 | (S)-3 |
| 6 | [100] | [1.0] | [0.01] | [20.0] | [59] | [59] | [30] |
| Example | (A)-1 | (B)-1 | (D)-1 | (Z)-1-2 | (S)-1 | (S)-2 | (S)-3 |
| 7 | [100] | [1.0] | [0.01] | [35.0] | [66] | [66] | [33] |
| Example | (A)-1 | (B)-1 | (D)-1 | (Z)-2-2 | (S)-1 | (S)-2 | (S)-3 |
| 8 | [100] | [1.0] | [0.01] | [20.0] | [59] | [59] | [30] |
| Example | (A)-1 | (B)-1 | (D)-1 | (Z)-1-3 | (S)-1 | (S)-2 | (S)-3 |
| 9 | [100] | [1.0] | [0.01] | [5.0] | [52] | [52] | [26] |
| Example | (A)-1 | (B)-1 | (D)-1 | (Z)-1-3 | (S)-1 | (S)-2 | (S)-3 |
| 10 | [100] | [1.0] | [0.01] | [20.0] | [59] | [59] | [30] |
| Example | (A)-1 | (B)-1 | (D)-1 | (Z)-1-3 | (S)-1 | (S)-2 | (S)-3 |
| 11 | [100] | [1.0] | [0.01] | [35.0] | [66] | [66] | [33] |
| Example | (A)-1 | (B)-1 | (D)-1 | (Z)-2-3 | (S)-1 | (S)-2 | (S)-3 |
| 12 | [100] | [1.0] | [0.01] | [20.0] | [59] | [59] | [30] |

TABLE 2

| | Component | Component | Component | Component | Component | | |
|---|---|---|---|---|---|---|---|
| | (A) | (B) | (D) | (Z) | (S) | | |
| Example | (A)-1 | (B)-1 | (D)-1 | (Z)-1-4 | (S)-1 | (S)-2 | (S)-3 |
| 13 | [100] | [1.0] | [0.01] | [5.0] | [52] | [52] | [26] |
| Example | (A)-1 | (B)-1 | (D)-1 | (Z)-1-4 | (S)-1 | (S)-2 | (S)-3 |
| 14 | [100] | [1.0] | [0.01] | [20.0] | [59] | [59] | [30] |
| Example | (A)-1 | (B)-1 | (D)-1 | (Z)-1-4 | (S)-1 | (S)-2 | (S)-3 |
| 15 | [100] | [1.0] | [0.01] | [35.0] | [66] | [66] | [33] |
| Example | (A)-1 | (B)-1 | (D)-1 | (Z)-2-4 | (S)-1 | (S)-2 | (S)-3 |
| 15 | [100] | [1.0] | [0.01] | [20.0] | [59] | [59] | [30] |
| Example | (A)-1 | (B)-1 | (D)-1 | (Z)-1-5 | (S)-1 | (S)-2 | (S)-3 |
| 17 | [100] | [1.0] | [0.01] | [5.0] | [52] | [52] | [26] |
| Example | (A)-1 | (B)-1 | (D)-1 | (Z)-1-5 | (S)-1 | (S)-2 | (S)-3 |
| 18 | [100] | [1.0] | [0.01] | [20.0] | [59] | [59] | [30] |
| Example | (A)-1 | (B)-1 | (D)-1 | (Z)-1-5 | (S)-1 | (S)-2 | (S)-3 |
| 19 | [100] | [1.0] | [0.01] | [35.0] | [66] | [66] | [33] |
| Example | (A)-1 | (B)-1 | (D)-1 | (Z)-2-5 | (S)-1 | (S)-2 | (S)-3 |
| 20 | [100] | [1.0] | [0.01] | [20.0] | [59] | [59] | [30] |

TABLE 3

| | Component | Component | Component | Component | Component | | |
|---|---|---|---|---|---|---|---|
| | (A) | (B) | (D) | (Z) | (S) | | |
| Example | (A)-2 | (B)-1 | (D)-1 | (Z)-1-1 | (S)-1 | (S)-2 | (S)-3 |
| 21 | [100] | [1.0] | [0.01] | [5.0] | [52] | [52] | [26] |
| Example | (A)-2 | (B)-1 | (D)-1 | (Z)-1-1 | (S)-1 | (S)-2 | (S)-3 |
| 22 | [100] | [1.0] | [0.01] | [20.0] | [59] | [59] | [30] |
| Example | (A)-2 | (B)-1 | (D)-1 | (Z)-1-1 | (S)-1 | (S)-2 | (S)-3 |
| 23 | [100] | [1.0] | [0.01] | [35.0] | [66] | [66] | [33] |
| Example | (A)-3 | (B)-1 | (D)-1 | (Z)-1-1 | (S)-1 | (S)-2 | (S)-3 |
| 24 | [100] | [1.0] | [0.01] | [5.0] | [52] | [52] | [26] |
| Example | (A)-3 | (B)-1 | (D)-1 | (Z)-1-1 | (S)-1 | (S)-2 | (S)-3 |
| 25 | [100] | [1.0] | [0.01] | [20.0] | [59] | [59] | [30] |
| Example | (A)-3 | (B)-1 | (D)-1 | (Z)-1-1 | (S)-1 | (S)-2 | (S)-3 |
| 26 | [100] | [1.0] | [0.01] | [35.0] | [66] | [66] | [33] |
| Example | (A)-4 | (B)-1 | (D)-1 | (Z)-1-1 | (S)-1 | (S)-2 | (S)-3 |
| 27 | [100] | [1.0] | [0.01] | [5.0] | [52] | [52] | [26] |
| Example | (A)-4 | (B)-1 | (D)-1 | (Z)-1-1 | (S)-1 | (S)-2 | (S)-3 |
| 28 | [100] | [1.0] | [0.01] | [20.0] | [59] | [59] | [30] |
| Example | (A)-4 | (B)-1 | (D)-1 | (Z)-1-1 | (S)-1 | (S)-2 | (S)-3 |
| 29 | [100] | [1.0] | [0.01] | [35.0] | [66] | [66] | [33] |
| Example | (A)-5 | (B)-1 | (D)-1 | (Z)-1-1 | (S)-1 | (S)-2 | (S)-3 |
| 30 | [100] | [1.0] | [0.01] | [5.0] | [52] | [52] | [26] |
| Example | (A)-5 | (B)-1 | (D)-1 | (Z)-1-1 | (S)-1 | (S)-2 | (S)-3 |
| 31 | [100] | [1.0] | [0.01] | [20.0] | [59] | [59] | [30] |
| Example | (A)-5 | (B)-1 | (D)-1 | (Z)-1-1 | (S)-1 | (S)-2 | (S)-3 |
| 32 | [100] | [1.0] | [0.01] | [35.0] | [66] | [66] | [33] |

TABLE 4

| | Component | Component | Component | Component | Component | | |
|---|---|---|---|---|---|---|---|
| | (A) | (B) | (D) | (Z) | (S) | | |
| Example | (A)-10 | (B)-1 | (D)-1 | (Z)-1-1 | (S)-1 | (S)-2 | (S)-3 |
| 33 | [100] | [1.0] | [0.01] | [20.0] | [59] | [59] | [30] |
| Example | (A)-10 | (B)-1 | (D)-1 | (Z)-1-1 | (S)-1 | (S)-2 | (S)-3 |
| 34 | [100] | [1.0] | [0.01] | [35.0] | [66] | [66] | [33] |
| Example | (A)-11 | (B)-1 | (D)-1 | (Z)-1-1 | (S)-1 | (S)-2 | (S)-3 |
| 35 | [100] | [1.0] | [0.01] | [10.0] | [54] | [54] | [27] |
| Example | (A)-11 | (B)-1 | (D)-1 | (Z)-1-1 | (S)-1 | (S)-2 | (S)-3 |
| 36 | [100] | [1.0] | [0.01] | [20.0] | [59] | [59] | [30] |
| Example | (A)-11 | (B)-1 | (D)-1 | (Z)-1-1 | (S)-1 | (S)-2 | (S)-3 |
| 37 | [100] | [1.0] | [0.01] | [35.0] | [66] | [66] | [33] |
| Example | (A)-12 | (B)-1 | (D)-1 | (Z)-1-1 | (S)-1 | (S)-2 | (S)-3 |
| 38 | [100] | [1.0] | [0.01] | [10.0] | [54] | [54] | [27] |
| Example | (A)-12 | (B)-1 | (D)-1 | (Z)-1-1 | (S)-1 | (S)-2 | (S)-3 |
| 39 | [100] | [1.0] | [0.01] | [20.0] | [59] | [59] | [30] |
| Example | (A)-12 | (B)-1 | (D)-1 | (Z)-1-1 | (S)-1 | (S)-2 | (S)-3 |
| 40 | [100] | [1.0] | [0.01] | [35.0] | [66] | [66] | [30] |
| Example | (A)-13 | (B)-1 | (D)-1 | (Z)-1-1 | (S)-1 | (S)-2 | (S)-3 |
| 41 | [100] | [1.0] | [0.01] | [5.0] | [52] | [52] | [26] |
| Example | (A)-13 | (B)-1 | (D)-1 | (Z)-1-1 | (S)-1 | (S)-2 | (S)-3 |
| 42 | [100] | [1.0] | [0.01] | [10.0] | [54] | [54] | [27] |
| Example | (A)-13 | (B)-1 | (D)-1 | (Z)-1-1 | (S)-1 | (S)-2 | (S)-3 |
| 43 | [100] | [1.0] | [0.01] | [20.0] | [59] | [59] | [30] |
| Example | (A)-13 | (B)-1 | (D)-1 | (Z)-1-1 | (S)-1 | (S)-2 | (S)-3 |
| 44 | [100] | [1.0] | [0.01] | [35.0] | [66] | [66] | [33] |
| Example | (A)-14 | (B)-1 | (D)-1 | (Z)-1-1 | (S)-1 | (S)-2 | (S)-3 |
| 45 | [100] | [1.0] | [0.01] | [20.0] | [59] | [59] | [30] |
| Example | (A)-14 | (B)-1 | (D)-1 | (Z)-1-1 | (S)-1 | (S)-2 | (S)-3 |
| 46 | [100] | [1.0] | [0.01] | [35.0] | [66] | [66] | [33] |

TABLE 5

| | Component | Component | Component | Component | Component | | |
|---|---|---|---|---|---|---|---|
| | (A) | (B) | (D) | (Z) | (S) | | |
| Comparative | (A)-7 | (B)-1 | (D)-1 | — | (S)-1 | (S)-2 | (S)-3 |
| Example 1 | [100] | [1.0] | [0.01] | | [49] | [49] | [25] |
| Comparative | (A)-8 | (B)-1 | (D)-1 | — | (S)-1 | (S)-2 | (S)-3 |
| Example 2 | [100] | [1.0] | [0.01] | | [49] | [49] | [25] |
| Comparative | (A)-9 | (B)-1 | (D)-1 | — | (S)-1 | (S)-2 | (S)-3 |
| Example 3 | [100] | [1.0] | [0.01] | | [49] | [49] | [25] |
| Comparative | (A)-7 | (B)-1 | (D)-1 | (Z)-1-1 | (S)-1 | (S)-2 | (S)-3 |
| Example 4 | [100] | [1.0] | [0.01] | [20.0] | [59] | [59] | [30] |
| Comparative | (A)-6 | (B)-1 | (D)-1 | (Z)-1-1 | (S)-1 | (S)-2 | (S)-3 |
| Example 5 | [100] | [1.0] | [0.01] | [20.0] | [59] | [59] | [30] |
| Comparative | (A)-1 | (B)-1 | (D)-1 | — | (S)-1 | (S)-2 | (S)-3 |
| Example 6 | [100] | [1.0] | [0.01] | | [49] | [49] | [25] |
| Comparative | (A)-2 | (B)-1 | (D)-1 | — | (S)-1 | (S)-2 | (S)-3 |
| Example 7 | [100] | [1.0] | [0.01] | | [49] | [49] | [25] |
| Comparative | (A)-3 | (B)-1 | (D)-1 | — | (S)-1 | (S)-2 | (S)-3 |
| Example 8 | [100] | [1.0] | [0.01] | | [49] | [49] | [25] |
| Comparative | (A)-4 | (B)-1 | (D)-1 | — | (S)-1 | (S)-2 | (S)-3 |
| Example 9 | [100] | [1.0] | [0.01] | | [49] | [49] | [25] |
| Comparative | (A)-5 | (B)-1 | (D)-1 | — | (S)-1 | (S)-2 | (S)-3 |
| Example 10 | [100] | [1.0] | [0.01] | | [49] | [49] | [25] |
| Comparative | (A)-1 | (B)-1 | (D)-1 | (Z)-3 | (S)-1 | (S)-2 | (S)-3 |
| Example 11 | [100] | [1.0] | [0.01] | [20.0] | [59] | [59] | [30] |

TABLE 6

| | Component | Component | Component | Component | Component | | |
|---|---|---|---|---|---|---|---|
| | (A) | (B) | (D) | (Z) | (S) | | |
| Comparative | (A)-10 | (B)-1 | (D)-1 | — | (S)-1 | (S)-2 | (S)-3 |
| Example 12 | [100] | [1.0] | [0.01] | | [49] | [49] | [25] |
| Comparative | (A)-10 | (B)-1 | (D)-1 | (Z)-3 | (S)-1 | (S)-2 | (S)-3 |
| Example 13 | [100] | [1.0] | [0.01] | [5.0] | [52] | [52] | [26] |
| Comparative | (A)-10 | (B)-1 | (D)-1 | (Z)-3 | (S)-1 | (S)-2 | (S)-3 |
| Example 14 | [100] | [1.0] | [0.01] | [10.0] | [54] | [54] | [27] |
| Comparative | (A)-11 | (B)-1 | (D)-1 | — | (S)-1 | (S)-2 | (S)-3 |
| Example 15 | [100] | [1.0] | [0.01] | | [49] | [49] | [25] |
| Comparative | (A)-11 | (B)-1 | (D)-1 | (Z)-3 | (S)-1 | (S)-2 | (S)-3 |
| Example 16 | [100] | [1.0] | [0.01] | [5.0] | [52] | [52] | [26] |
| Comparative | (A)-12 | (B)-1 | (D)-1 | — | (S)-1 | (S)-2 | (S)-3 |
| Example 17 | [100] | [1.0] | [0.01] | | [49] | [49] | [25] |
| Comparative | (A)-12 | (B)-1 | (D)-1 | (Z)-3 | (S)-1 | (S)-2 | (S)-3 |
| Example 18 | [100] | [1.0] | [0.01] | [5.0] | [52] | [52] | [26] |
| Comparative | (A)-13 | (B)-1 | (D)-1 | — | (S)-1 | (S)-2 | (S)-3 |
| Example 19 | [100] | [1.0] | [0.01] | | [49] | [49] | [25] |
| Comparative | (A)-14 | (B)-1 | (D)-1 | — | (S)-1 | (S)-2 | (S)-3 |
| Example 20 | [100] | [1.0] | [0.01] | | [49] | [49] | [25] |
| Comparative | (A)-14 | (B)-1 | (D)-1 | (Z)-3 | (S)-1 | (S)-2 | (S)-3 |
| Example 21 | [100] | [1.0] | [0.01] | [5.0] | [52] | [52] | [26] |
| Comparative | (A)-14 | (B)-1 | (D)-1 | (Z)-3 | (S)-1 | (S)-2 | (S)-3 |
| Example 22 | [100] | [1.0] | [0.01] | [10.0] | [54] | [54] | [27] |

In Tables 1 to 6, each abbreviation has the following meaning. The numerical values in the brackets are blending amounts (parts by mass).

(A)-1: polymer compound represented by Chemical Formula (A-1) This polymer compound (A-1) was obtained by radical polymerization using monomers from which constitutional units constituting the polymer compound were derived, at a predetermined molar ratio. The weight-average molecular weight (Mw) of the polymer compound (A-1) in terms of standard polystyrene determined by GPC measurement was 10000, and the polydispersity (Mw/Mn) thereof was 1.90. The copolymer compositional ratio (the ratio (molar ratio) between constitutional units in the structural formula) determined by ¹³C-NMR was l/m/n=40/30/25.

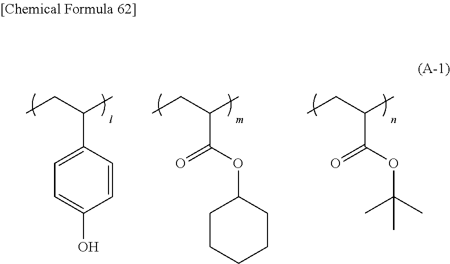

(A)-2: polymer compound represented by Chemical Formula (A-2) This polymer compound (A-2) was obtained by radical polymerization using monomers from which constitutional units constituting the polymer compound were derived, at a predetermined molar ratio. The weight-average molecular weight (Mw) of the polymer compound (A-2) in terms of standard polystyrene determined by GPC measurement was 10000, and the polydispersity (Mw/Mn) thereof was 1.90. The copolymer compositional ratio (the ratio (molar ratio) between constitutional units in the structural formula) determined by ¹³C-NMR was l/m/n=20/55/25.

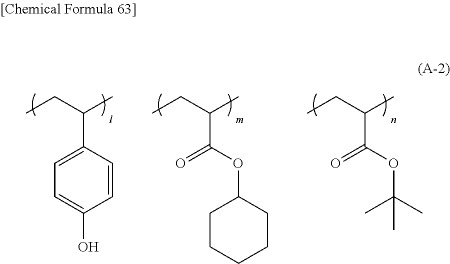

(A)-3: polymer compound represented by Chemical Formula (A-3) This polymer compound (A-3) was obtained by radical polymerization using monomers from which constitutional units constituting the polymer compound were derived, at a predetermined molar ratio. The weight-average molecular weight (Mw) of the polymer compound (A-3) in terms of standard polystyrene determined by GPC measurement was 10,000, and the polydispersity (Mw/Mn) thereof was 1.90. The copolymer compositional ratio (the ratio (molar ratio) between constitutional units in the structural formula) determined by ¹³C-NMR was l/m/n=50/25/25.

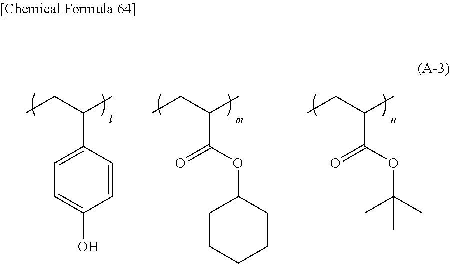

(A)-4: polymer compound represented by Chemical Formula (A-4) This polymer compound (A-4) was obtained by radical polymerization using monomers from which constitutional units constituting the polymer compound were derived, at a predetermined molar ratio. The weight-average molecular weight (Mw) of the polymer compound (A-4) in terms of standard polystyrene determined by GPC measurement was 10,000, and the polydispersity (Mw/Mn) thereof was 1.90. The copolymer compositional ratio (the ratio (molar ratio) between constitutional units in the structural formula) determined by ¹³C-NMR was l/m/n=50/25/25.

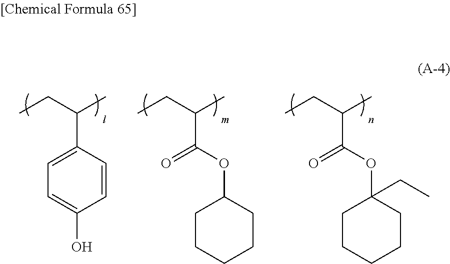

(A)-5: polymer compound represented by Chemical Formula (A-5) This polymer compound (A-5) was obtained by radical polymerization using monomers from which constitutional units constituting the polymer compound were derived, at a predetermined molar ratio. The weight-average molecular weight (Mw) of the polymer compound (A-5) in terms of standard polystyrene determined by GPC measurement was 10,000, and the polydispersity (Mw/Mn) thereof was 1.90. The copolymer compositional ratio (the ratio (molar ratio) between constitutional units in the structural formula) determined by ¹³C-NMR was l/m/n=20/45/35.

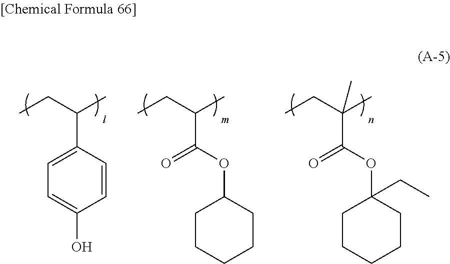

(A)-6: polymer compound represented by Chemical Formula (A-6). This polymer compound (A-6) was obtained by radical polymerization using monomers from which constitutional units constituting the polymer compound were derived, at a predetermined molar ratio. The weight-average molecular weight (Mw) of the polymer compound (A-6) in terms of standard polystyrene determined by GPC measurement was 10,000, and the polydispersity (Mw/Mn) thereof was 1.90. The copolymer compositional ratio (the ratio (molar ratio) between constitutional units in the structural formula) determined by ¹³C-NMR was l/m/n=40/35/25.

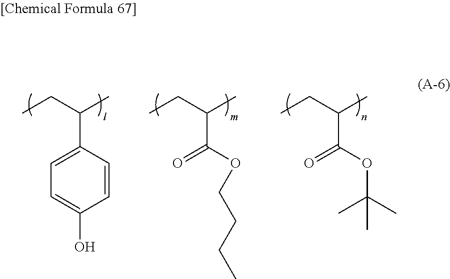

(A)-7: polymer compound represented by Chemical Formula (A-7). This polymer compound (A-7) was obtained by radical polymerization using monomers from which constitutional units constituting the polymer compound were derived, at a predetermined molar ratio. The weight-average molecular weight (Mw) of the polymer compound (A-7) in terms of standard polystyrene determined by GPC measurement was 10,000, and the polydispersity (Mw/Mn) thereof was 1.90. The copolymer compositional ratio (the ratio (molar ratio) between constitutional units in the structural formula) determined by ¹³C-NMR was l/m/n=40/35/25.

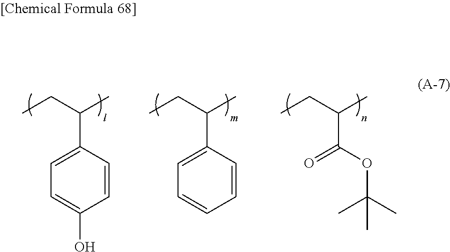

(A)-8: polymer compound represented by Chemical Formula (A-8) This polymer compound (A-8) was obtained by radical polymerization using monomers from which constitutional units constituting the polymer compound were derived, at a predetermined molar ratio. The weight-average molecular weight (Mw) of the polymer compound (A-8) in terms of standard polystyrene determined by GPC measurement was 10,000, and the polydispersity (Mw/Mn) thereof was 1.90. The copolymer compositional ratio (the ratio (molar ratio) between constitutional units in the structural formula) determined by ¹³C-NMR was l/m/n=50/25/25.

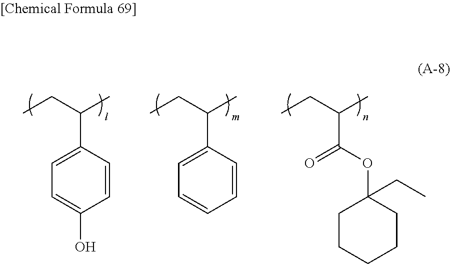

(A)-9: polymer compound represented by Chemical Formula (A-9) This polymer compound (A-9) was obtained by radical polymerization using monomers from which constitutional units constituting the polymer compound were derived, at a predetermined molar ratio. The weight-average molecular weight (Mw) of the polymer compound (A-9) in terms of standard polystyrene determined by GPC measurement was 10,000, and the polydispersity (Mw/Mn) thereof was 1.90. The copolymer compositional ratio (the ratio (molar ratio) between constitutional units in the structural formula) determined by ¹³C-NMR was l/m/n=20/45/35.

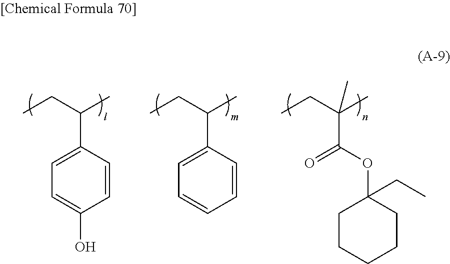

(A)-10: polymer compound represented by Chemical Formula (A-10) This polymer compound (A-10) was obtained by radical polymerization using monomers from which constitutional units constituting the polymer compound were derived, at a predetermined molar ratio. The weight-average molecular weight (Mw) of the polymer compound (A-10) in terms of standard polystyrene determined by GPC measurement was 10,000, and the polydispersity (Mw/Mn) thereof was 1.90. The copolymer compositional ratio (the ratio (molar ratio) between constitutional units in the structural formula) determined by ¹³C-NMR was l/m/n=40/35/25.

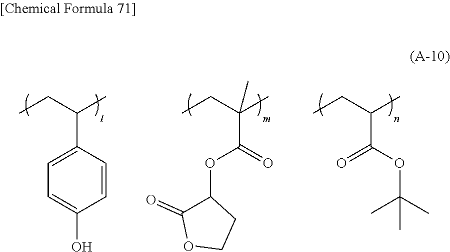

(A)-11: polymer compound represented by Chemical Formula (A-11) This polymer compound (A-11) was obtained by radical polymerization using monomers from which constitutional units constituting the polymer compound were derived, at a predetermined molar ratio. The weight-average molecular weight (Mw) of the polymer compound (A-11) in terms of standard polystyrene determined by GPC measurement was 10,000, and the polydispersity (Mw/Mn) thereof was 1.90. The copolymer compositional ratio (the ratio (molar ratio) among constitutional units in the structural formula) determined by ¹³C-NMR is l/m/n=30/45/25.

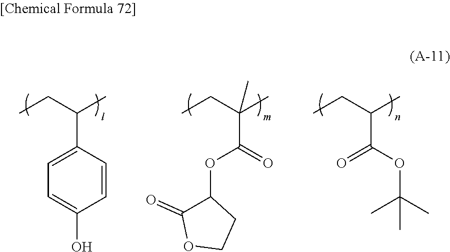

(A)-12: polymer compound represented by Chemical Formula (A-12) This polymer compound (A-12) was obtained by radical polymerization using monomers from which constitutional units constituting the polymer compound were derived, at a predetermined molar ratio. The weight-average molecular weight (Mw) of the polymer compound (A-12) in terms of standard polystyrene determined by GPC measurement was 10,000, and the polydispersity (Mw/Mn) thereof was 1.90. The copolymer compositional ratio (the ratio (molar ratio) between constitutional units in the structural formula) determined by ¹³C-NMR was l/m/n=20/55/25.

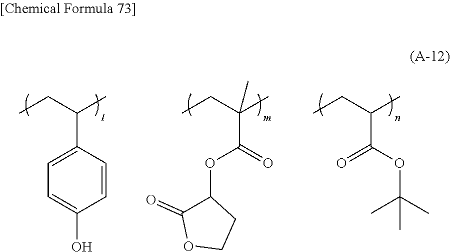

(A)-13: polymer compound represented by Chemical Formula (A-13) This polymer compound (A-13) was obtained by radical polymerization using monomers from which constitutional units constituting the polymer compound were derived, at a predetermined molar ratio. The weight-average molecular weight (Mw) of the polymer compound (A-13) in terms of standard polystyrene determined by GPC measurement was 10,000, and the polydispersity (Mw/Mn) thereof was 1.90. The copolymer compositional ratio (the ratio (molar ratio) between constitutional units in the structural formula) determined by ¹³C-NMR was l/m/n=20/45/35.

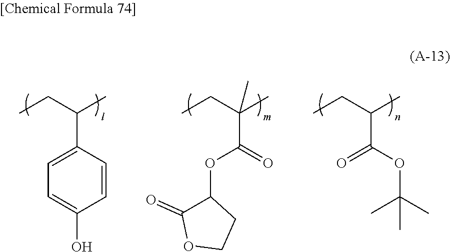

(A)-14: polymer compound represented by Chemical Formula (A-14) This polymer compound (A-14) was obtained by radical polymerization using monomers from which constitutional units constituting the polymer compound were derived, at a predetermined molar ratio. The weight-average molecular weight (Mw) of the polymer compound (A-14) in terms of standard polystyrene determined by GPC measurement was 10,000, and the polydispersity (Mw/Mn) thereof was 1.90. The copolymer compositional ratio (the ratio (molar ratio) between constitutional units in the structural formula) determined by ¹³C-NMR was l/m/n=20/45/35.

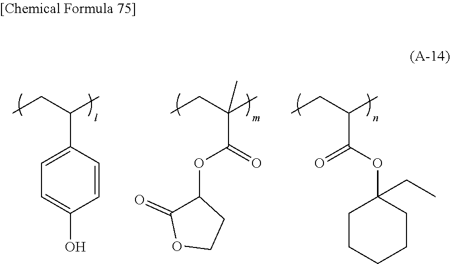

(B)-1: acid generation agent consisting of compound represented by Chemical Formula (B-1)
(D)-1: nitrogen-containing organic compound consisting of compound represented by Chemical Formula (D-1)

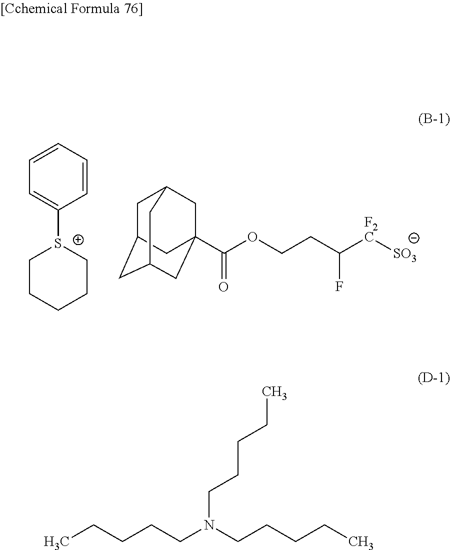

(Z)-1-1: compound represented by Chemical Formula (Z-1) The weight-average molecular weight (Mw) of the compound (Z-1-1) in terms of standard polystyrene determined by GPC measurement was 40,000, and the polydispersity (Mw/Mn) thereof was 4.00. The copolymer compositional ratio (the ratio (molar ratio) between constitutional units in the structural formula) determined by ¹³C-NMR was l/m/n=40/45/15.

(Z)-1-2: compound represented by Chemical Formula (Z-1) The weight-average molecular weight (Mw) of the compound (Z-1-2) in terms of standard polystyrene determined by GPC measurement was 80.000, and the polydispersity (Mw/Mn) thereof was 5.10. The copolymer compositional ratio (the ratio (molar ratio) between constitutional units in the structural formula) determined by ¹³C-NMR was l/m/n=40/45/15.

(Z)-1-3: compound represented by Chemical Formula (Z-1) The weight-average molecular weight (Mw) of the compound (Z-1-3) in terms of standard polystyrene determined by GPC measurement was 200,000, and the polydispersity (Mw/Mn) thereof was 8.50. The copolymer compositional ratio (the ratio (molar ratio) between constitutional units in the structural formula) determined by ¹³C-NMR was l/m/n=40/45/15.

(Z)-1-4: compound represented by Chemical Formula (Z-1) The weight-average molecular weight (Mw) of the compound (Z-1-4) in terms of standard polystyrene determined by GPC measurement was 10,000, and the polydispersity (Mw/Mn) thereof was 2.00. The copolymer compositional ratio (the ratio (molar ratio) between constitutional units in the structural formula) determined by ¹³C-NMR was l/m/n=40/45/15.

(Z)-1-5: compound represented by Chemical Formula (Z-1) The weight-average molecular weight (Mw) of the compound (Z-1-5) in terms of standard polystyrene determined by GPC measurement was 2,000, and the polydispersity (Mw/Mn) thereof was 1.50. The copolymer compositional ratio (the ratio (molar ratio) between constitutional units in the structural formula) determined by ¹³C-NMR was l/m/n=40/45/15.

(Z)-2-1: compound represented by Chemical Formula (Z-2) The weight-average molecular weight (Mw) of the compound (Z-2-1) in terms of standard polystyrene determined by GPC measurement was 40.000, and the polydispersity (Mw/Mn) thereof was 4.00. The copolymer compositional ratio (the ratio (molar ratio) between constitutional units in the structural formula) determined by ¹³C-NMR was l/m/n=40/45/15.

(Z)-2-2: compound represented by Chemical Formula (Z-2) The weight-average molecular weight (Mw) of the compound (Z-2-2) in terms of standard polystyrene determined by GPC measurement was 80,000, and the polydispersity (Mw/Mn) thereof was 5.10. The copolymer compositional ratio (the ratio (molar ratio) between constitutional units in the structural formula) determined by ¹³C-NMR was l/m/n=40/45/15.

(Z)-2-3: compound represented by Chemical Formula (Z-2) The weight-average molecular weight (Mw) of the compound (Z-2-3) in terms of standard polystyrene determined by GPC measurement was 200,000, and the polydispersity (Mw/Mn) thereof was 8.50. The copolymer compositional ratio (the ratio (molar ratio) between constitutional units in the structural formula) determined by ¹³C-NMR was l/m/n=40/45/15.

(Z)-2-4: compound represented by Chemical Formula (Z-2) The weight-average molecular weight (Mw) of the compound (Z-2-4) in terms of standard polystyrene determined by GPC measurement was 10,000, and the polydispersity (Mw/Mn) thereof was 2.00. The copolymer compositional ratio (the ratio (molar ratio) between constitutional units in the structural formula) determined by ¹³C-NMR was l/m/n=40/45/15.

(Z)-2-5: compound represented by Chemical Formula (Z-2) The weight-average molecular weight (Mw) of the compound (Z-2-5) in terms of standard polystyrene determined by GPC measurement was 2,000, and the polydispersity (Mw/Mn) thereof was 1.50. The copolymer compositional ratio (the ratio (molar ratio) between constitutional units in the structural formula) determined by ¹³C-NMR was l/m/n=40/45/15.

(Z)-3: compound represented by Chemical Formula (Z-3) The weight-average molecular weight (Mw) of the compound (Z-3) in terms of standard polystyrene determined by GPC measurement was 40,000, and the polydispersity (Mw/Mn) thereof was 4.00. The copolymer compositional ratio (the ratio (molar ratio) between constitutional units in the structural formula) determined by ¹³C-NMR was l/m/n=40/45/15.

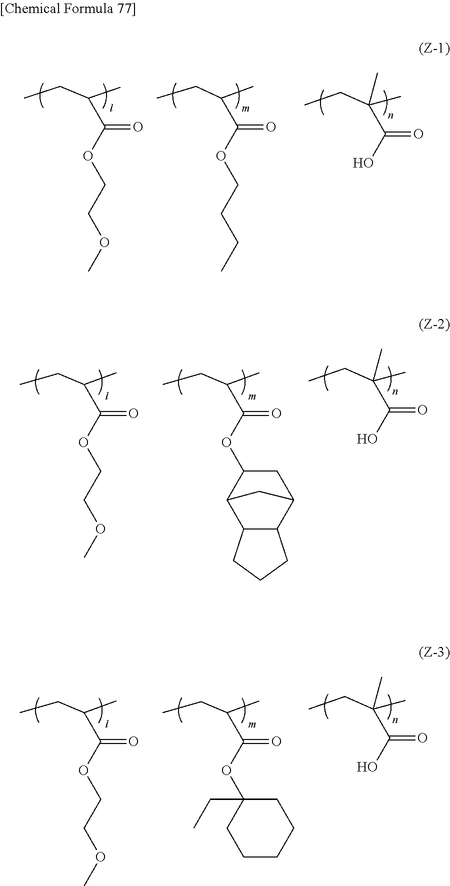

(S)-1: propylene glycol monomethyl ether acetate (PGMEA)
(S)-2: propylene glycol monomethyl ether (PGME)
(S)-3: butyl acetate

### <Resist Pattern Formation>

### Step (i):

A silicon wafer that had been treated with hexamethyldisilazane (HMDS) at 110° C. for 60 seconds was coated with the resist composition of each example using a spinner. The silicon wafer was subjected to a post applied bake (PAB) on a hot plate at 140° C. for 90 seconds and dried, thereby obtaining a resist film having a film thickness of 18 μm.

### Step (ii):

Next, the resist film was selectively irradiated with a KrF excimer laser (248 nm) by a KrF exposure apparatus NSR-S203B (manufactured by Nikon Corporation; numerical aperture (NA)=0.60, σ=0.68) through a mask pattern (binary mask).

Thereafter, a post exposure bake (PEB) treatment was performed on the resist film at 120° C. for 90 seconds.

Step (iii):

Subsequently, alkali development was performed under the conditions of 23° C. and 60 seconds using a 2.38% by mass tetramethylammonium hydroxide (TMAH) aqueous solution “NMD-3” (product name, manufactured by TOKYO OHKA KOGYO CO., LTD.) as a developing solution.

As a result, an isolated space pattern (IS pattern) having a space width of 5 μm was formed.

### [Evaluation of Cracks]

The substrate on which the IS pattern was formed in <Resist pattern formation> was placed in a chamber of a scanning electron microscope S-9380 (manufactured by Hitachi High-Tech Corporation), and a vacuum treatment was performed on the substrate for 60 seconds under a pressure of 0.0001 Pa. The silicon wafer after the vacuum treatment was observed using an optical microscope, and the number of cracks was counted. The number of cracks was evaluated based on the following evaluation criteria. The results are listed in the columns of “cracks” in Tables 7 to 12.

### Evaluation Criteria

A: The number of cracks was 0.
B: The number of cracks was in a range of 1 to 5.
C: The number of cracks was in a range of 6 to 20.
D: The number of cracks was 21 or greater.

### [Evaluation of ΔCD Shape]

With the IS pattern formed in <Resist pattern formation>, the CD in the upper portion of the pattern (CD-top) and the CD in the bottom portion of the pattern (CD-bottom) were measured with a scanning electron microscope 5-9380 (manufactured by Hitachi High-Tech Corporation), and the difference (ΔCD) therebetween was determined. In a case where the value of ΔCD decreased, this indicates that the rectangularity of the pattern increased and a pattern having a satisfactory shape was formed. The results are listed in the columns of “ΔCD shape (μm)” in Tables 7 to 12.

### [Evaluation of Viscosity]

The viscosity (cP) of each resist composition of each example was measured with an automatic viscosity measuring device VMC-252 (manufactured by RIGO). The measured viscosity was evaluated according to the following evaluation criteria. The results are listed in the columns of “viscosity” in Tables 7 to 12.

### Evaluation Criteria

A: The viscosity was less than 500 cP.
B: The viscosity was 500 cP or greater and less than 600 cP.
C: The viscosity was 600 cP or greater.
   [Evaluation of Change in CD after Post-Exposure Delay]

An IS pattern was formed in the same manner as in <Resist pattern formation> described above except that the resist film was selectively exposed to a KrF excimer laser, allowed to stand for 2 hours, and subjected to a post exposure bake (PEB) treatment at 120° C. for 90 seconds in the step (ii) of <Resist pattern formation> described above.

The formed IS pattern was measured with a scanning electron microscope S-9380 (manufactured by Hitachi High-Tech Corporation), and a CD difference due to a post-exposure delay time (hereinafter, also referred to as “CD (PED) value”) was calculated. The calculated CD (PED) value was evaluated according to the following evaluation criteria. In a case where the CD (PED) value decreased, this indicates that the resist was unlikely to undergo a change in CD due to the process, which was satisfactory. The results are listed in the columns of “CD (PED)” in Tables 7 to 12.

### Evaluation Criteria

A: CD (PED)<50 nm
B: 50 nm≤CD (PED)<150 nm
C: 150 nm≤CD (PED)≤500 nm
D: CD (PED)>500 nm

TABLE 7

| | | ΔCD | | CD |
|---|---|---|---|---|
| | Cracks | (μm) | Viscosity | (PED) |
| Example 1 | B | 5.06 | A | B |
| Example 2 | A | 5.09 | A | A |
| Example 3 | A | 5.38 | A | A |
| Example 4 | C | 5.13 | A | A |
| Example 5 | B | 5.05 | A | B |
| Example 6 | A | 5.11 | A | A |
| Example 7 | A | 5.36 | B | A |
| Example 8 | C | 5.13 | A | A |
| Example 9 | B | 5.10 | A | B |
| Example 10 | A | 5.14 | C | B |
| Example 11 | A | 5.32 | C | A |
| Example 12 | C | 5.21 | C | B |

TABLE 8

| | | ΔCD | | CD |
|---|---|---|---|---|
| | Cracks | (μm) | Viscosity | (PED) |
| Example 13 | C | 5.13 | A | B |
| Example 14 | B | 5.25 | A | A |
| Example 15 | A | 5.45 | A | A |
| Example 15 | C | 5.32 | A | A |
| Example 17 | C | 5.22 | A | A |
| Example 18 | B | 5.46 | A | A |
| Example 19 | B | 5.68 | A | A |
| Example 20 | C | 5.50 | A | A |

TABLE 9

| | | ΔCD | | CD |
|---|---|---|---|---|
| | Cracks | (μm) | Viscosity | (PED) |
| Example 21 | B | 5.18 | A | B |
| Example 22 | A | 5.20 | A | A |
| Example 23 | A | 5.39 | A | A |
| Example 24 | B | 5.22 | A | B |
| Example 25 | A | 5.26 | A | A |
| Example 26 | A | 5.48 | A | A |
| Example 27 | B | 5.32 | A | B |
| Example 28 | A | 5.41 | A | A |
| Example 29 | A | 5.77 | A | A |
| Example 30 | B | 5.15 | A | B |
| Example 31 | A | 5.20 | A | A |
| Example 32 | A | 5.43 | A | A |

TABLE 10

| | | ΔCD | | CD |
|---|---|---|---|---|
| | Cracks | (μm) | Viscosity | (PED) |
| Example 33 | A | 4.58 | A | A |
| Example 34 | A | 4.84 | A | A |
| Example 35 | B | 4.82 | A | B |
| Example 36 | A | 4.81 | A | A |
| Example 37 | A | 5.08 | A | A |
| Example 38 | B | 5.05 | A | B |
| Example 39 | A | 5.04 | A | A |
| Example 40 | A | 5.33 | A | A |
| Example 41 | B | 5.28 | A | B |
| Example 42 | A | 5.29 | A | A |
| Example 43 | A | 5.30 | A | A |
| Example 44 | A | 5.50 | A | A |
| Example 45 | A | 5.46 | A | A |
| Example 46 | A | 5.79 | A | A |

TABLE 11

| | | ΔCD | | CD |
|---|---|---|---|---|
| | Cracks | (μm) | Viscosity | (PED) |
| Comparative | D | 7.12 | A | D |
| Example 1 | | | | |
| Comparative | D | 7.28 | A | D |
| Example 2 | | | | |
| Comparative | D | 7.25 | A | D |
| Example 3 | | | | |
| Comparative | C | 7.09 | A | D |
| Example 4 | | | | |
| Comparative | C | 7.45 | A | B |
| Example 5 | | | | |
| Comparative | D | 5.05 | A | C |
| Example 6 | | | | |
| Comparative | D | 5.11 | A | C |
| Example 7 | | | | |
| Comparative | D | 5.38 | A | C |
| Example 8 | | | | |
| Comparative | D | 5.47 | A | C |
| Example 9 | | | | |
| Comparative | D | 5.18 | A | C |
| Example 10 | | | | |
| Comparative | A | 5.55 | A | C |
| Example 11 | | | | |

TABLE 12

| | | ΔCD | | CD |
|---|---|---|---|---|
| | Cracks | (μm) | Viscosity | (PED) |
| Comparative | D | 4.33 | A | C |
| Example 12 | | | | |
| Comparative | D | 4.55 | A | C |
| Example 13 | | | | |
| Comparative | C | 4.59 | A | C |
| Example 14 | | | | |
| Comparative | D | 4.35 | A | C |
| Example 15 | | | | |
| Comparative | D | 4.58 | A | C |
| Example 16 | | | | |
| Comparative | D | 4.38 | A | C |
| Example 17 | | | | |
| Comparative | D | 4.61 | A | C |
| Example 18 | | | | |
| Comparative | D | 5.02 | A | C |
| Example 19 | | | | |
| Comparative | D | 4.55 | A | C |
| Example 20 | | | | |
| Comparative | D | 4.79 | A | D |
| Example 21 | | | | |
| Comparative | D | 4.83 | A | D |
| Example 22 | | | | |

As shown in the results listed in Tables 7 to 12, it was confirmed that the viscosities of all the resist compositions of the examples were 500 cP or less. In addition, it was confirmed that the thick resist pattern formed of the resist composition of the examples had a small ΔCD, reduced the occurrence of cracks, and had satisfactory CD (PED).

While preferred embodiments of the present invention have been described and illustrated above, it should be understood that these are exemplary of the present invention and are not to be considered as limiting. Additions, omissions, substitutions, and other modifications can be made without departing from the scope of the invention. Accordingly, the present invention is not to be considered as being limited by the foregoing description and is only limited by the scope of the appended claims.

What is claimed is:

1. A resist composition which generates an acid upon light exposure and whose solubility in a developing solution is changed due to an action of the acid, the resist composition comprising:
a resin component (A1) that has a constitutional unit (a1) containing an acid decomposable group whose polarity is increased due to an action of an acid, a constitutional unit (a10) represented by General Formula (a10-1), and a constitutional unit (a5) represented by General Formula (a5-1); and
a resin component (Z) that has a constitutional unit (z1) represented by General Formula (z1-1) and no acid dissociable group, 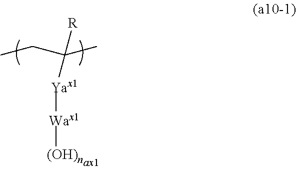
wherein R represents a hydrogen atom, an alkyl group having 1 to 5 carbon atoms, or a halogenated alkyl group having 1 to 5 carbon atoms, Ya^{x1} represents a single bond or a divalent linking group, Wa^{x1} represents an aromatic hydrocarbon group which may have a substituent, and nₐₓ₁ represents an integer of 1 or greater, 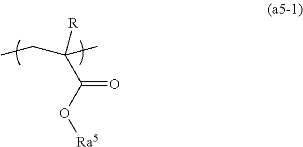
wherein R represents a hydrogen atom, an alkyl group having 1 to 5 carbon atoms, or a halogenated alkyl group having 1 to 5 carbon atoms, and Ra⁵ represents an acid non-dissociable aliphatic cyclic group in which some carbon atoms forming a ring skeleton may be substituted with oxygen atoms, 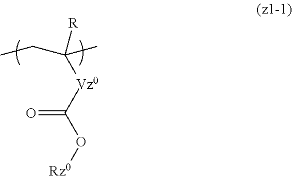
wherein R represents a hydrogen atom, an alkyl group having 1 to 5 carbon atoms, or a halogenated alkyl group having 1 to 5 carbon atoms, Vz⁰ represents a single bond or a divalent hydrocarbon group which may contain a heteroatom, where in a case where Vz⁰ represents the divalent hydrocarbon group which may have a heteroatom, Vz⁰ does not include an acid dissociable group, and Rz⁰ represents a hydrogen atom or a group represented by General Formula (z1-r-1), 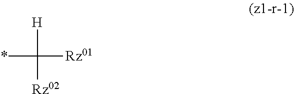
wherein Rz⁰¹ represents a hydrocarbon group which may have a substituent, Rz⁰² represents a hydrogen atom or a hydrocarbon group which may have a substituent, Rz⁰¹ and Rz⁰² may be bonded to each other to form a ring structure, where Rz⁰¹ and Rz⁰² do not include an acid dissociable group, and * represents a bonding site.

2. The resist composition according to claim 1,
wherein a content of the resin component (Z) is in a range of 1 to 50 parts by mass with respect to 100 parts by mass of the resin component (A1).

3. The resist composition according to claim 1,
wherein a weight-average molecular weight of the resin component (Z) is in a range of 20,000 to 100,000.

4. The resist composition according to claim 1,
wherein a proportion of the constitutional unit (a10) in the resin component (A1) is in a range of 15% to 60% by mole with respect to a total amount (100% by mole) of all constitutional units constituting the resin component (A1).

5. A method for forming a resist pattern, comprising:
forming a resist film on a support using the resist composition according to claim 1;
exposing the resist film to light; and
developing the resist film exposed to light to form a resist pattern.
